(19) United States
(12) Patent Application Publication
(10) Pub. No.: US 2025/0338610 A1
(43) Pub. Date: Oct. 30, 2025

(54) Semiconductor Structure And Method For Forming The Same

(71) Applicant: Taiwan Semiconductor Manufacturing Company, Ltd., Hsin-Chu (TW)

(72) Inventors: Wan Chen Hsieh, Hsin-Chu city (TW); Chung-Ting Ko, Kaohsiung City (TW); Tai-Chun Huang, Hsin-Chu city (TW)

(21) Appl. No.: 19/260,797

(22) Filed: Jul. 7, 2025

Related U.S. Application Data
(63) Continuation of application No. 17/721,723, filed on Apr. 15, 2022.
(60) Provisional application No. 63/216,015, filed on Jun. 29, 2021.
(60) Provisional application No. 63/235,029, filed on Aug. 19, 2021.

(51) Int. Cl. H10D 84/83; H01L 21/28; H10D 84/01; H10D 84/03

(52) U.S. Cl. CPC H10D 84/834; H01L 21/28123; H10D 84/0151; H10D 84/0158; H10D 84/038

(57) ABSTRACT

A semiconductor structure includes a substrate, an isolation structure over the substrate, a first semiconductor fin protruding from the substrate and through the isolation structure, a second semiconductor fin protruding from the substrate and through the isolation structure, a dielectric fin between the first semiconductor fin and the second semiconductor fin, a first gate stack across the first semiconductor fin, a first gate spacer extending along a sidewall of the first gate stack, a second gate stack across the second semiconductor fin, a second gate spacer extending along a sidewall of the second gate stack, and a gate cut feature disposed over a top surface of the dielectric fin. Top surfaces of the first and second semiconductor fins and the top surface of the dielectric fin are coplanar. The gate cut feature separates the first gate stack from the second gate stack.

### PRIORITY

This is a continuation application of U.S. patent application Ser. No. 17/721,723, filed Apr. 15, 2022, which claims the benefit of U.S. Provisional Application No. 63/235,029, filed Aug. 19, 2021, and the benefit of U.S. Provisional Application No. 63/216,015, filed on Jun. 29, 2021, all of which are incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

As the semiconductor industry has progressed into nanometer technology process nodes in pursuit of higher device density, higher performance, and lower costs, challenges from both fabrication and design issues have resulted in the development of three-dimensional designs. Fin-like field effect transistors (FinFETs) and multi-bridge-channel (MBC) transistors are examples of multi-gate transistors that have become popular and promising candidates for high performance and low leakage applications. A FinFET has an elevated channel wrapped by a gate structure on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The advantages of a FinFET and an MBC transistor may include reducing the short channel effect and providing a higher current flow.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1R are cross-sectional views of various stages of a process for forming a semiconductor structure, in accordance with some embodiments.

FIG. 1A-1 is a perspective view of the semiconductor structure of FIG. 1A, in accordance with some embodiments.

FIG. 1B-1 is a perspective view of the semiconductor structure of FIG. 1B, in accordance with some embodiments.

FIGS. 1C-1 to 1R-1 are top views of the semiconductor structures of FIGS. 1C-1R, in accordance with some embodiments.

FIG. 1G-2 is a cross-sectional view illustrating the semiconductor structure along a sectional line II-II′ in FIG. 1G-1, in accordance with some embodiments.

FIG. 1H-2 is a cross-sectional view illustrating the semiconductor structure along a sectional line II-II′ in FIG. 1H-1, in accordance with some embodiments.

FIG. 1I-2 is a cross-sectional view illustrating the semiconductor structure along a sectional line II-II′ in FIG. 1I-1, in accordance with some embodiments.

FIG. 1I-3 is a cross-sectional view illustrating the semiconductor structure along a sectional line III-III′ in FIG. 1I-1, in accordance with some embodiments.

FIG. 1J-2 is a cross-sectional view illustrating the semiconductor structure along a sectional line II-II′ in FIG. 1J-1, in accordance with some embodiments.

FIG. 1J-3 is a cross-sectional view illustrating the semiconductor structure along a sectional line III-III′ in FIG. 1J-1, in accordance with some embodiments.

FIG. 1P-2 is a cross-sectional view illustrating the semiconductor structure along a sectional line II-II′ in FIG. 1P-1, in accordance with some embodiments.

FIG. 1Q-2 is a cross-sectional view illustrating the semiconductor structure along a sectional line II-II′ in FIG. 1Q-1, in accordance with some embodiments.

FIG. 1R-2 is a cross-sectional view illustrating the semiconductor structure along a sectional line II-II′ in FIG. 1R-1, in accordance with some embodiments.

FIG. 2 is a cross-sectional view of a semiconductor structure, in accordance with some embodiments.

FIG. 3 is a cross-sectional view of a semiconductor structure, in accordance with some embodiments.

FIG. 4 is a cross-sectional view of a semiconductor structure, in accordance with some embodiments.

FIGS. 5A-5D are cross-sectional views of various stages of a process for forming a semiconductor structure, in accordance with some embodiments.

FIGS. 6A-6B are cross-sectional views of various stages of a process for forming a semiconductor structure, in accordance with some embodiments.

FIG. 7 is a perspective view of a semiconductor structure, in accordance with some embodiments of the disclosure.

FIGS. 8A-1 through 8L-5 are schematic views illustrating the formation of a semiconductor structure at various intermediate stages, in accordance with some embodiments of the disclosure.

FIGS. 9-1 through 9-4 are a modification of the semiconductor structure of FIGS. 8L-1 through 8L-5, in accordance with some embodiments of the disclosure.

FIGS. 10A-10B are cross-sectional views illustrating the formation of a semiconductor structure at various intermediate stages, in accordance with some embodiments of the disclosure.

FIGS. 11A-11B are cross-sectional views illustrating the formation of a semiconductor structure at various intermediate stages, in accordance with some embodiments of the disclosure.

FIGS. 12A-12B are cross-sectional views illustrating the formation of a semiconductor structure at various intermediate stages, in accordance with some embodiments of the disclosure.

FIGS. 13A-1 through 13B-2 are cross-sectional views illustrating the formation of a semiconductor structure at various intermediate stages, in accordance with some embodiments of the disclosure.

FIGS. 14A-1 through 14D-5 are schematic views illustrating the formation of a semiconductor structure at various intermediate stages, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5% or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor structure. Some of the features described below can be replaced or eliminated for different embodiments. Although some embodiments are discussed with operations performed in a particular order, these operations may be performed in another logical order.

Various embodiments that include fin-like field effect transistor (FinFET) device as example multi-gate transistors are illustrated in the figures, but the present disclosure is not so limited and may be applicable to other multi-gate transistors, such as MBC transistors. For FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

In accordance with some embodiments, semiconductor structures and methods for forming the same are provided. The methods include forming a dielectric fin structure between a first semiconductor fin structure and a second semiconductor fin structure, forming a gate structure over the first semiconductor fin structure, the dielectric fin structure, and the second semiconductor fin structure; and forming an opening through the gate structure and to the dielectric fin structure, thereby cutting through the gate structure. The formation of the dielectric fin structure may reduce the aspect ratio of the opening, which may help the formation of the opening and help to fill a gate cut isolation structure into the opening.

In addition, the semiconductor structures include a gate cut isolation structure between gate stacks. The gate cut isolation structure includes a protection layer with good etching resistance and a fill layer with high breakdown voltage. The protection layer may protect the fill layer from being damaged in the etching process for removing a dummy gate structure. The fill layer may prevent leakage between the gate stacks. Therefore, the reliability of the semiconductor device may be improved, and the manufacturing yield of the semiconductor device may be increased.

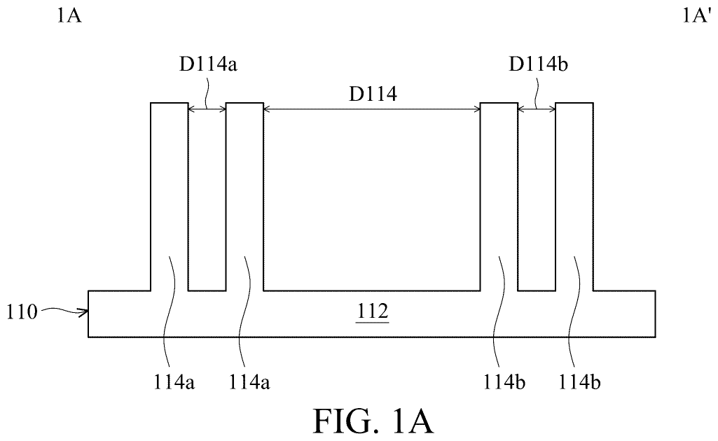

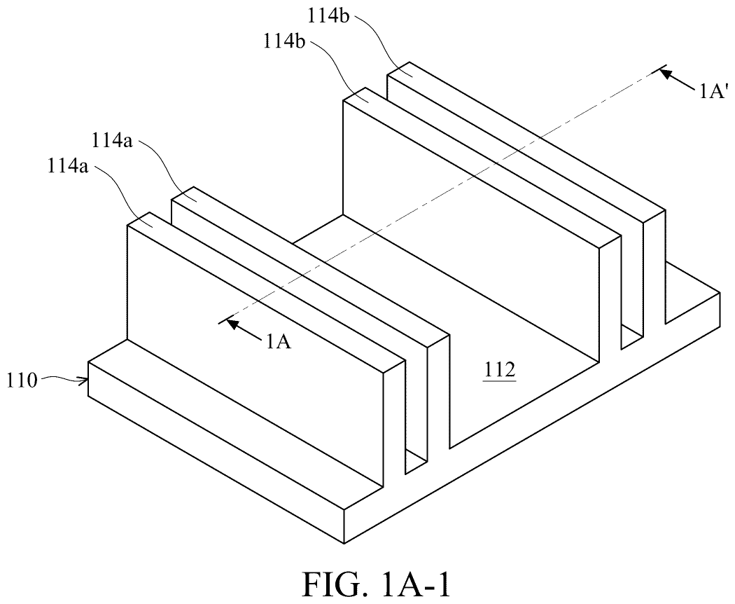

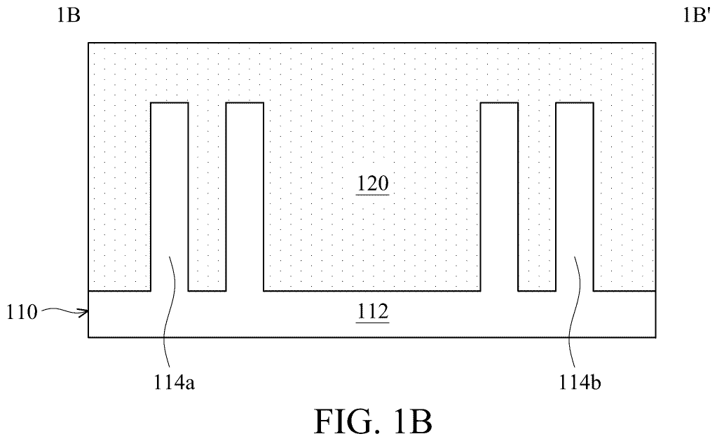

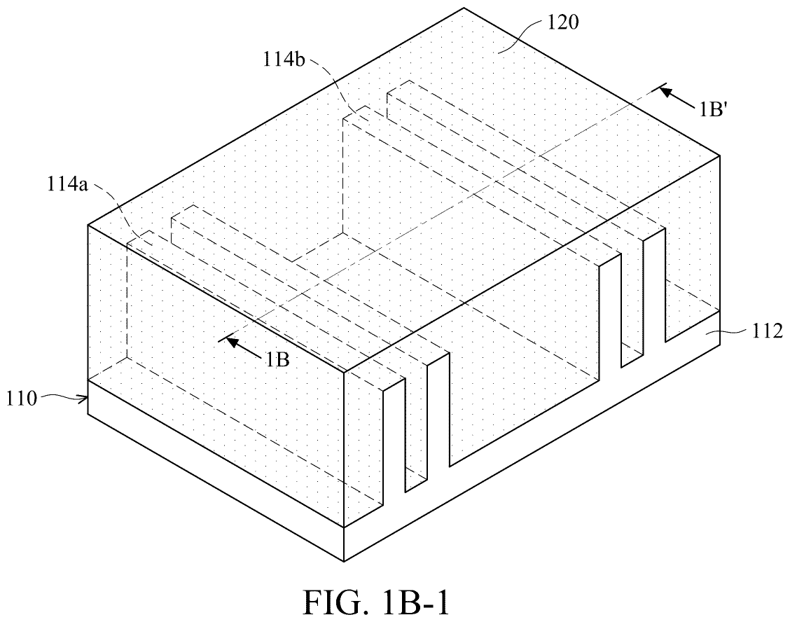

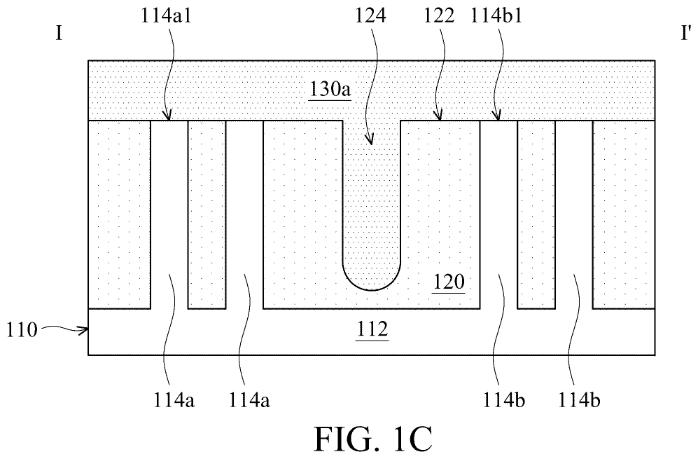

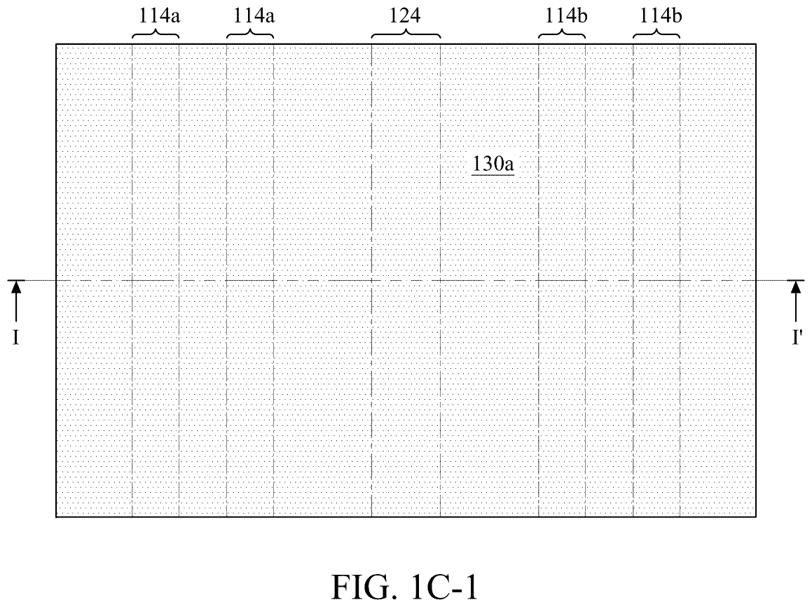

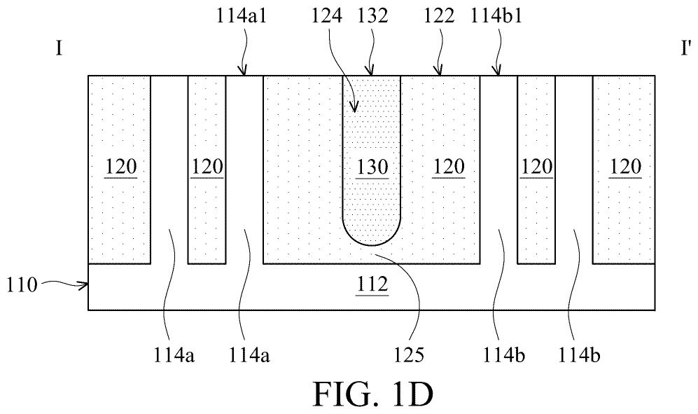

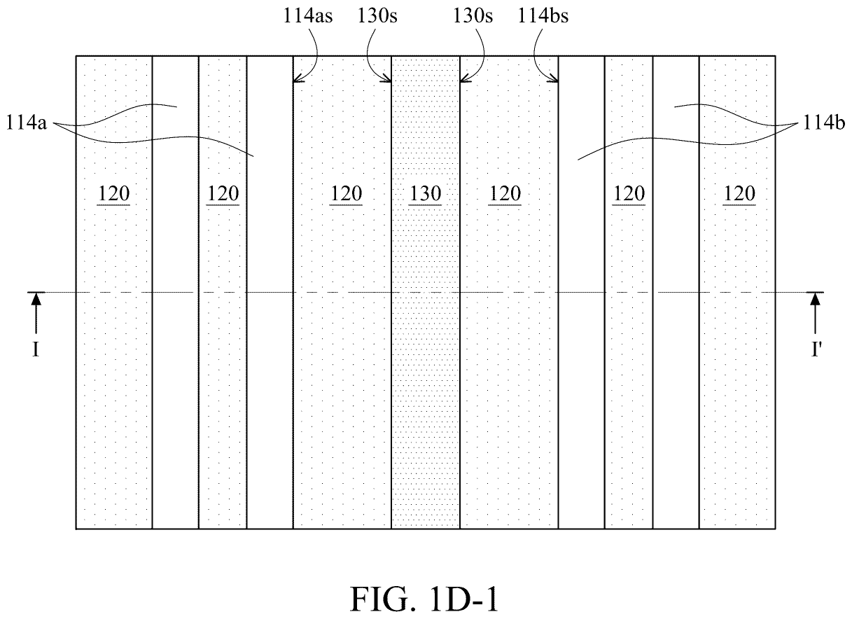

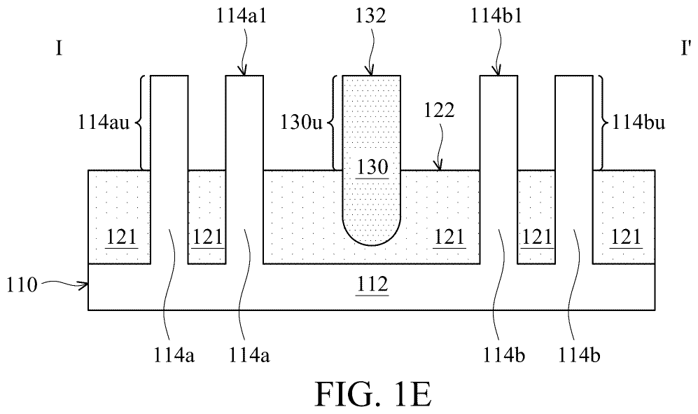

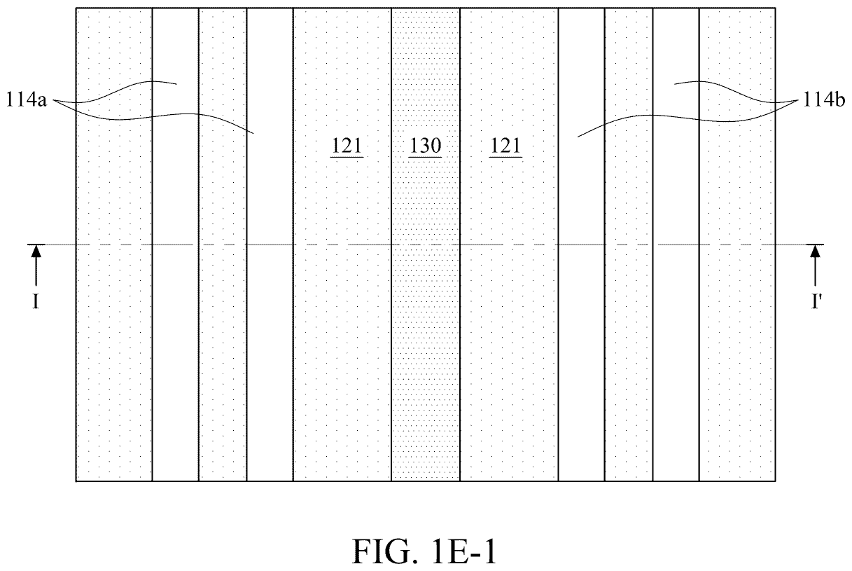

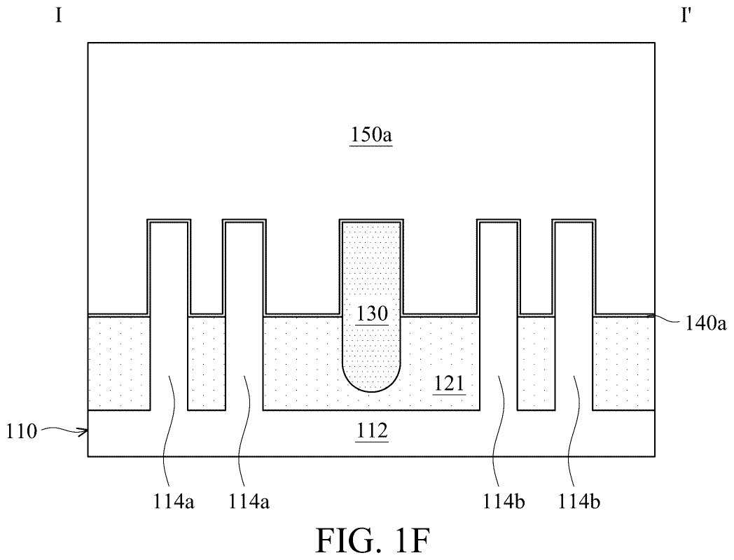

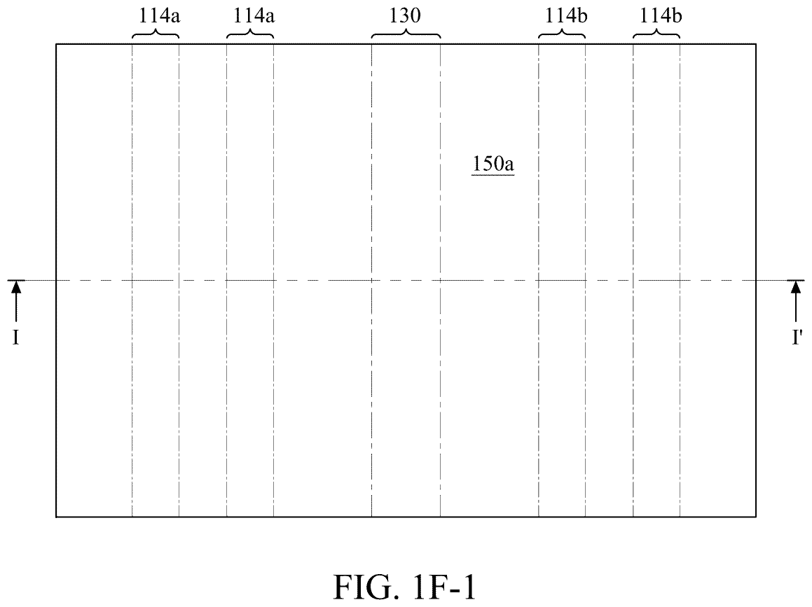

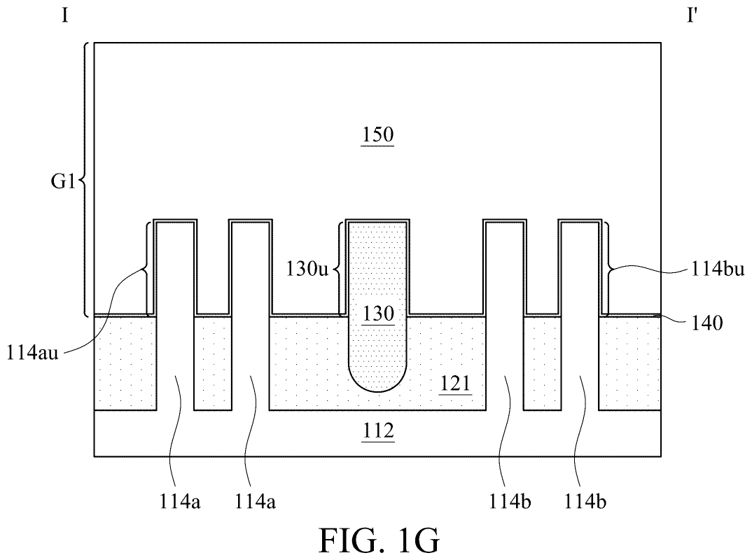

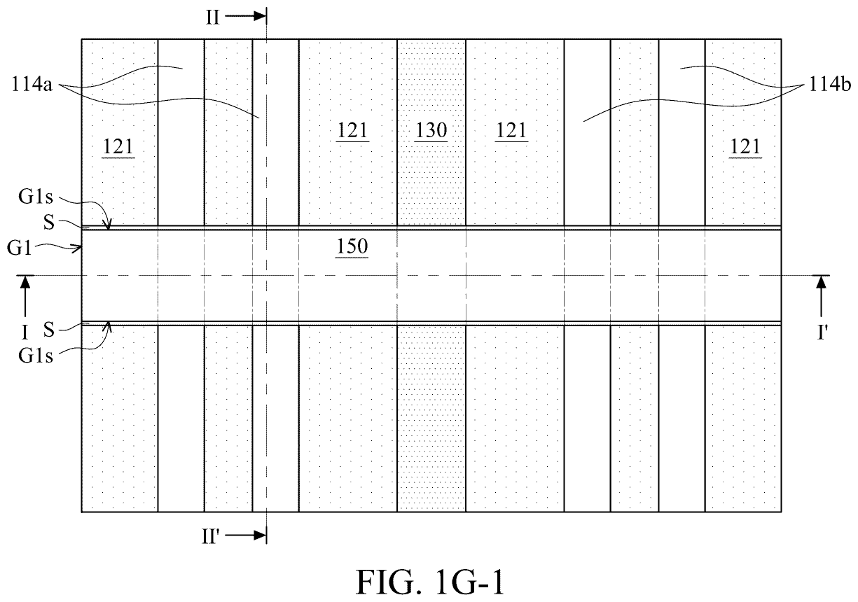

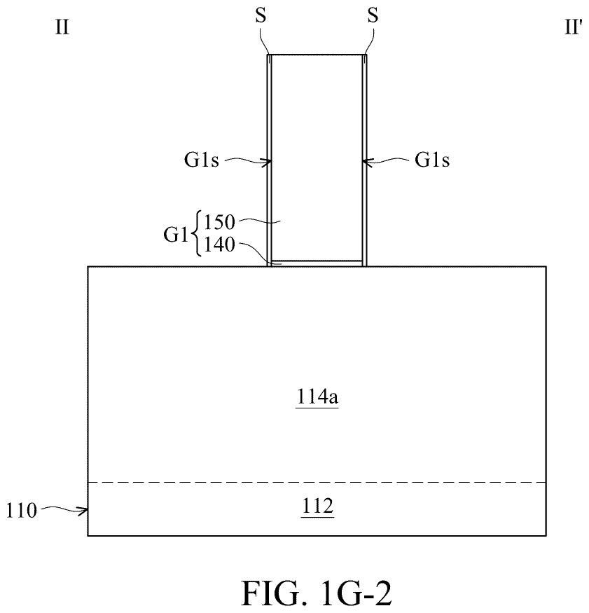

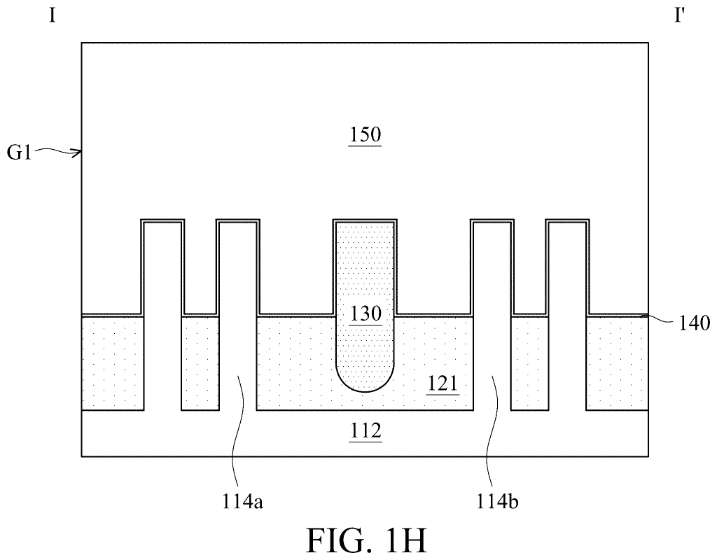

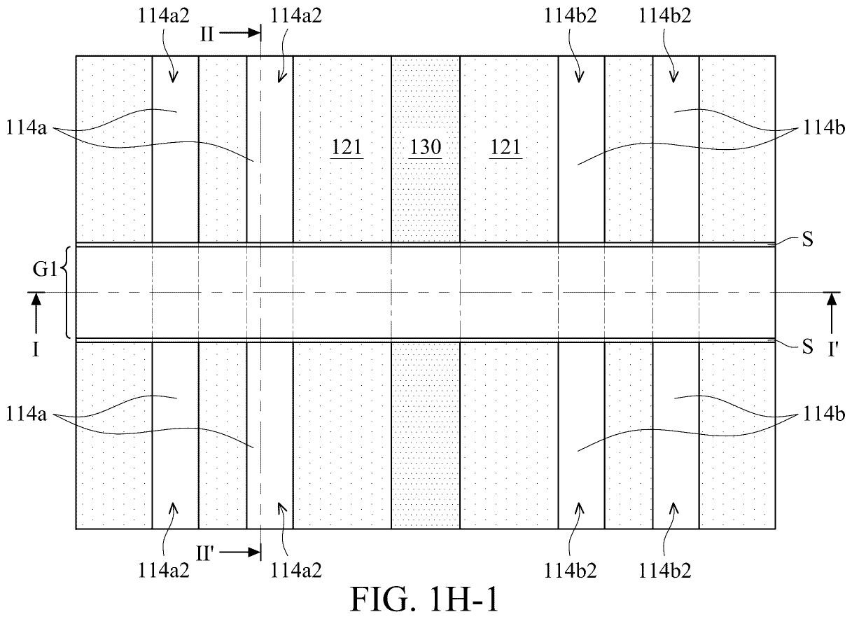

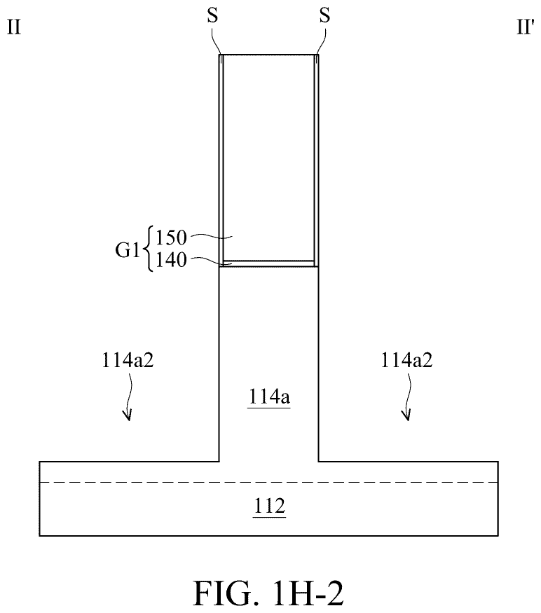

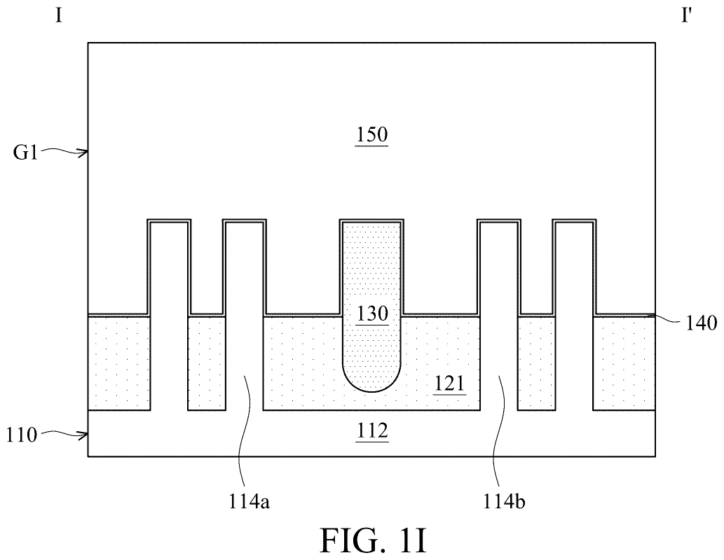

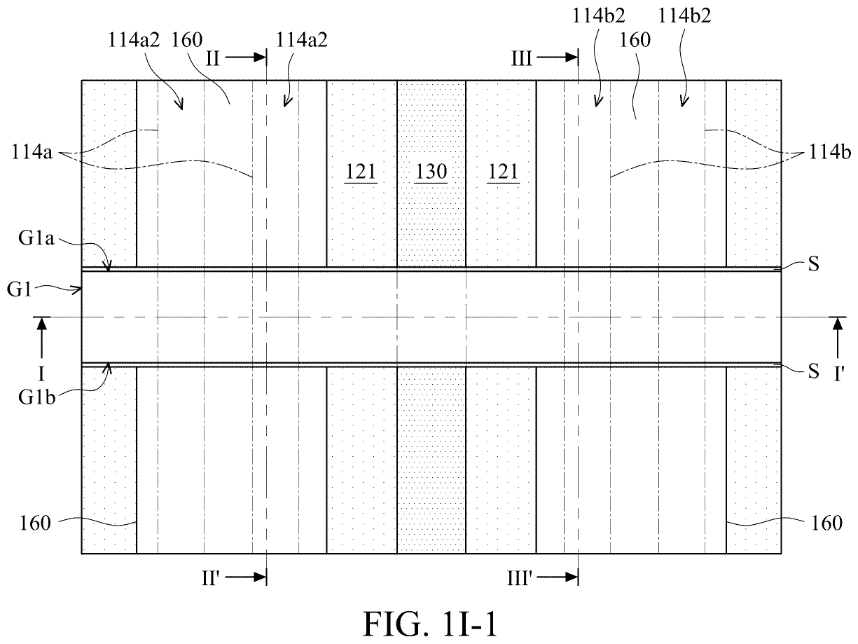

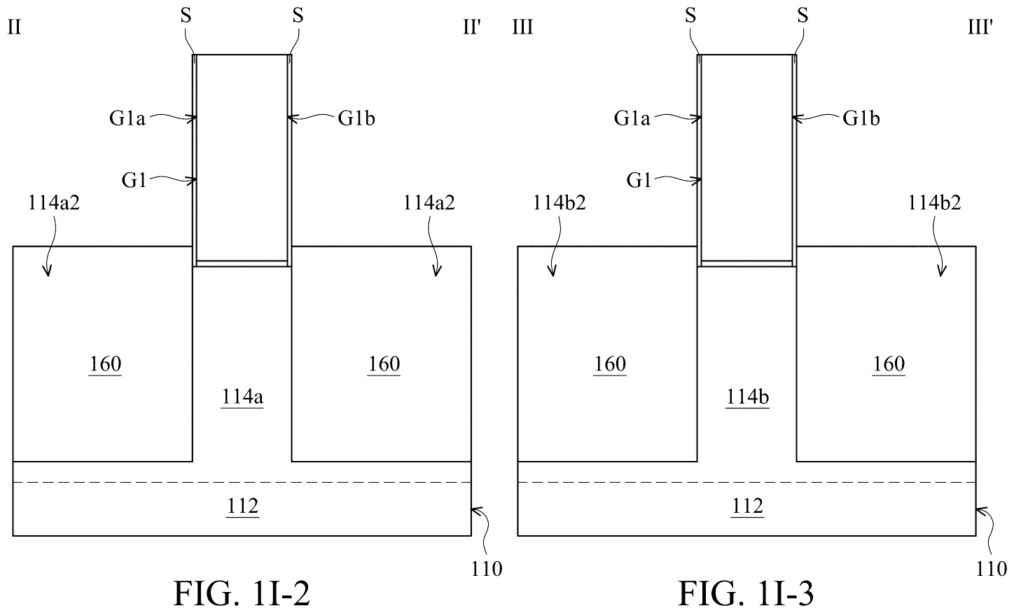

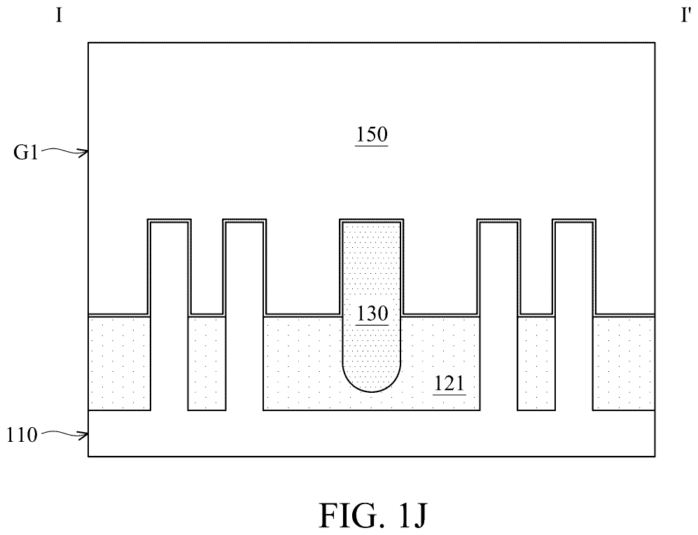

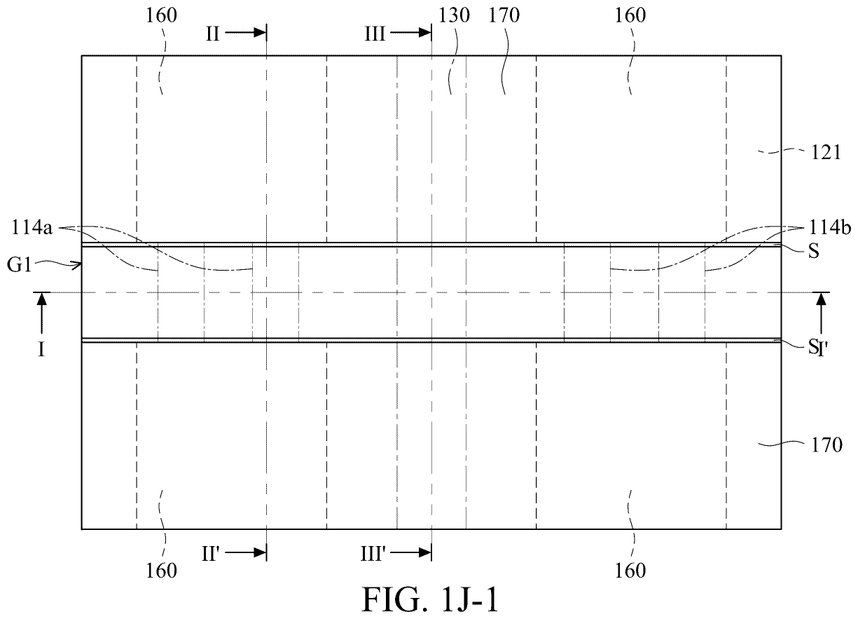

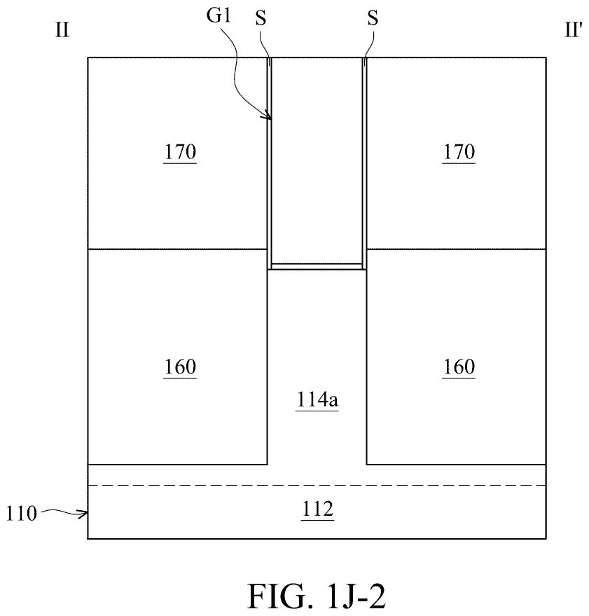

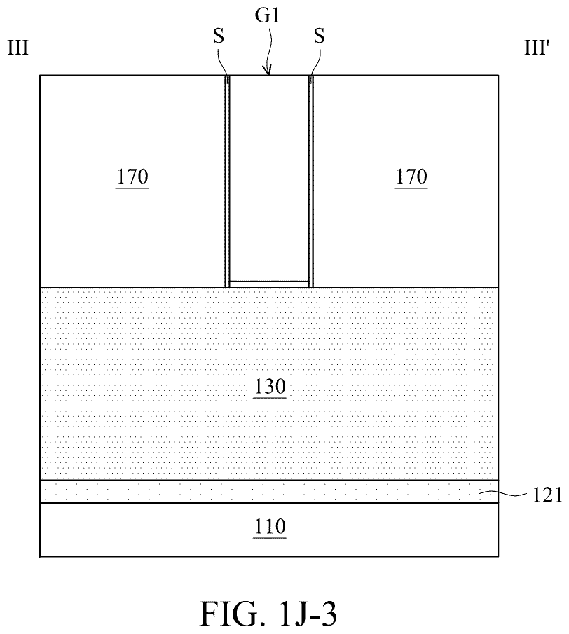

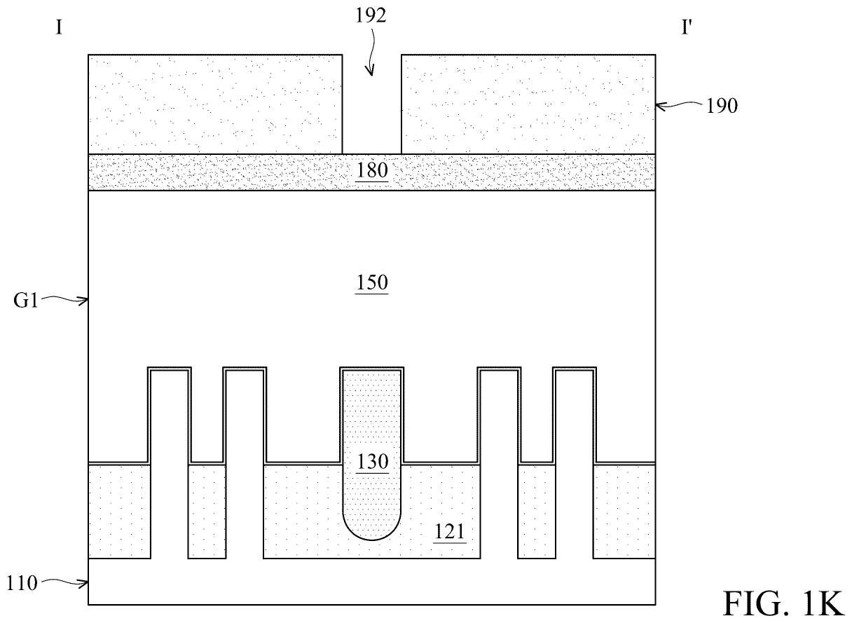

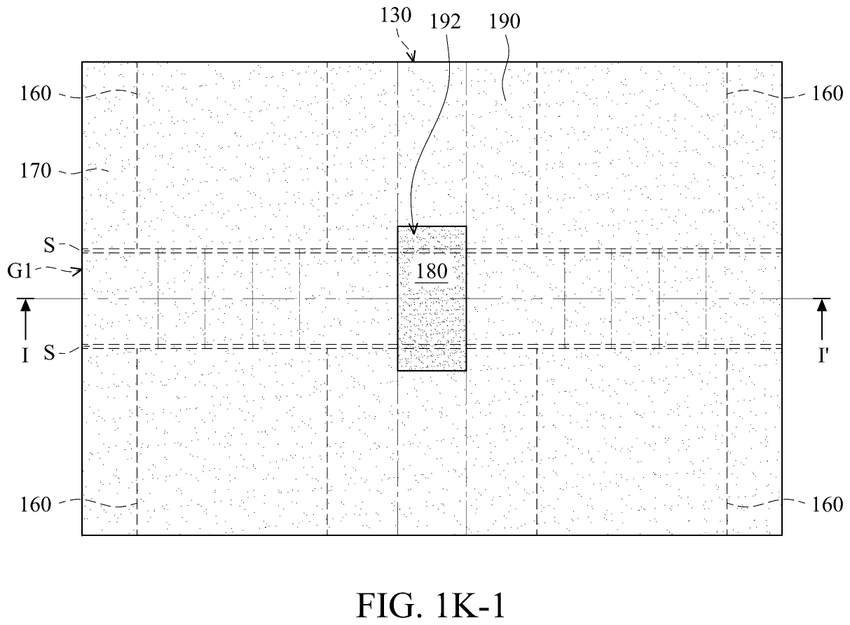

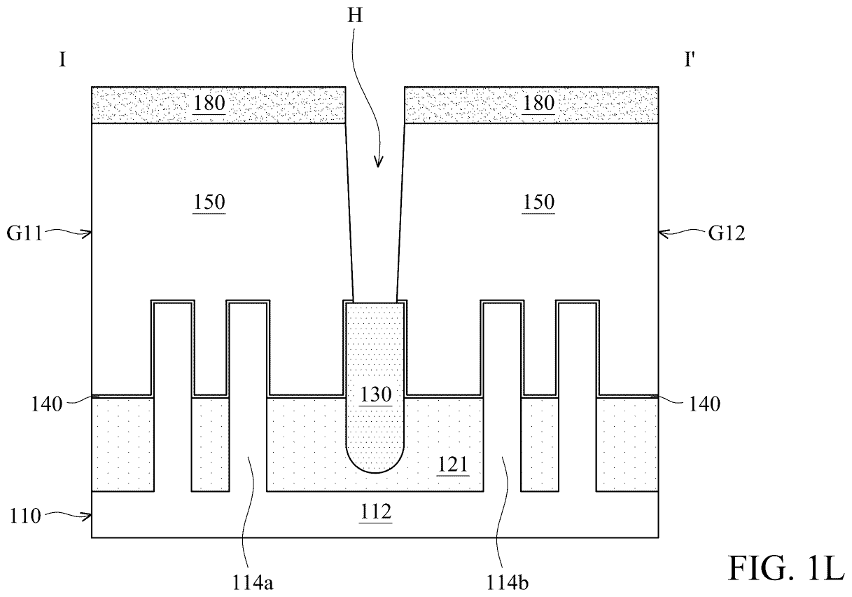

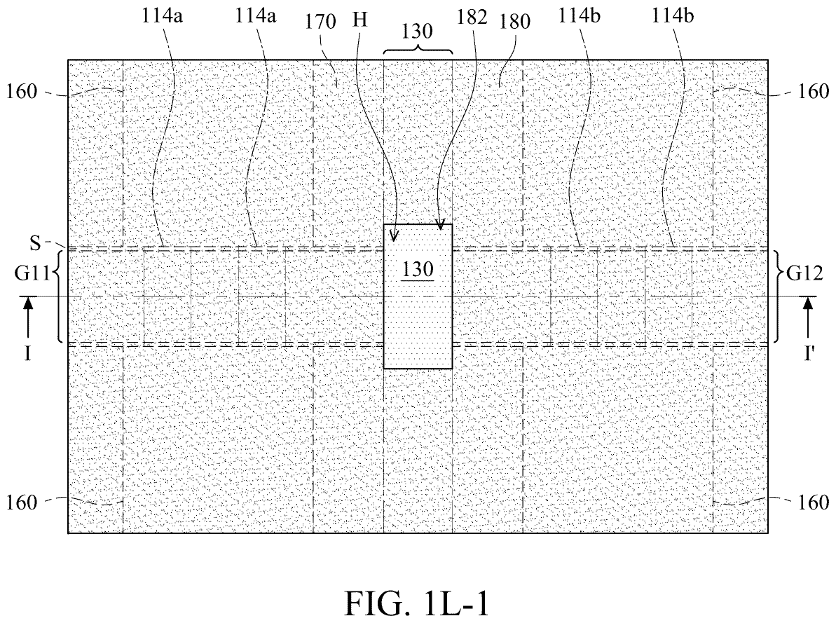

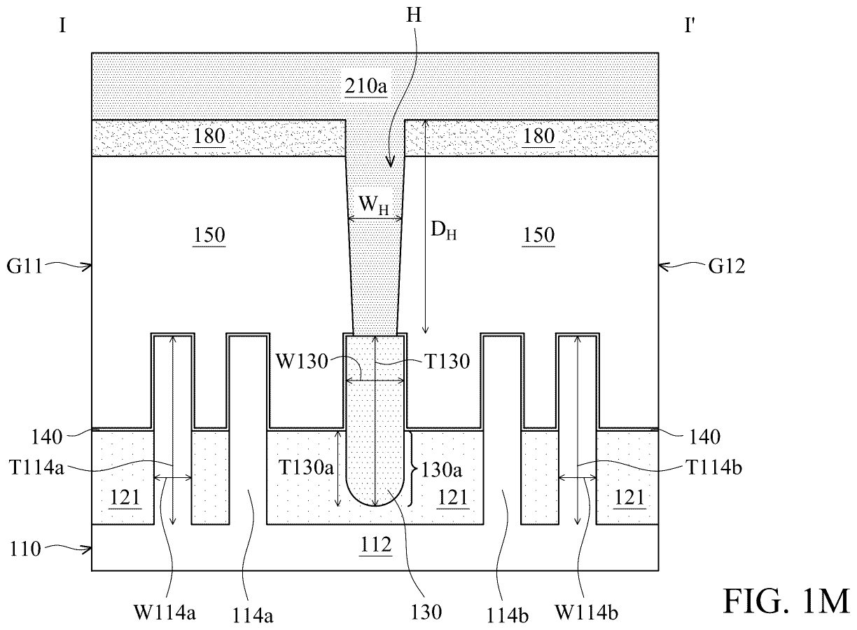

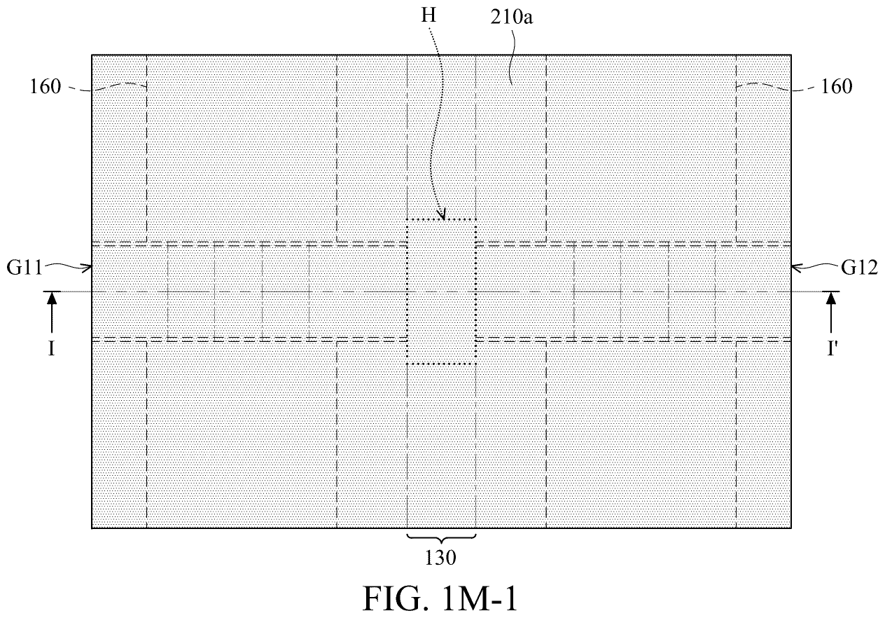

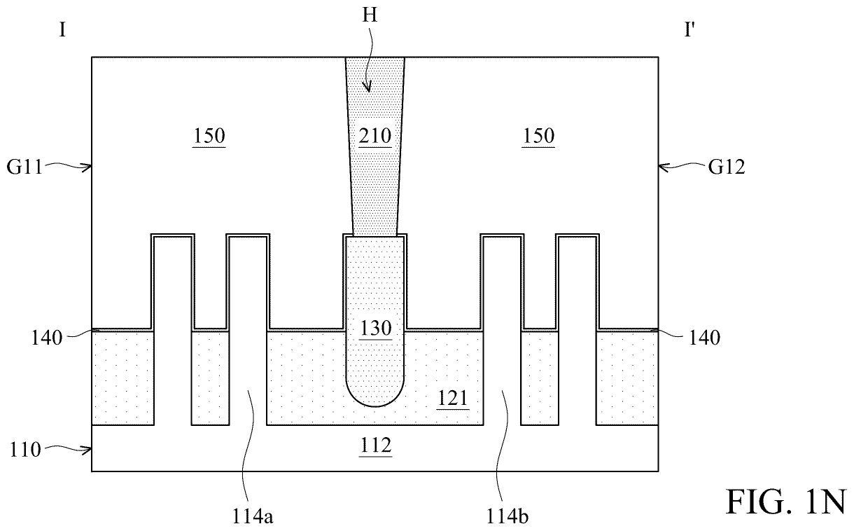

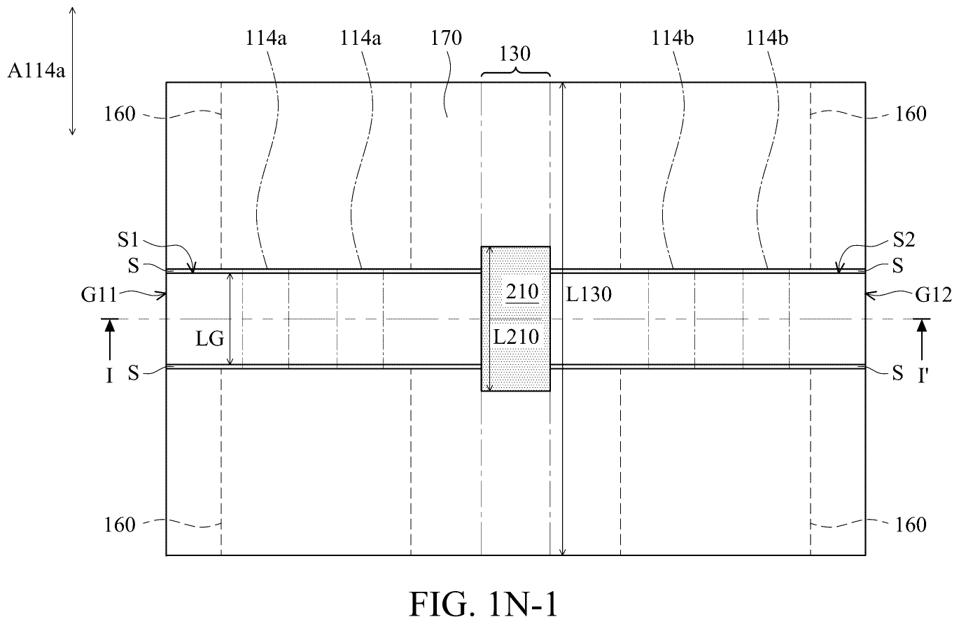

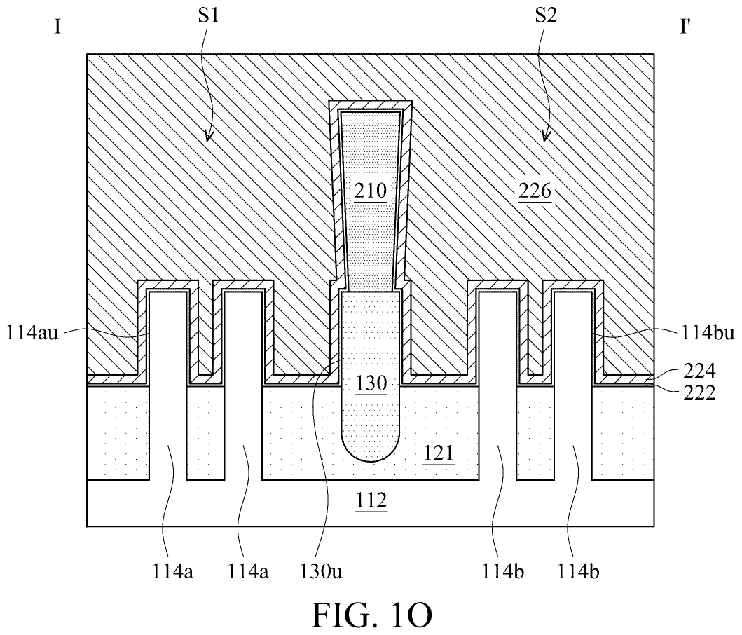

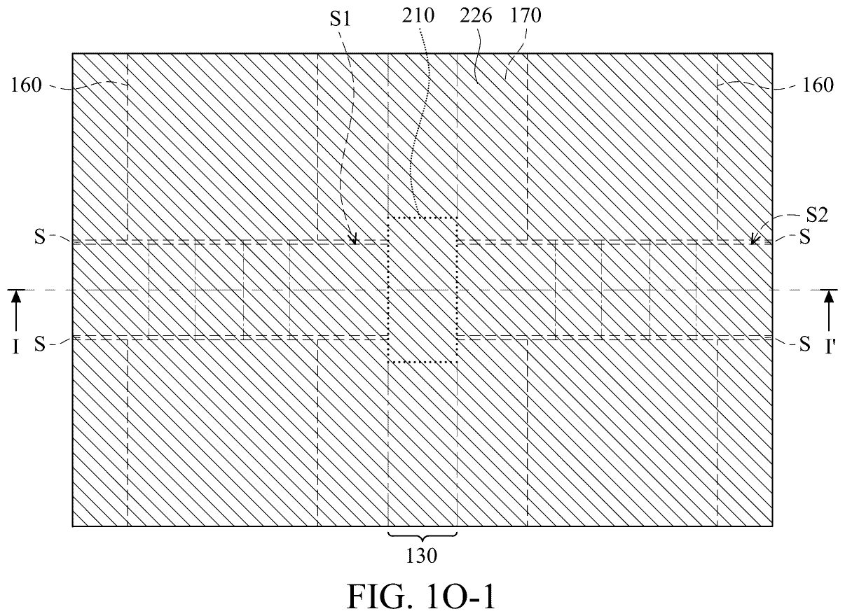

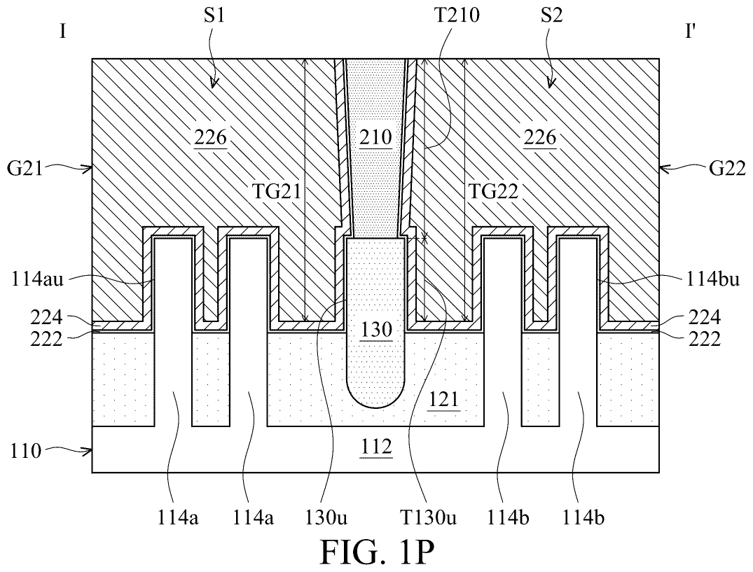

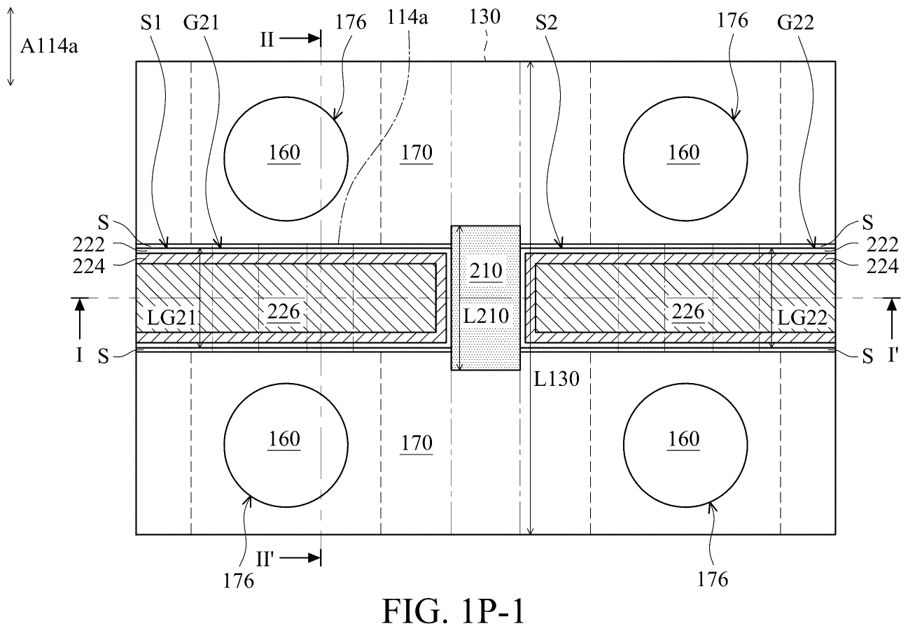

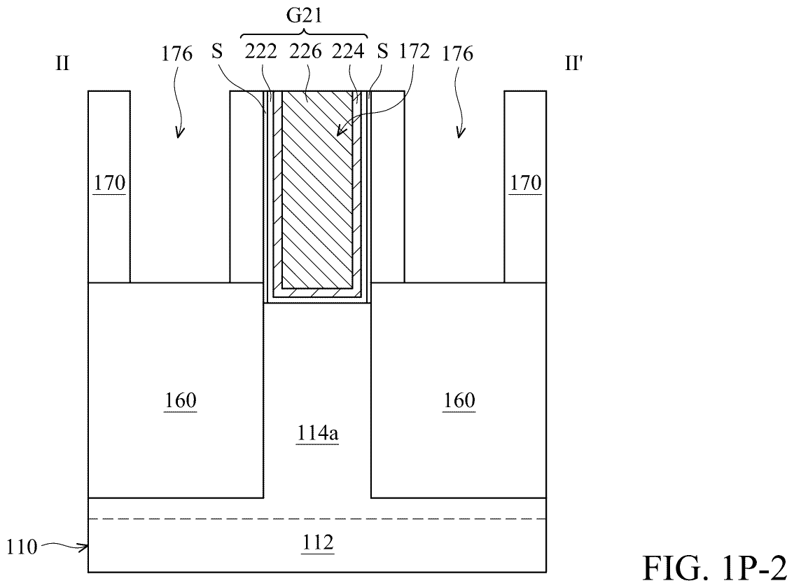

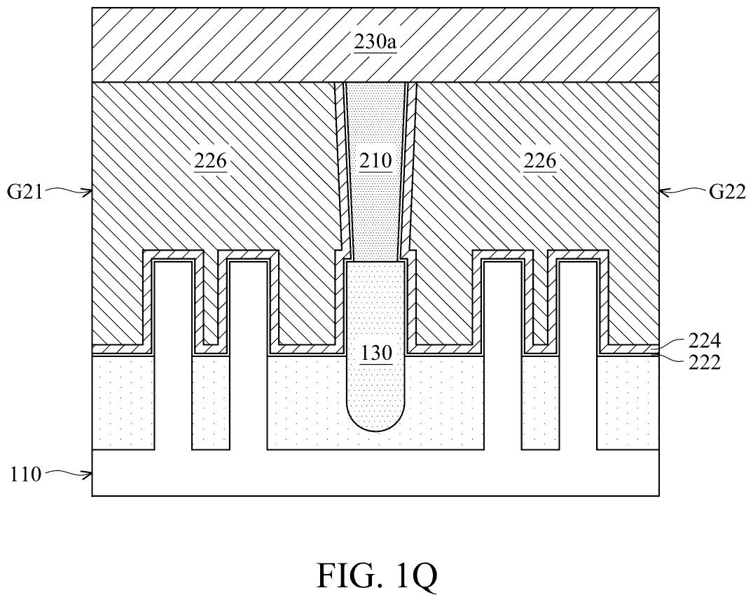

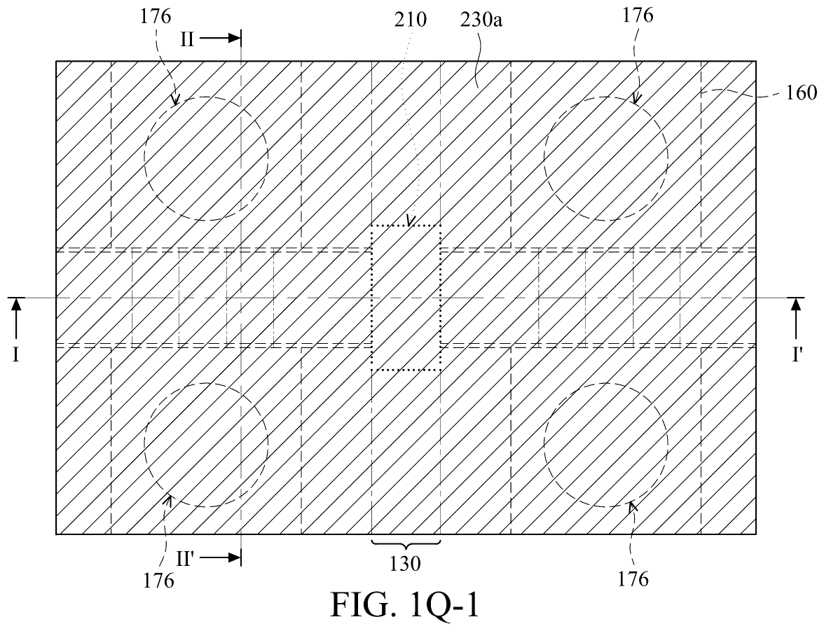

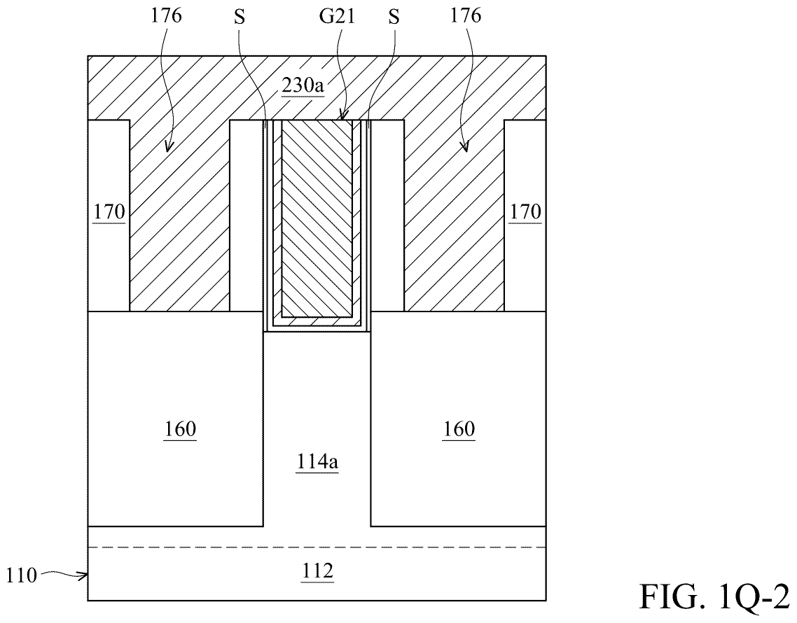

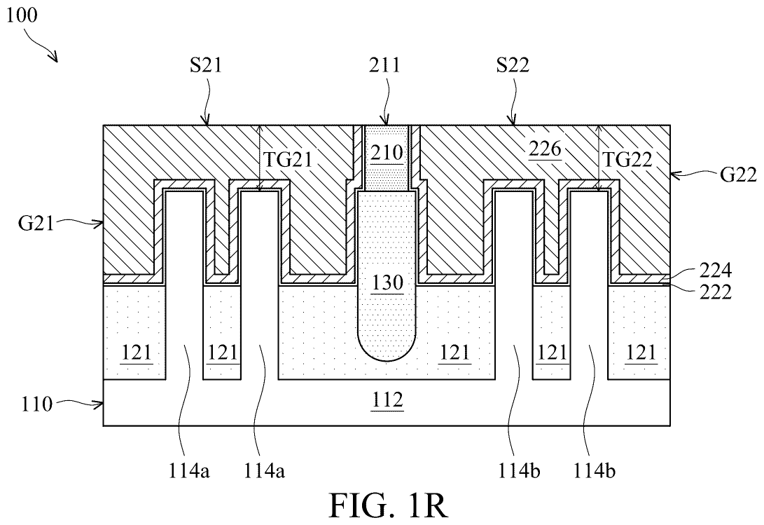

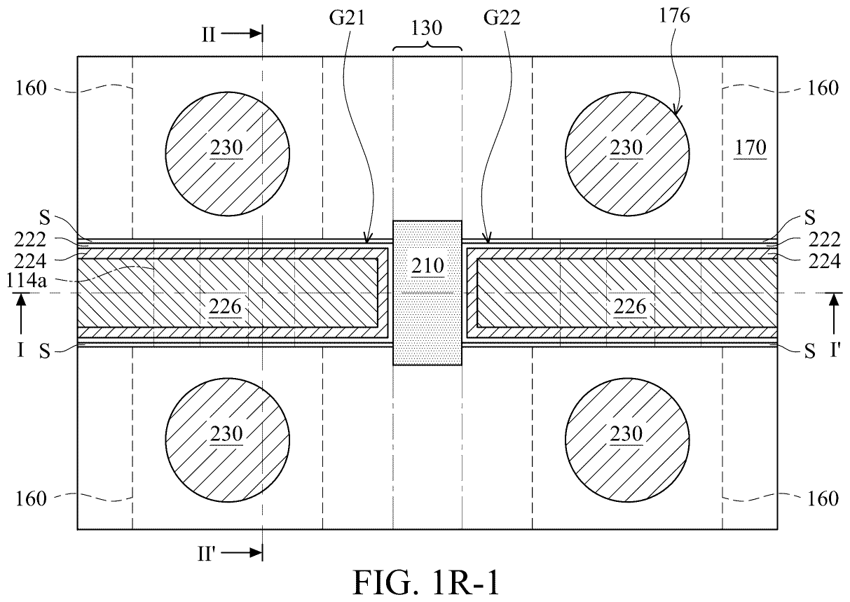

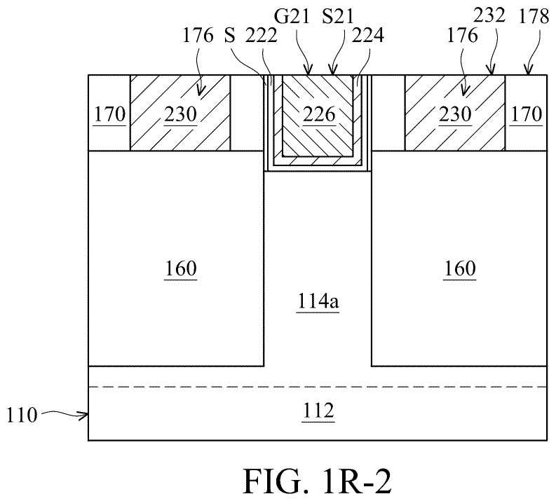

FIGS. 1A-1R are cross-sectional views of various stages of a process for forming a semiconductor structure, in accordance with some embodiments. FIG. 1A-1 is a perspective view of the semiconductor structure of FIG. 1A, in accordance with some embodiments.

As shown in FIGS. 1A and 1A-1, a substrate 110 is provided, in accordance with some embodiments. As shown in FIGS. 1A and 1A-1, the substrate 110 has a base 112 and semiconductor fin structures 114a and 114b, in accordance with some embodiments. The semiconductor fin structures 114a and 114b are over the base 112, in accordance with some embodiments.

The semiconductor fin structures 114a and 114b are spaced apart from each other, in accordance with some embodiments. In some embodiments, a distance D114 between the semiconductor fin structures 114a and 114b is greater than a distance D114a between the semiconductor fin structures 114a. In some embodiments, the distance D114 is greater than a distance D114b between the semiconductor fin structures 114b.

The substrate 110 includes, for example, a semiconductor substrate. The substrate 110 includes, for example, a semiconductor wafer (such as a silicon wafer) or a portion of a semiconductor wafer. In some embodiments, the substrate 110 is made of an elementary semiconductor material including silicon or germanium in a single crystal structure, a polycrystal structure, or an amorphous structure.

In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to define active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

FIG. 1B-1 is a perspective view of the semiconductor structure of FIG. 1B, in accordance with some embodiments. As shown in FIGS. 1B and 1B-1, an insulating material 120 is formed over the base 112 and the semiconductor fin structures 114a and 114b, in accordance with some embodiments. The semiconductor fin structures 114a and 114b are in the insulating material 120, in accordance with some embodiments.

The insulating material 120 includes an oxide-containing material (such as silicon oxide or silicon oxynitride), glass (such as borosilicate glass, phosphoric silicate glass, borophosphosilicate glass, or fluorinated silicate glass), a low-k material, a porous dielectric material, or a combination thereof, in accordance with some embodiments.

The insulating material 120 is formed using a deposition process or a spin-on process, in accordance with some embodiments. The deposition process includes a chemical vapor deposition (CVD) process, a high density plasma chemical vapor deposition process, a flowable chemical vapor deposition process, an atomic layer deposition (ALD) process, or a combination thereof, in accordance with some embodiments.

As shown in FIG. 1C, a top portion of the insulating material 120 is removed, in accordance with some embodiments. The removal process includes performing a planarization process (e.g., a chemical mechanical polishing process) on the insulating material 120 until top surfaces 114a1 and 114b1 of the semiconductor fin structures 114a and 114b are exposed, in accordance with some embodiments. After the removal process, a top surface 122 of the insulating material 120 is substantially level with top surfaces 114a1 and 114b1 of the semiconductor fin structures 114a and 114b, in accordance with some embodiments.

FIGS. 1C-1 to 1R-1 are top views of the semiconductor structures of FIGS. 1C-1R, in accordance with some embodiments. As shown in FIGS. 1C and 1C-1, the insulating material 120 between the semiconductor fin structures 114a and 114b is partially removed to form a recess 124 in the insulating material 120, in accordance with some embodiments.

The recess 124 is between the semiconductor fin structures 114a and 114b, in accordance with some embodiments. As shown in FIG. 1C-1, the recess 124 has a strip shape, in accordance with some embodiments. The removal process includes an etching process, such as a dry etching process, in accordance with some embodiments.

As shown in FIGS. 1C and 1C-1, a dielectric material 130a is formed over the semiconductor fin structures 114a and 114b and the insulating material 120 and in the recess 124 of the insulating material 120, in accordance with some embodiments. The dielectric material 130a and the insulating material 120 are different materials, in accordance with some embodiments. The dielectric material 130a is made of an etch resistance material or an insulating material, in accordance with some embodiments.

The etch resistance material includes a metal oxide material (e.g., HfO₂ or ZrO₂), a nitrogen-containing material (e.g., SiCN or SiCON), a combination thereof, or the like, in accordance with some embodiments. The insulating material includes an oxide-containing material (such as silicon oxide), a nitrogen-containing material (e.g., silicon oxynitride), a combination thereof, or another suitable insulating material having a high breakdown voltage and a low leakage current.

The dielectric material 130a is formed using a deposition process or a spin-on process, in accordance with some embodiments. The deposition process includes an atomic layer deposition (ALD) process, a chemical vapor deposition process, a high density plasma chemical vapor deposition process, a flowable chemical vapor deposition process, or a combination thereof, in accordance with some embodiments.

As shown in FIGS. 1D and 1D-1, the dielectric material 130a outside of the recess 124 of the insulating material 120 is removed, in accordance with some embodiments. The dielectric material 130a remaining in the recess 124 forms a dielectric fin structure 130, in accordance with some embodiments. The dielectric fin structure 130 is between the semiconductor fin structures 114a and 114b, in accordance with some embodiments.

After the removal process, a top surface 132 of the dielectric fin structure 130 is substantially level with (or coplanar with) the top surfaces 122, 114a1, and 114b1 of the insulating material 120 and the semiconductor fin structures 114a and 114b, in accordance with some embodiments. The removal process includes a planarization process (e.g., a chemical mechanical polishing process), in accordance with some embodiments.

As shown in FIG. 1D, a portion 125 of the insulating material 120 is between the dielectric fin structure 130 and the base 112, in accordance with some embodiments. The portion 125 separates the dielectric fin structure 130 from the base 112, in accordance with some embodiments. As shown in FIG. 1D-1, sidewalls 130s of the dielectric fin structure 130 are substantially parallel to sidewalls 114as and 114bs of the semiconductor fin structures 114a and 114b, in accordance with some embodiments.

As shown in FIGS. 1E and 1E-1, a top portion of the insulating material 120 is removed, in accordance with some embodiments. The remainder of the insulating material 120 is referred to as an isolation structure 121, in accordance with some embodiments of the disclosure. After the removal process, upper portions 130u, 114au, and 114bu of the dielectric fin structure 130 and the semiconductor fin structures 114a and 114b protrude from the top surface 122 of the isolation structure 121, in accordance with some embodiments. After the removal process, the dielectric fin structure 130 is partially embedded in the isolation structure 121, in accordance with some embodiments.

As shown in FIGS. 1F and 1F-1, a gate dielectric material layer 140a is conformally formed over the semiconductor fin structures 114a and 114b, the dielectric fin structure 130, and the isolation structure 121, in accordance with some embodiments. The gate dielectric material layer 140a is made of an oxide-containing material (e.g., silicon oxide) or another suitable insulating material. The gate dielectric material layer 140a is formed using a deposition process, such as a chemical vapor deposition process, in accordance with some embodiments.

As shown in FIGS. 1F and 1F-1, a gate electrode layer 150a is formed over the gate dielectric material layer 140a, in accordance with some embodiments. The gate electrode layer 150a is made of a semiconductor material (e.g., polysilicon) or a conductive material, in accordance with some embodiments. The gate electrode layer 150a is formed using a deposition process, such as a chemical vapor deposition process, a physical vapor deposition process, or an atomic layer deposition process, in accordance with some embodiments.

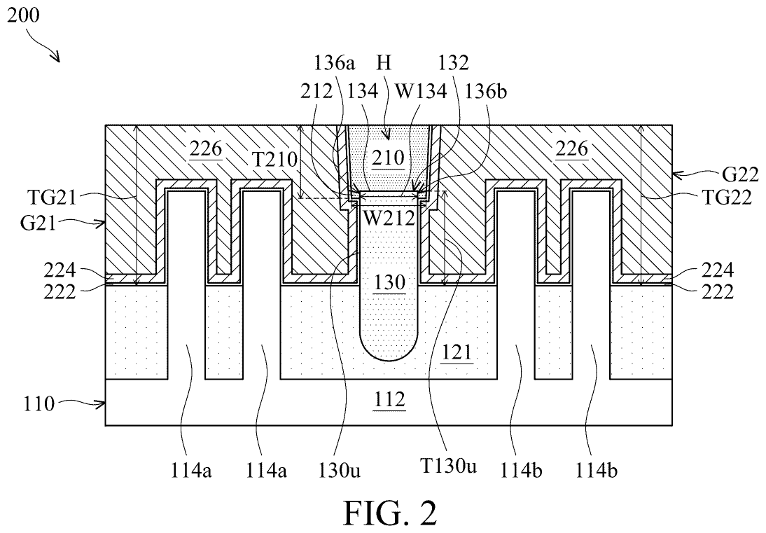

FIG. 1G-2 is a cross-sectional view illustrating the semiconductor structure along a sectional line II-II′ in FIG. 1G-1, in accordance with some embodiments. As shown in FIGS. 1G, 1G-1, and 1G-2, portions of the gate electrode layer 150a and the gate dielectric material layer 140a are removed, in accordance with some embodiments.

The remaining gate electrode layer 150a forms a dummy gate electrode layer 150, in accordance with some embodiments. The remaining gate dielectric material layer 140a forms a dummy gate dielectric layer 140, in accordance with some embodiments. The dummy gate electrode layer 150 and the dummy gate dielectric layer 140 together form a dummy gate structure G1, in accordance with some embodiments. As shown in FIG. 1G, the dummy gate structure G1 wraps around the upper portions 130u, 114au, and 114bu of the dielectric fin structure 130 and the semiconductor fin structures 114a and 114b, in accordance with some embodiments.

As shown in FIGS. 1G-1 and 1G-2, a gate spacer layer S is formed over sidewalls G1s of the dummy gate structure G1, in accordance with some embodiments. The gate spacer layer S is positioned over the semiconductor fin structures 114a and 114b, the isolation structure 121, and the dielectric fin structure 130, in accordance with some embodiments.

The gate spacer layer S includes an insulating material, such as a silicon-containing material (e.g., silicon oxide), a nitride material (e.g., silicon nitride), an oxynitride material (e.g., silicon oxynitride), or a carbide material (e.g., silicon carbide), in accordance with some embodiments. The formation of the gate spacer layer S includes a deposition process (e.g., a chemical vapor deposition process) and an anisotropic etching process, in accordance with some embodiments.

FIG. 1H-2 is a cross-sectional view illustrating the semiconductor structure along a sectional line II-II′ in FIG. 1H-1, in accordance with some embodiments. As shown in FIGS. 1H, 1H-1, and 1H-2, portions of the semiconductor fin structures 114a and 114b, which are not covered by the dummy gate structure G1 and the gate spacer layer S, are removed to form recesses 114a2 in the fin structures 114a and recesses 114b2 in the fin structures 114b, in accordance with some embodiments. The removal process includes an etching process, in accordance with some embodiments.

FIG. 1I-2 is a cross-sectional view illustrating the semiconductor structure along a sectional line II-II′ in FIG. 1I-1, in accordance with some embodiments. FIG. 1I-3 is a cross-sectional view illustrating the semiconductor structure along a sectional line III-III′ in FIG. 1I-1, in accordance with some embodiments. As shown in FIGS. 1I and 1I-1, source/drain features 160 are formed over the semiconductor fin structures 114a and 114b, in accordance with some embodiments.

As shown in FIG. 1I-1, the source/drain features 160 are on two opposite sides G1a and G1b of the dummy gate structure G1, in accordance with some embodiments. As shown in FIGS. 1I-2 and 1I-3, the source/drain features 160 are formed in the recesses 114a2 and 114b2 of the semiconductor fin structures 114a and 114b, in accordance with some embodiments. Each source/drain feature 160 is in direct contact with the fin structures 114a or 114b thereunder, in accordance with some embodiments.

In some embodiments, the source/drain features 160 are made of a P-type conductivity material. The P-type conductivity material includes silicon germanium (SiGe) or another suitable P-type conductivity material. The source/drain features 160 are doped with the Group IIIA element, in accordance with some embodiments. The Group IIIA element includes boron or another suitable material.

In some other embodiments, the source/drain features 160 are made of an N-type conductivity material, in accordance with some embodiments. The N-type conductivity material includes silicon phosphorus (SiP) or another suitable N-type conductivity material. The source/drain features 160 are doped with the Group VA element, in accordance with some embodiments. The Group VA element includes phosphor (P), antimony (Sb), or another suitable Group VA material. The source/drain features 160 are formed using an epitaxial process, in accordance with some embodiments.

FIG. 1J-2 is a cross-sectional view illustrating the semiconductor structure along a sectional line II-II′ in FIG. 1J-1, in accordance with some embodiments. FIG. 1J-3 is a cross-sectional view illustrating the semiconductor structure along a sectional line III-III′ in FIG. 1J-1, in accordance with some embodiments.

As shown in FIGS. 1J, 1J-1, 1J-2, and 1J-3, an interlayer dielectric layer 170 is formed over the source/drain features 160, the isolation structure 121, and the dielectric fin structure 130, in accordance with some embodiments. The interlayer dielectric layer 170 includes an insulating material, such as an oxide-containing material (e.g., silicon oxide), an oxynitride material (e.g., silicon oxynitride), a low-k material, a porous dielectric material, glass, or a combination thereof, in accordance with some embodiments.

The glass includes borosilicate glass (BSG), phosphoric silicate glass (PSG), borophosphosilicate glass (BPSG), fluorinated silicate glass (FSG), or a combination thereof, in accordance with some embodiments. The interlayer dielectric layer 170 is formed using a deposition process (e.g., a chemical vapor deposition process) and a planarization process (e.g., a chemical mechanical polishing process), in accordance with some embodiments.

As shown in FIGS. 1K and 1K-1, a hard mask layer 180 is formed over the dummy gate structure G1, the interlayer dielectric layer 170, and the gate spacer layer S, in accordance with some embodiments. The hard mask layer 180 and the dummy gate structure G1 are made of different materials, in accordance with some embodiments. The hard mask layer 180, the interlayer dielectric layer 170, and the gate spacer layer S are made of different materials, in accordance with some embodiments. The hard mask layer 180 is made of a nitride material (e.g., silicon nitride), an oxynitride material (e.g., silicon oxynitride), or the like, in accordance with some embodiments.

As shown in FIGS. 1K and 1K-1, a mask layer 190 is formed over the hard mask layer 180, in accordance with some embodiments. The mask layer 190 has an opening 192, in accordance with some embodiments. The opening 192 exposes a portion of the hard mask layer 180 over the dummy gate structure G1 and the dielectric fin structure 130, in accordance with some embodiments.

The mask layer 190 and the hard mask layer 180 are made of different materials, in accordance with some embodiments. The mask layer 190 is made of a polymer material, such as a photoresist material, in accordance with some embodiments.

As shown in FIGS. 1K, 1L, and 1L-1, the exposed portion of the hard mask layer 180 and the dummy gate structure G1 thereunder are removed to form a gate-cut opening H passing through the dummy gate structure G1, in accordance with some embodiments. The gate-cut opening H also passes through the gate spacer layer S and the interlayer dielectric layer 170, in accordance with some embodiments. The gate-cut opening H exposes a portion of the dielectric fin structure 130, in accordance with some embodiments.

The dielectric fin structure 130 is used as an etch stop structure in the removal process, in accordance with some embodiments. Therefore, the depth of the gate-cut opening H is able to be adjusted by adjusting the height of the dielectric fin structure 130, in accordance with some embodiments.

Although FIG. 1L only shows one gate-cut opening H and one dielectric fin structure 130, the numbers of the gate-cut opening H and the dielectric fin structure 130 are not limited thereto. In other words, there may be multiple gate-cut openings H and multiple dielectric fin structures 130. Since the depths of the gate-cut openings H are able to be adjusted by adjusting the heights of the dielectric fin structures 130, the formation of the dielectric fin structures 130 may improve the etch depth uniformity.

The dummy gate structure G1 is divided into dummy gate structures G11 and G12 by the gate-cut opening H, in accordance with some embodiments. The dummy gate structure G11 is over the fin structures 114a, in accordance with some embodiments. The dummy gate structure G12 is over the fin structures 114b, in accordance with some embodiments. The removal process includes an etching process, in accordance with some embodiments. The etching process includes a dry etching process, in accordance with some embodiments.

As shown in FIGS. 1K, 1L, and 1L-1, the mask layer 190 is removed, in accordance with some embodiments. In some embodiments, the mask layer 190 is removed during removing the exposed portion of the hard mask layer 180 and the dummy gate structure G1 thereunder.

In some other embodiments, the mask layer 190 is removed after removing the exposed portion of the hard mask layer 180 and the dummy gate structure G1 thereunder. The removal process includes an etching process, in accordance with some embodiments. The etching process includes a dry etching process or a wet etching process, in accordance with some embodiments.

As shown in FIGS. 1M and 1M-1, a gate cut isolation layer 210a is deposited over the hard mask layer 180 and in the gate-cut opening H, in accordance with some embodiments. Since the formation of the dielectric fin structure 130, the aspect ratio of the gate-cut opening H is reduced, which reduces the difficulty of the formation of the gate-cut opening H and helps to fill the gate cut isolation layer 210a into the gate-cut opening H, in accordance with some embodiments.

The depth DH of the gate-cut opening H ranges from about 100 nm to about 200 nm, in accordance with some embodiments. The width WH of the gate-cut opening H ranges from about 10 nm to about 20 nm, in accordance with some embodiments. The aspect ratio (i.e., D_{H}/W_{H}) of the gate-cut opening H ranges from about 5 to about 20, in accordance with some embodiments.

The thickness T130 of the dielectric fin structure 130 ranges from about 30 nm to about 60 nm, in accordance with some embodiments. In some embodiments, a lower portion 130a of the dielectric fin structure 130 is embedded in the isolation structure 121. The thickness T130a of the lower portion 130a ranges from about 10 nm to about 30 nm, in accordance with some embodiments. The width W130 of the dielectric fin structure 130 ranges from about 8 nm to about 20 nm, in accordance with some embodiments.

The width W114a (or W114b) of the fin structure 114a (or 114b) ranges from about 5 nm to about 20 nm, in accordance with some embodiments. The thickness T114a (or T114b) of the fin structure 114a (or 114b) ranges from about 40 nm to about 70 nm, in accordance with some embodiments.

In some embodiments, the gate cut isolation layer 210a and the dielectric fin structure 130 are made of different materials. In some other embodiments, the gate cut isolation layer 210a and the dielectric fin structure 130 are made of the same material.

The gate cut isolation layer 210a is made of an insulating material, such as an oxide-containing material (such as silicon oxide), a nitrogen-containing material (e.g., silicon nitride or silicon oxynitride), a carbon-containing material (e.g., silicon carbide), a combination thereof, or another insulating material having a high breakdown voltage and a low leakage current.

The gate cut isolation layer 210a is formed using a deposition process or a spin-on process (e.g., a spin-on sol-gel process), in accordance with some embodiments. The deposition process includes an atomic layer deposition (ALD) process, a chemical vapor deposition process, a high density plasma chemical vapor deposition process, a flowable chemical vapor deposition process, or a combination thereof, in accordance with some embodiments.

As shown in FIGS. 1N and 1N-1, the gate cut isolation layer 210a outside of the gate-cut opening H and the hard mask layer 180 are removed, in accordance with some embodiments. The gate cut isolation layer 210a remaining in the gate-cut opening H forms a gate cut isolation structure 210, in accordance with some embodiments. The gate cut isolation structure 210 is between the dummy gate structures G11 and G12 and between the source/drain features 160, in accordance with some embodiments.

The gate cut isolation structure 210 is in direct contact with the dummy gate structures G11 and G12 (i.e., the dummy gate electrode layer 150 and the dummy gate dielectric layer 140), the gate spacer layer S, and the interlayer dielectric layer 170, in accordance with some embodiments. The dielectric fin structure 130 separates the gate cut isolation structure 210 from the isolation structure 121, in accordance with some embodiments.

The dielectric fin structure 130 and the gate cut isolation structure 210 collectively separate the dummy gate structure G11 from the dummy gate structure G12, in accordance with some embodiments. The dielectric fin structure 130 and the gate cut isolation structure 210 electrically insulate the dummy gate structure G11 from the dummy gate structure G12, in accordance with some embodiments. The dielectric fin structure 130 and the gate cut isolation structure 210 are used as a gate line-end definition structure, in accordance with some embodiments.

The dielectric fin structure 130 is longer than the gate cut isolation structure 210 as measured in a longitudinal direction A114a of the fin structures 114a, in accordance with some embodiments. That is, the length L130 of the dielectric fin structure 130 is greater than the length L210 of the gate cut isolation structure 210, in accordance with some embodiments.

The length L130 is greater than the length LG of the dummy gate structure G11 or G12, in accordance with some embodiments. The length L210 is greater than the length LG of the dummy gate structure G11 or G12, in accordance with some embodiments. The removal process includes a planarization process, such as a chemical mechanical polishing process, in accordance with some embodiments.

As shown in FIGS. 1O and 1O-1, the dummy gate structures G11 and G12 are removed, in accordance with some embodiments. The removal process includes an etching process, such as a wet etching process, in accordance with some embodiments.

After the removal process, gate trenches S1 and S2 are formed in the gate spacer layer S, in accordance with some embodiments. The gate trench S1 exposes the upper portions 114au and 130u of the semiconductor fin structures 114a and the dielectric fin structure 130, in accordance with some embodiments. The gate trench S2 exposes the upper portions 114bu and 130u of the semiconductor fin structures 114b and the dielectric fin structure 130, in accordance with some embodiments.

As shown in FIG. 1O, a gate dielectric layer 222 is formed over the isolation structure 121, the semiconductor fin structures 114a and 114b, and the gate cut isolation structures 210 and 130, in accordance with some embodiments. The gate dielectric layer 222 is made of silicon oxide, silicon nitride, silicon oxynitride, a dielectric material with high dielectric constant (high-K), another suitable dielectric material, or a combination thereof.

Examples of high-K dielectric materials include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, another suitable high-K material, or a combination thereof. The gate dielectric layer 222 is formed using a deposition process, such as a CVD process or a PVD process, in accordance with some embodiments.

As shown in FIG. 1O, a work function metal layer 224 is formed over the gate dielectric layer 222, in accordance with some embodiments. The work function metal layer 224 provides a desired work function for transistors to enhance device performance including improved threshold voltage.

In the embodiments of forming an NMOS transistor, the work function metal layer 224 can be an n-type metal capable of providing a work function value suitable for the device, such as equal to or less than about 4.5 eV. The n-type metal may be made of metal, metal carbide, metal nitride, or a combination thereof. For example, the n-type metal is made of tantalum, tantalum nitride, or a combination thereof.

In the embodiments of forming a PMOS transistor, the work function metal layer 224 can be a p-type metal capable of providing a work function value suitable for the device, such as equal to or greater than about 4.8 eV. The p-type metal may be made of metal, metal carbide, metal nitride, other suitable materials, or a combination thereof.

For example, the p-type metal is made of titanium, titanium nitride, other suitable materials, or a combination thereof. The work function metal layer 224 is formed using a deposition process, in accordance with some embodiments. The deposition process includes a PVD process, a CVD process, an ALD process, another suitable method, or a combination thereof.

Afterwards, as shown in FIGS. 1O and 1O-1, a gate electrode layer 226 (also called a metal gate electrode layer) is formed over the work function metal layer 224 to fill the gate trenches S1 and S2, in accordance with some embodiments. The gate electrode layer 226 is made of a suitable metal material, such as aluminum, tungsten, gold, platinum, cobalt, another suitable metal, an alloy thereof, or a combination thereof, in accordance with some embodiments.

The gate electrode layer 226 is formed using a deposition process, in accordance with some embodiments. The deposition process includes a PVD process, a CVD process, an ALD process, another suitable method, or a combination thereof.

FIG. 1P-2 is a cross-sectional view illustrating the semiconductor structure along a sectional line II-II′ in FIG. 1P-1, in accordance with some embodiments. As shown in FIGS. 1P, 1P-1, and 1P-2, the gate dielectric layer 222, the work function metal layer 224, and the gate electrode layer 226 outside of the gate trenches S1 and S2 of the gate spacer layer S are removed, in accordance with some embodiments.

The gate electrode layer 226, the work function metal layer 224, and the gate dielectric layer 222 remaining in the gate trench S1 together form a gate stack G21, in accordance with some embodiments. The gate electrode layer 226, the work function metal layer 224, and the gate dielectric layer 222 remaining in the gate trench S2 together form a gate stack G22, in accordance with some embodiments.

As shown in FIG. 1P, the gate stack G21 wraps around the upper portions 114au of the semiconductor fin structures 114a, in accordance with some embodiments. The gate stack G22 wraps around the upper portions 114bu of the semiconductor fin structures 114b, in accordance with some embodiments. The upper portion 130u of the dielectric fin structure 130 is between the gate stacks G21 and G22, in accordance with some embodiments.

As shown in FIG. 1P, a sum of the thickness T130u of the upper portion 130u of the dielectric fin structure 130 and the thickness T210 of the gate cut isolation structure 210 is substantially equal to the thickness TG21 or TG22 of the gate stack G21 or G22, in accordance with some embodiments.

The dielectric fin structure 130 and the gate cut isolation structure 210 electrically insulate the gate stack G21 from the gate stack G22, in accordance with some embodiments. The dielectric fin structure 130 and the gate cut isolation structure 210 are used as a metal gate line-end definition structure, in accordance with some embodiments. As shown in FIG. 1P-1, the dielectric fin structure 130 is longer than both the gate stacks G21 and G22 as measured in the longitudinal direction A114a of the fin structures 114a, in accordance with some embodiments. The gate cut isolation structure 210 is longer than both the gate stacks G21 and G22, in accordance with some embodiments.

That is, the length L130 of the dielectric fin structure 130 is greater than the length LG21 or LG22 of the gate stack G21 or G22, which ensures the electrical isolation between the gate stacks G21 and G22, in accordance with some embodiments. The length L210 of the gate cut isolation structure 210 is greater than the length LG21 or LG22 of the gate stack G21 or G22, which ensures the electrical isolation between the gate stacks G21 and G22, in accordance with some embodiments.

As shown in FIGS. 1P-1 and 1P-2, portions of the interlayer dielectric layer 170 are removed to form through holes 176 in the interlayer dielectric layer 170, in accordance with some embodiments. The through holes 176 pass through the interlayer dielectric layer 170 and expose the source/drain features 160 thereunder, in accordance with some embodiments. The removal process includes an etching process, such as a dry etching process, in accordance with some embodiments.

FIG. 1Q-2 is a cross-sectional view illustrating the semiconductor structure along a sectional line II-II′ in FIG. 1Q-1, in accordance with some embodiments. As shown in FIGS. 1Q, 1Q-1, and 1Q-2, a conductive layer 230a is formed in the through holes 176 and over the gate stacks G21 and G22, the gate cut isolation structure 210, and the interlayer dielectric layer 170, in accordance with some embodiments.

The conductive layer 230a is made of a suitable conductive material, such as a metal material (e.g., aluminum, tungsten, gold, platinum, cobalt, another suitable metal, an alloy thereof, or a combination thereof), in accordance with some embodiments. The conductive layer 230a is formed using a deposition process (e.g., a CVD process or a PVD process) or a plating process, in accordance with some embodiments.

FIG. 1R-2 is a cross-sectional view illustrating the semiconductor structure along a sectional line II-II′ in FIG. 1R-1, in accordance with some embodiments. As shown in FIGS. 1R, 1R-1, and 1R-2, the conductive layer 230a outside of the through holes 176 and the upper portions of the interlayer dielectric layer 170, the conductive layer 230a, and the gate stacks G21 and G22 are removed, in accordance with some embodiments.

After the removal process, the conductive layer 230a remaining in the through holes 176 forms contact plugs 230, in accordance with some embodiments. The contact plugs 230 pass through the interlayer dielectric layer 170, in accordance with some embodiments. Each contact plug 230 is electrically connected to the source/drain feature 160 thereunder, in accordance with some embodiments.

As shown in FIGS. 1R, 1R-1, and 1R-2, the top surfaces 211, S21, S22, 232, and 178 of the gate cut isolation structure 210, the gate stacks G21 and G22, the contact plugs 230, and the interlayer dielectric layer 170 are substantially level with each other, in accordance with some embodiments.

As shown in FIG. 1R, the thickness TG21 of the gate stack G21 over the fin structures 114a ranges from about 8 nm to about 20 nm, in accordance with some embodiments. As shown in FIG. 1R, the thickness TG22 of the gate stack G22 over the fin structures 114b ranges from about 8 nm to about 20 nm, in accordance with some embodiments.

The removal process includes a planarization process, such as a chemical mechanical polishing process, in accordance with some embodiments. In this step, a semiconductor structure 100 is substantially formed, in accordance with some embodiments.

FIG. 2 is a cross-sectional view of a semiconductor structure 200, in accordance with some embodiments. As shown in FIG. 2, the semiconductor structure 200 is similar to the semiconductor structure 100 of FIG. 1R. One difference is that a top portion 134 of the dielectric fin structure 130 extends into a bottom portion 212 of the gate cut isolation structure 210, in accordance with some embodiments.

The width W134 of the top portion 134 is less than the width W212 of the bottom portion 212, in accordance with some embodiments. The gate-cut opening H exposes the top surface 132 and sidewalls 136a and 136b of the dielectric fin structure 130, in accordance with some embodiments. The sidewall 136a faces the gate stack G21, in accordance with some embodiments. The sidewall 136b faces the gate stack G22, in accordance with some embodiments.

The sum of the thickness T130u of the upper portion 130u of the dielectric fin structure 130 and the thickness T210 of the gate cut isolation structure 210 is greater than the thickness TG21 or TG22 of the gate stack G21 or G22, in accordance with some embodiments.

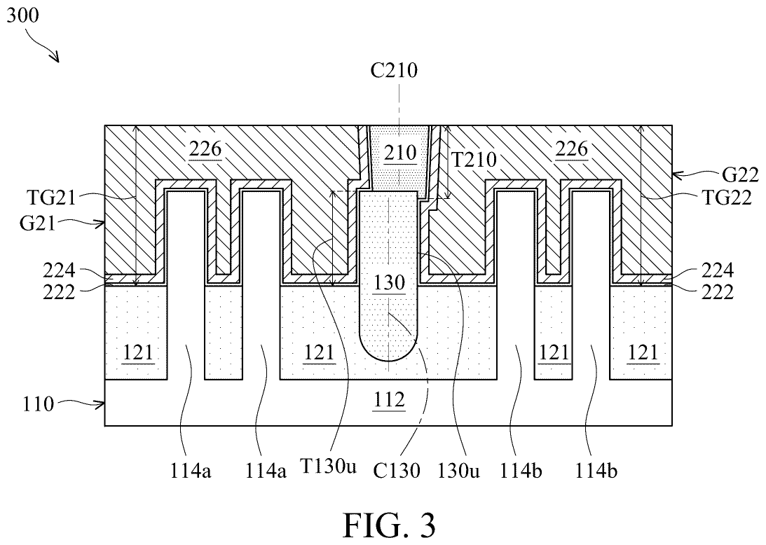

FIG. 3 is a cross-sectional view of a semiconductor structure 300, in accordance with some embodiments. As shown in FIG. 3, the semiconductor structure 300 is similar to the semiconductor structure 100 of FIG. 1R. One difference is that the central axis C130 of the dielectric fin structure 130 is misaligned with the central axis C210 of the gate cut isolation structure 210, in accordance with some embodiments.

The sum of the thickness T130u of the upper portion 130u of the dielectric fin structure 130 and the thickness T210 of the gate cut isolation structure 210 is greater than the thickness TG21 or TG22 of the gate stack G21 or G22, in accordance with some embodiments.

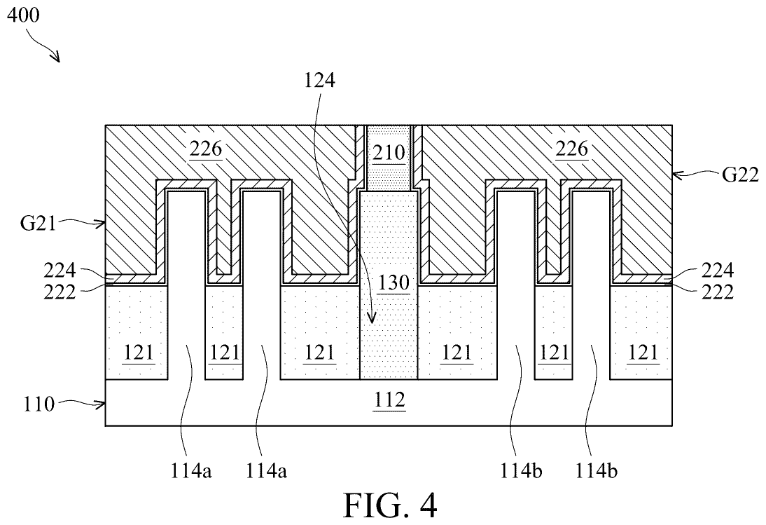

FIG. 4 is a cross-sectional view of a semiconductor structure 400, in accordance with some embodiments. As shown in FIG. 4, the semiconductor structure 400 is similar to the semiconductor structure 100 of FIG. 1R. One difference is that the dielectric fin structure 130 passes through the insulating material 121, which may improve the electrical isolation of the gate stack G21 from the gate stack G22, in accordance with some embodiments.

The dielectric fin structure 130 is in direct contact with the base 112 of the substrate 110, in accordance with some embodiments. The recess 124 of the insulating material 120 (FIG. 1C) passes through the insulating material 120, in accordance with some embodiments.

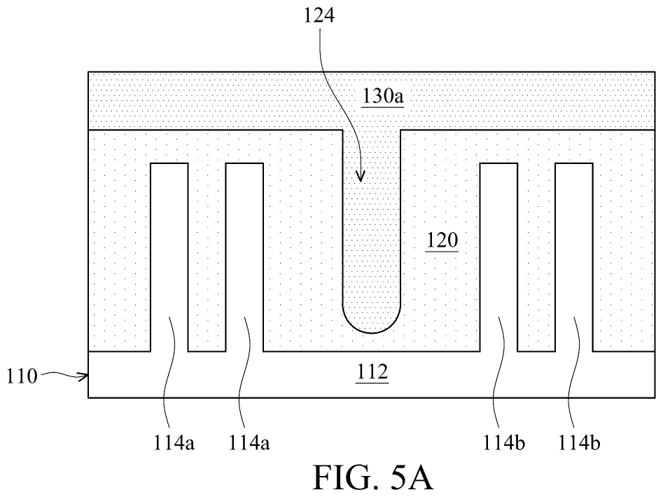

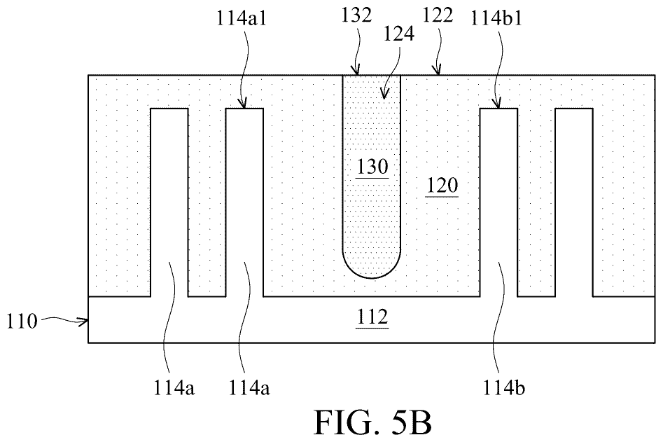

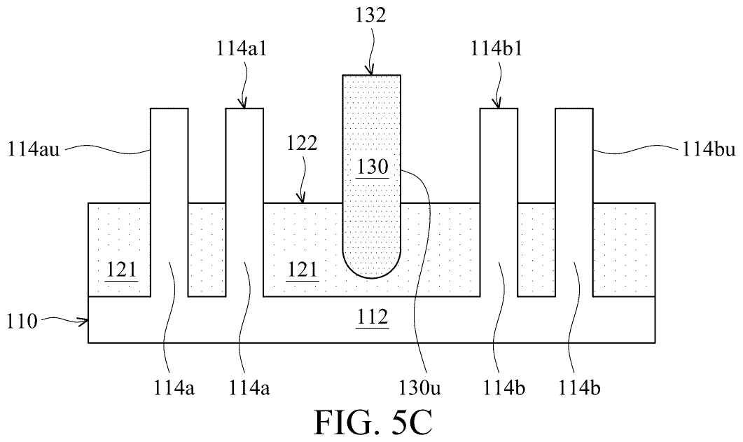

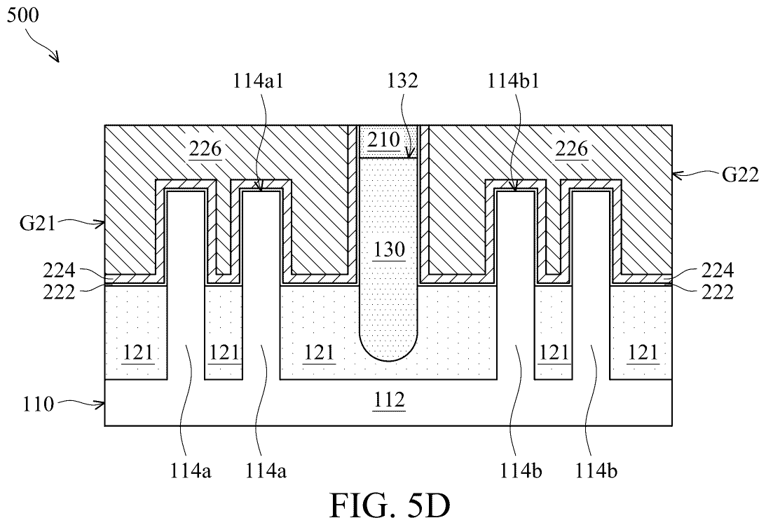

FIGS. 5A-5D are cross-sectional views of various stages of a process for forming a semiconductor structure, in accordance with some embodiments. As shown in FIG. 5A, after the step of FIG. 1B, the insulating material 120 between the semiconductor fin structures 114a and 114b is partially removed to form a recess 124 in the insulating material 120, in accordance with some embodiments.

The recess 124 is between the semiconductor fin structures 114a and 114b, in accordance with some embodiments. As shown in FIG. 5A, a dielectric material 130a is formed over the insulating material 120 and in the recess 124 of the insulating material 120, in accordance with some embodiments.

As shown in FIGS. 5A and 5B, the dielectric material 130a outside of the recess 124 of the insulating material 120 is removed, in accordance with some embodiments. The dielectric material 130a remaining in the recess 124 forms a dielectric fin structure 130, in accordance with some embodiments.

The top surface 132 of the dielectric fin structure 130 is higher than the top surfaces 114a1 and 114b1 of the semiconductor fin structures 114a and 114b, in accordance with some embodiments. The top surface 122 of the insulating material 120 is higher than the top surfaces 114a1 and 114b1 of the semiconductor fin structures 114a and 114b, in accordance with some embodiments.

As shown in FIG. 5C, a top portion of the insulating material 120 is removed to from an isolation structure 121, in accordance with some embodiments. After the removal process, upper portions 130u, 114au, and 114bu of the dielectric fin structure 130 and the semiconductor fin structures 114a and 114b protrude from the top surface 122 of the isolation structure 121, in accordance with some embodiments.

As shown in FIG. 5D, the steps of FIGS. 1F-1R are performed to form a semiconductor structure 500, in accordance with some embodiments. Since the top surface 132 of the dielectric fin structure 130 is higher than the top surfaces 114a1 and 114b1 of the semiconductor fin structures 114a and 114b, the formation of the dielectric fin structure 130 greatly reduces the aspect ratio of the trench used to accommodate the gate cut isolation structure 210, in accordance with some embodiments. The placement variation between the gate cut isolation structure 210 and the dielectric fin structure 130 as discussed in FIGS. 2-4 may also be included in the embodiments as illustrated in FIG. 5D, in accordance with some embodiments. Therefore, the formation of the dielectric fin structure 130 improves the yield of the gate cut isolation structure 210, in accordance with some embodiments.

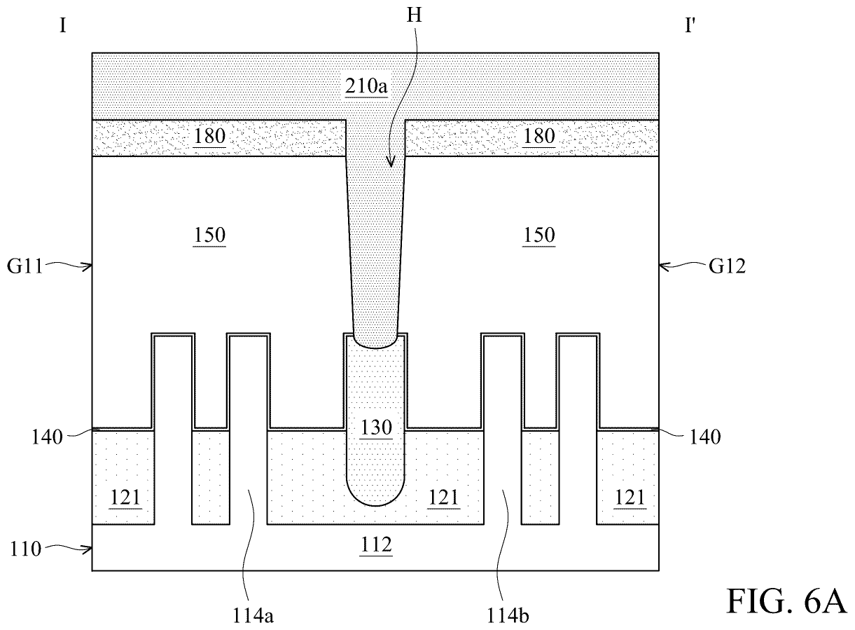

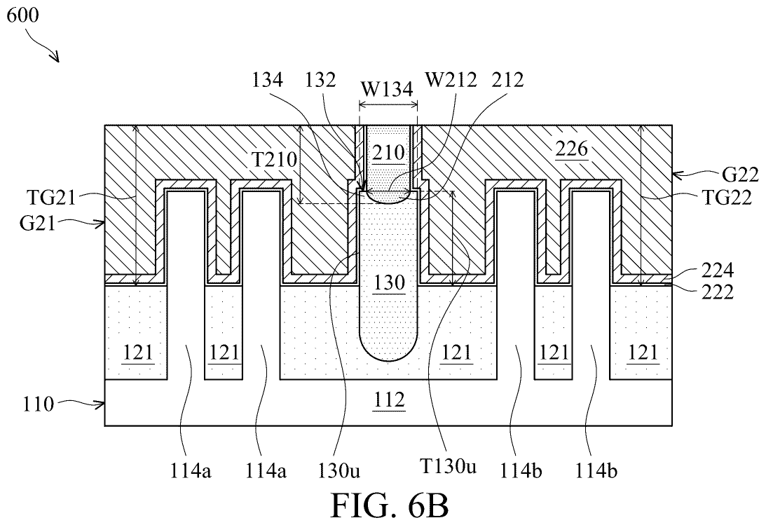

FIGS. 6A-6B are cross-sectional views of various stages of a process for forming a semiconductor structure, in accordance with some embodiments. As shown in FIGS. 1K and 6A, the step of FIG. 1L is performed to partially remove the exposed portion of the hard mask layer 180, the dummy gate structure G1 thereunder, and the dielectric fin structure 130 thereunder so as to form a gate-cut opening H passing through the dummy gate structure G1 and extending into the dielectric fin structure 130, in accordance with some embodiments.

As shown in FIG. 6B, the steps of FIGS. 1M-1R are performed to form a semiconductor structure 600, in accordance with some embodiments. In the semiconductor structure 600, the bottom portion 212 of the gate cut isolation structure 210 extends into the top portion 134 of the dielectric fin structure 130, in accordance with some embodiments. The width W134 of the top portion 134 is greater than the width W212 of the bottom portion 212, in accordance with some embodiments.

The sum of the thickness T130u of the upper portion 130u of the dielectric fin structure 130 and the thickness T210 of the gate cut isolation structure 210 is greater than the thickness TG21 or TG22 of the gate stack G21 or G22, in accordance with some embodiments. The placement variation between the gate cut isolation structure 210 and the dielectric fin structure 130 as discussed in FIGS. 2-5D may also be included in the embodiments as illustrated in FIG. 6B, in accordance with some embodiments.

Processes and materials for forming the semiconductor structures 200, 300, 400, 500 and 600 may be similar to, or the same as, those for forming the semiconductor structure 100 described above. Elements with the same or similar structures and/or materials as those in FIGS. 1A to 6B are labeled with the same reference numbers. Therefore, their detailed descriptions will not be repeated herein.

In accordance with some embodiments, semiconductor structures and methods for forming the same are provided. The methods (for forming the semiconductor structure) include: forming a dielectric fin structure partially in the insulating material between a first semiconductor fin structure and a second semiconductor fin structure; forming a gate structure over the first semiconductor fin structure, the dielectric fin structure, and the second semiconductor fin structure; and removing the gate structure over the dielectric fin structure to form an opening in the gate structure. The gate structure is divided into a first gate structure and a second gate structure by the opening. Due to the formation of the dielectric fin structure, the gate structure over the dielectric fin structure is thinner than other portions of the gate structure. Therefore, the formation of the dielectric fin structure reduces the aspect ratio of the opening, which helps the formation of the opening and helps to fill a gate cut isolation structure into the opening.

In accordance with some embodiments, a semiconductor structure is provided. The semiconductor structure includes a substrate having a base, a first semiconductor fin structure, and a second semiconductor fin structure over the base. The semiconductor structure includes an isolation structure over the base. The first semiconductor fin structure and the second semiconductor fin structure are partially in the isolation structure. The semiconductor structure includes a first gate stack wrapping around the first semiconductor fin structure. The semiconductor structure includes a second gate stack wrapping around the second semiconductor fin structure. The semiconductor structure includes a dielectric fin structure partially embedded in the isolation structure. An upper portion of the dielectric fin structure is between the first gate stack and the second gate stack. The semiconductor structure includes a gate cut isolation structure over the dielectric fin structure and separating the first gate stack from the second gate stack. In some embodiments, the dielectric fin structure is longer than both the first gate stack and the second gate stack as measured in a longitudinal direction of the first semiconductor fin structure. In some embodiments, the gate cut isolation structure is longer than both the first gate stack and the second gate stack. In some embodiments, the dielectric fin structure is longer than the gate cut isolation structure. In some embodiments, a sum of a first thickness of the upper portion of the dielectric fin structure and a second thickness of the gate cut isolation structure is substantially equal to a third thickness of the first gate stack. In some embodiments, a first top surface of the dielectric fin structure is substantially level with a second top surface of the first semiconductor fin structure. In some embodiments, a first sidewall of the dielectric fin structure is substantially parallel to a second sidewall of the first semiconductor fin structure in a top view of the dielectric fin structure and the first semiconductor fin structure. In some embodiments, a first top surface of the dielectric fin structure is higher than a second top surface of the first semiconductor fin structure. In some embodiments, a portion of the isolation structure is between the dielectric fin structure and the base.

In accordance with some embodiments, a semiconductor structure is provided. The semiconductor structure includes a substrate having a base, a first semiconductor fin structure, and a second semiconductor fin structure over the base. The semiconductor structure includes an isolation structure over the base. The first semiconductor fin structure and the second semiconductor fin structure are partially in the isolation structure. The semiconductor structure includes a dielectric fin structure partially embedded in the isolation structure and between the first semiconductor fin structure and the second semiconductor fin structure. The semiconductor structure includes a first gate stack wrapping around the first semiconductor fin structure and over a first side of the dielectric fin structure. The semiconductor structure includes a second gate stack wrapping around the second semiconductor fin structure and over a second side of the dielectric fin structure. The semiconductor structure includes a gate cut isolation structure over the dielectric fin structure. The dielectric fin structure and the gate cut isolation structure electrically insulate the first gate stack from the second gate stack. In some embodiments, the dielectric fin structure has an upper portion between the first gate stack and the second gate stack, and a sum of a first thickness of the upper portion and a second thickness of the gate cut isolation structure is greater than a third thickness of the first gate stack. In some embodiments, a bottom portion of the gate cut isolation structure extends into the dielectric fin structure. In some embodiments, a top portion of the dielectric fin structure extends into the gate cut isolation structure. In some embodiments, the dielectric fin structure passes through the isolation structure.

In accordance with some embodiments, a method for forming a semiconductor structure is provided. The method includes providing a substrate having a base, a first semiconductor fin structure, and a second semiconductor fin structure over the base. The method includes forming an insulating material over the base. The first semiconductor fin structure and the second semiconductor fin structure are in the insulating material. The method includes partially removing the insulating material between the first semiconductor fin structure and the second semiconductor fin structure to form a recess in the insulating material. The method includes forming a dielectric fin structure in the recess of the insulating material. The method includes removing a top portion of the insulating material. The method includes forming a first gate structure wrapping around a first upper portion of the dielectric fin structure, a second upper portion of the first semiconductor fin structure, and a third upper portion of the second semiconductor fin structure. The method includes partially removing the first gate structure to form an opening passing through the first gate structure and exposing the dielectric fin structure. The first gate structure is divided into a second gate structure and a third gate structure by the opening. The method includes forming a gate cut isolation structure in the opening. In some embodiments, a first top surface of the insulating material is substantially level with a second top surface of the first semiconductor fin structure during forming the dielectric fin structure in the recess of the insulating material. In some embodiments, a first top surface of the insulating material is higher than a second top surface of the first semiconductor fin structure during forming the dielectric fin structure in the recess of the isolation structure. In some embodiments, the method also includes partially removing the dielectric fin structure through the opening of the first gate structure after partially removing the first gate structure. In some embodiments, the opening of the first gate structure exposes a top surface and a sidewall of the dielectric fin structure, and the sidewall faces the second gate structure. In some embodiments, the recess of the insulating material passes through the insulating material.

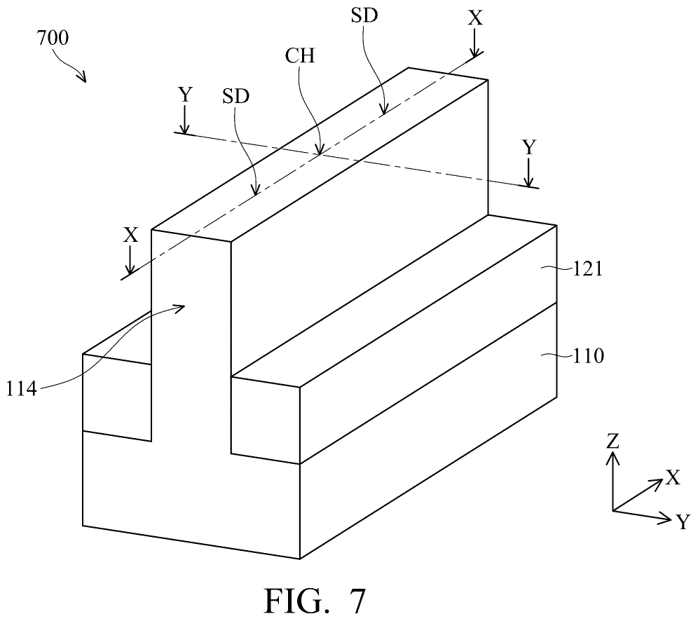

FIG. 7 is a perspective view of a semiconductor structure 700, in accordance with some embodiments. The semiconductor structure 700 includes a substrate 110, and a semiconductor fin structure 114 and an isolation structure 121 over the substrate 110, in accordance with some embodiments. Although one semiconductor fin structure 114 is illustrated in FIG. 7, more than one semiconductor fin structure 114 may be formed over the substrate 110.

For a better understanding of the semiconductor structure, X-Y-Z coordinate reference is provided in the figures of the present disclosure. X-axis and Y-axis are generally orientated along the lateral (or horizontal) directions that are parallel to the main surface of the substrate 110. Y-axis is transverse (e.g., substantially perpendicular) to the X-axis. Z-axis is generally oriented along the vertical direction that is perpendicular to the main surface of the substrate 110 (or the X-Y plane).

The semiconductor fin structure 114 extends in the X direction, in accordance with some embodiments. That is, the semiconductor fin structure 114 has a longitudinal axis parallel to the X direction, in accordance with some embodiments. X direction may also be referred to as the channel-extending direction. The current of the resulting semiconductor device (e.g., FinFET) flows in the X direction through the channel.

The semiconductor fin structure 114 includes a channel region CH and source/drain regions SD, where the channel region CH is defined between the source/drain regions SD, in accordance with some embodiments. In this disclosure, a source/drain refers to a source and/or a drain. It should be noted that in the present disclosure, a source and a drain are used interchangeably and the structures thereof are substantially the same. FIG. 7 shows one channel region CH and two source/drain regions SD for illustrative purposes and is not intended to be limiting. The number of channel regions CH and source/drain regions SD may be dependent on the demands on the design of the semiconductor device and/or performance considerations. A gate structure or gate stack (not shown) will be formed with a longitudinal axis parallel to the Y direction and extending across and/or surrounding the channel region CH of the semiconductor fin structure 114. Y direction may also be referred to as a gate-extending direction.

FIG. 7 further illustrates a reference cross-section that is used in later figures. Cross-section X-X is in a plane parallel to the longitudinal axis (X direction) of the semiconductor fin structure 114 and through the semiconductor fin structure 114, in accordance with some embodiments. Cross-section Y-Y is in a plan parallel to the longitudinal axis (Y direction) of the gate structure and through the gate structure, in accordance with some embodiments.

FIGS. 8A-1 through 8L-5 are schematic views illustrating the formation of a semiconductor structure 700 at various intermediate stages, in accordance with some embodiments of the disclosure.

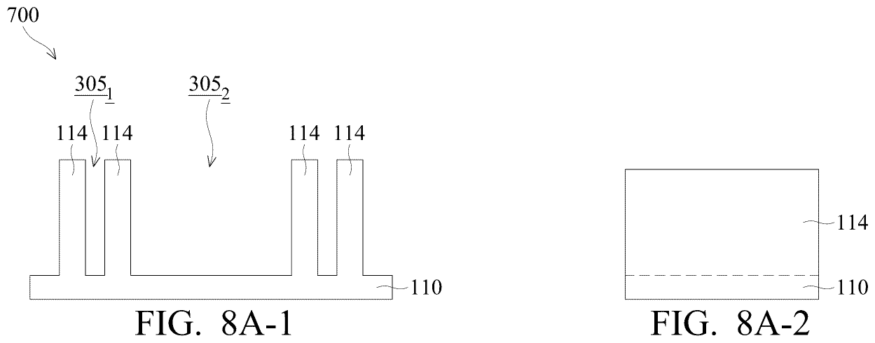

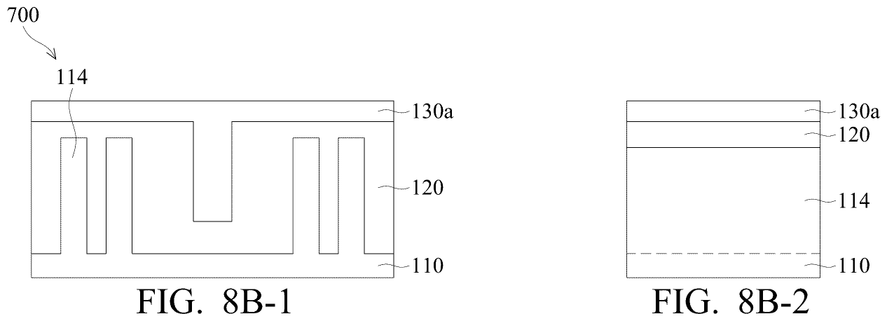

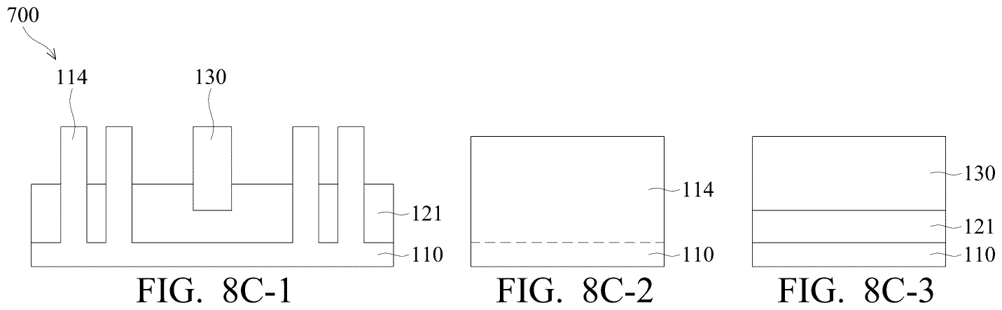

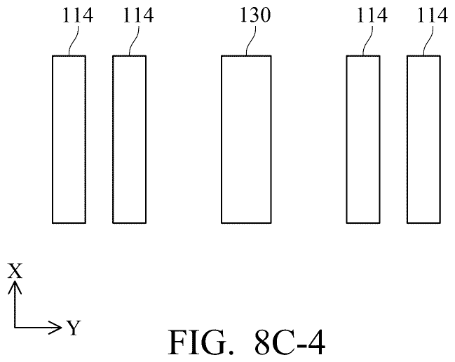

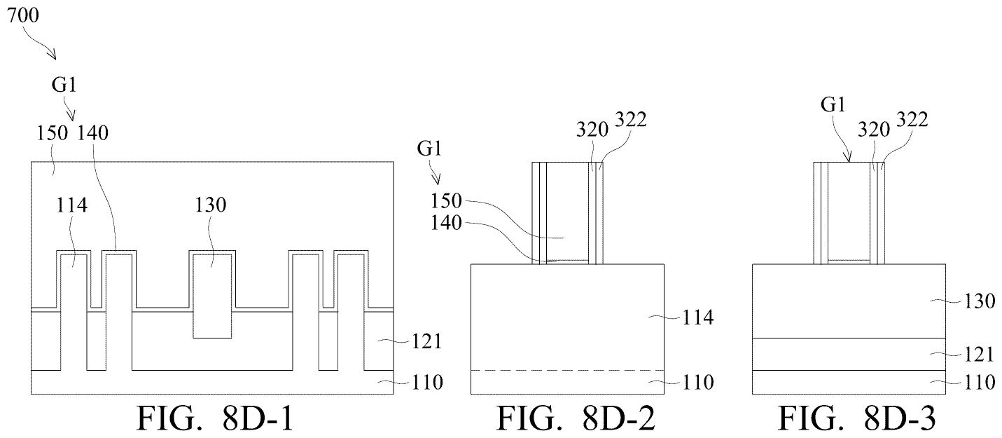

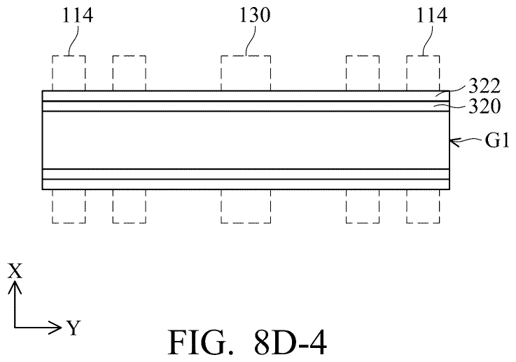

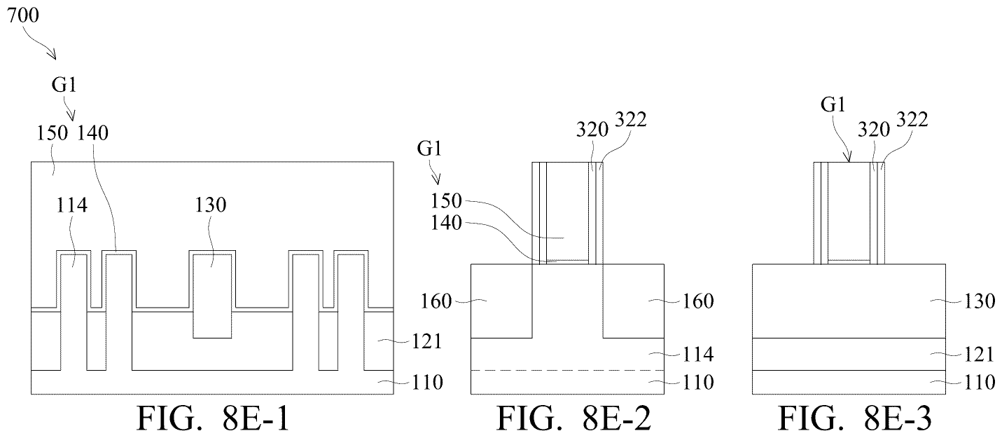

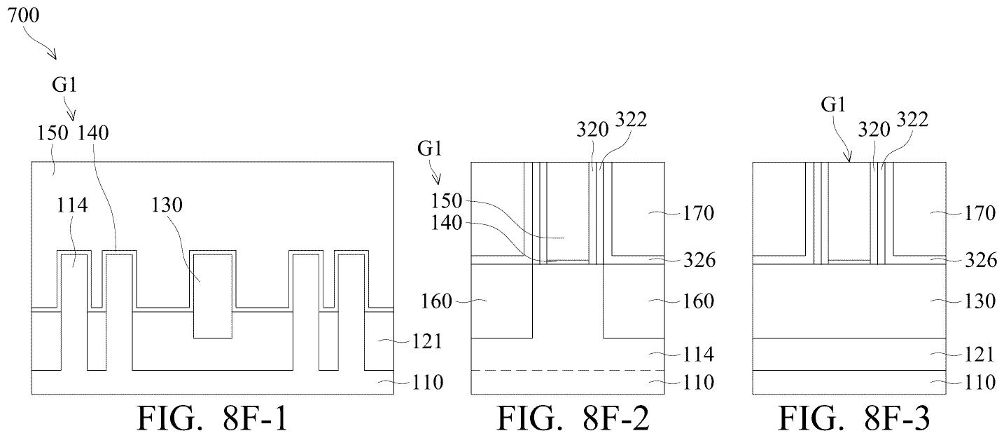

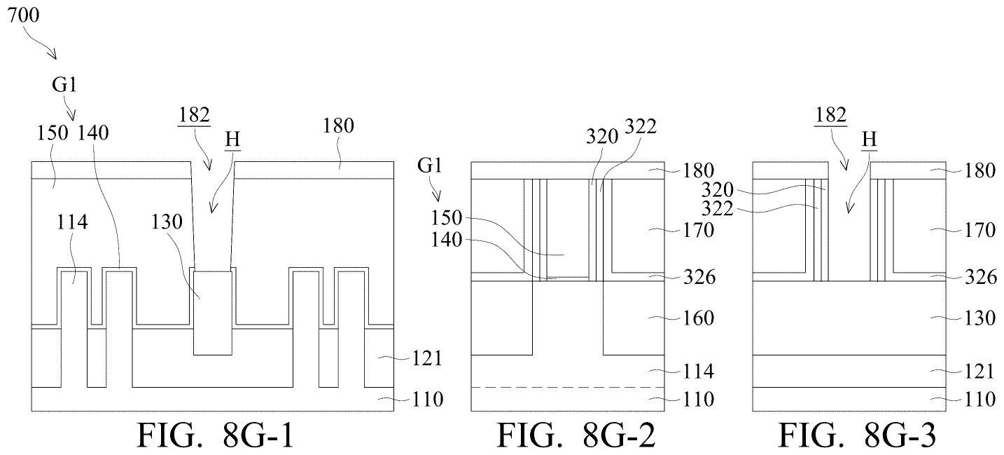

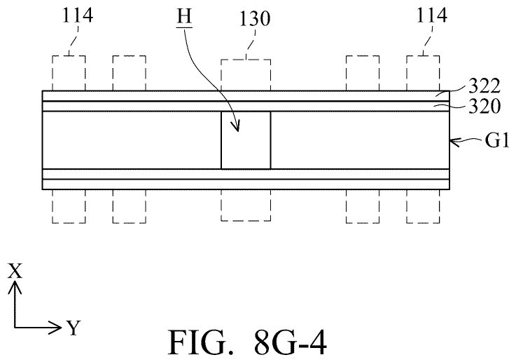

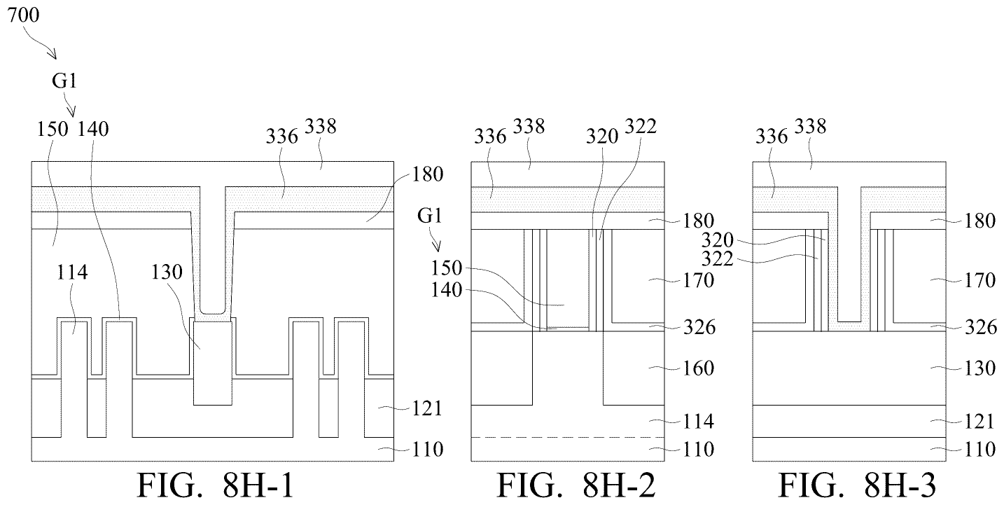

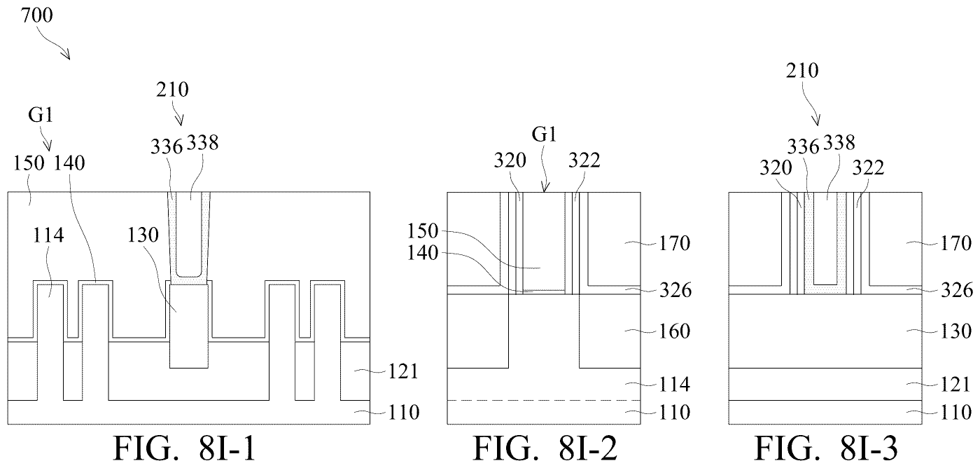

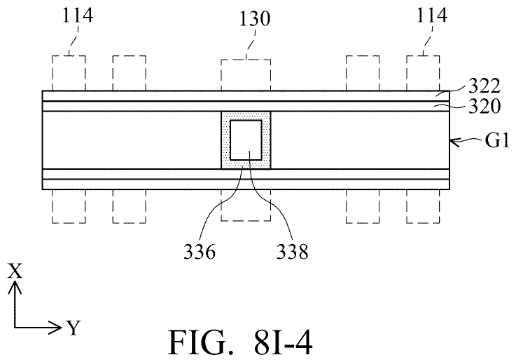

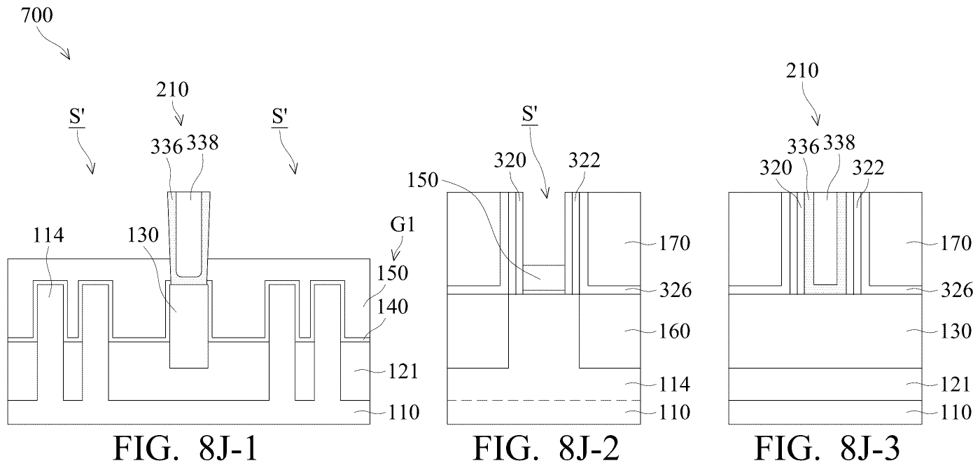

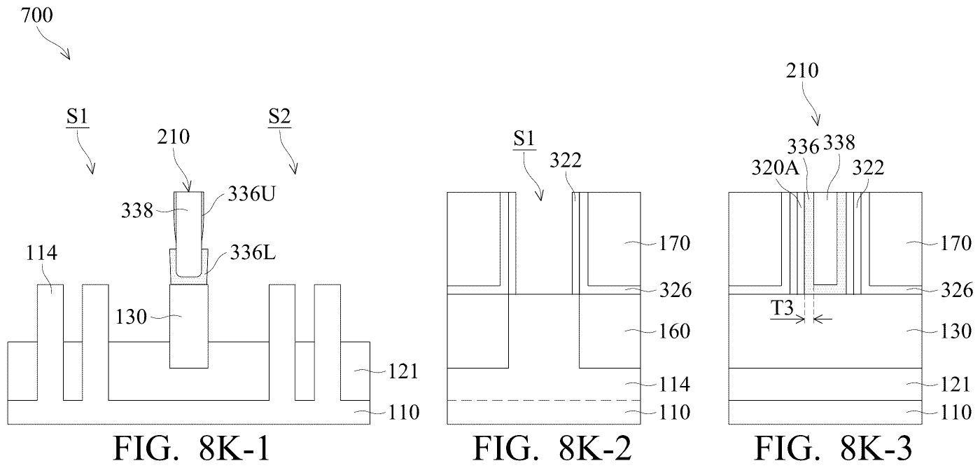

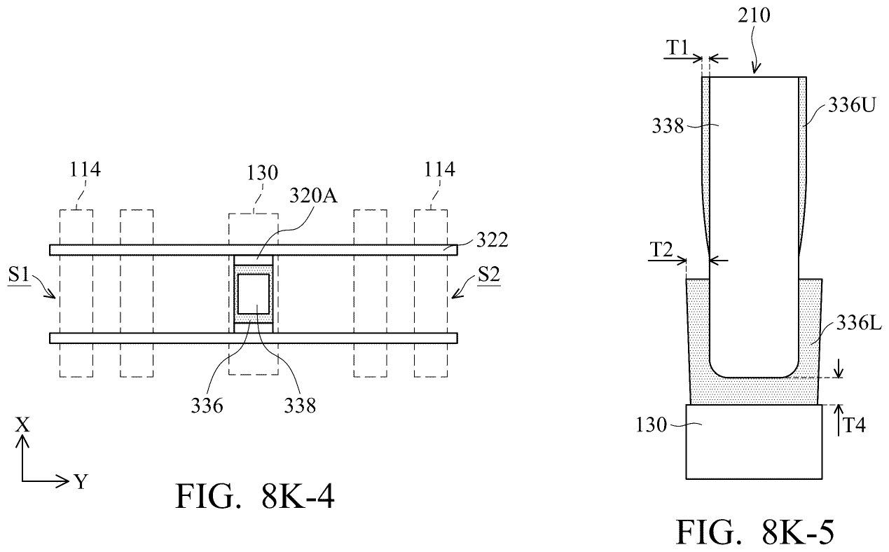

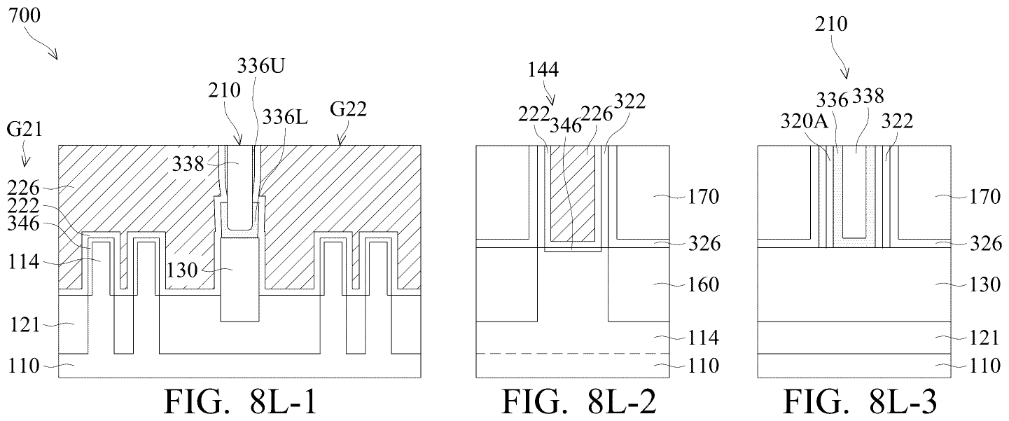

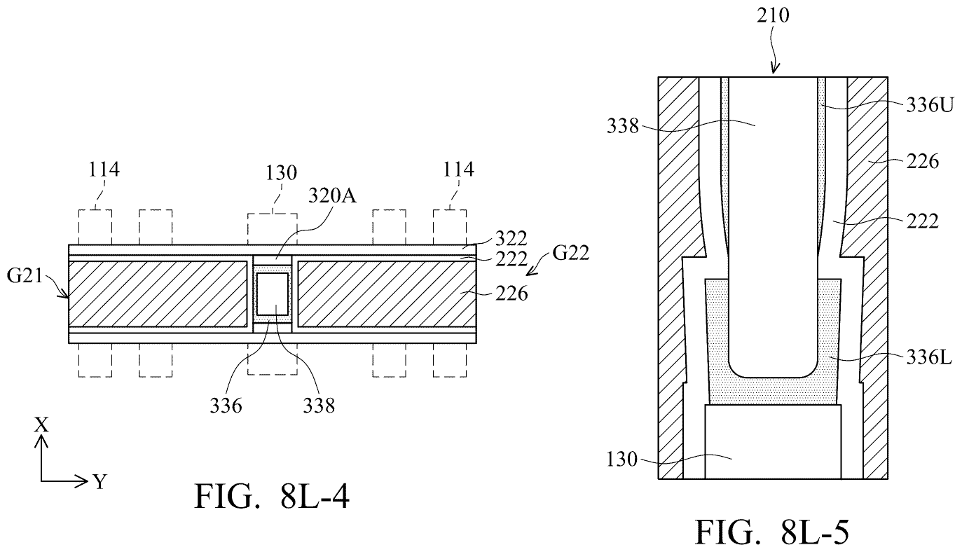

FIGS. 8A-1, 8B-1, 8C-1, 8D-1, 8E-1, 8F-1, 8G-1, 8H-1, 8I-1, 8J-1, 8K-1 and 8L-1 are cross-sectional views corresponding to plane Y-Y shown in FIG. 7, in accordance with some embodiments. FIGS. 8A-2, 8B-2, 8C-2, 8D-2, 8E-2, 8F-2, 8G-2, 8H-2, 8I-2, 8J-2, 8K-2 and 8L-2 are cross-sectional views corresponding to plane X-X shown in FIG. 7, in accordance with some embodiments. FIGS. 8C-3, 8D-3, 8E-3, 8F-3, 8G-3, 8H-3, 8I-3, 8J-3, 8K-3 and 8L-3 are cross-sectional views of the semiconductor structure 700 taken along a plane parallel to the X direction and through a dielectric fin structure, in accordance with some embodiments. FIGS. 8C-4, 8D-4, 8G-4, 8I-4, 8K-4 and 8L-4 are plan views of the semiconductor structure 700, in accordance with some embodiments. FIGS. 8K-5 and 8L-5 are enlarged views of FIGS. 8K-1 and 8L-1 to illustrate more detail of a gate cut isolation structure and neighboring components, in accordance with some embodiments.

FIGS. 8A-1 and 8A-2 illustrate the formation of semiconductor fin structures 114, in accordance with some embodiments.

Semiconductor fin structures 114 are formed over a semiconductor substrate 110, as shown in FIGS. 8A-1 and 8A-2, in accordance with some embodiments. In some embodiments, the semiconductor fin structures 114 extend in the X direction and are arranged in parallel to one another in the Y direction. That is, the semiconductor fin structures 114 have longitudinal axes parallel to the X direction, in accordance with some embodiments.

In some embodiments, the substrate 110 is a semiconductor substrate such as a silicon substrate. In some embodiments, the substrate 110 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 110 may optionally include an epitaxial layer (epi-layer), may be strained for performance enhancement, may include a silicon-on-insulator (SOI) structure, and/or have other suitable enhancement features.

In some embodiments, the formation of the semiconductor fin structure 114 includes patterning the substrate 110 to form trenches 305 so that the semiconductor fin structures 114 protrude from between the trenches 305. The patterning process may include photolithography and etching processes. The trenches 305 between the semiconductor fin structures 114 may have different widths. For example, a trench 305₁ is narrower than a trench 305₂.

FIGS. 8B-1 and 8B-2 illustrate the deposition of an insulating material 120 and a dielectric material 130a, in accordance with some embodiments.

An insulating material 120 is deposited over the semiconductor structure 700, as shown in FIGS. 8B-1 and 8B-2, in accordance with some embodiments. The trenches 305₁ with small widths are entirely filled with the insulating material 120 while the trenches 305₂ with large widths are partially filled with the insulating material 120, in accordance with some embodiments.

In some embodiments, the insulating material 120 includes silicon oxide, silicon nitride, silicon oxynitride (SiON), another suitable insulating material, and/or a combination thereof. In some embodiments, the insulating material 120 is deposited using chemical vapor deposition (CVD) such as low pressure CVD (LPCVD), plasma enhanced CVD (PECVD), or high density plasma CVD (HDP-CVD), high aspect ratio process (HARP), flowable CVD (FCVD)); atomic layer deposition (ALD); another suitable method, and/or a combination thereof.

A dielectric material 130a is deposited over the insulating material 120 to overfill the remaining portion of the trenches 305₂, as shown in FIGS. 8B-1 and 8B-2, in accordance with some embodiments. In some embodiments, the dielectric material 130a includes silicon nitride (SiN) silicon carbon nitride (SiCN), silicon oxynitride (SiON), silicon carbon oxynitride SiCON, hafnium oxide (HfO₂), lanthanum oxide (La₂O₃), aluminum oxide (Al₂O₃), zirconium oxide (ZrO₂), another suitable insulating material, multilayers thereof, and/or a combination thereof. In some embodiments, the dielectric material 130a and the insulating material 120 are made of different materials and have a great difference in etching selectivity. In some embodiments, the dielectric material 130a is deposited using CVD such as LPCVD, PECVD, HDP-CVD, HARP, FCVD, ALD, another suitable technique, and/or a combination thereof.

FIGS. 8C-1, 8C-2, 8C-3 and 8C-4 illustrate the formation of an isolation structure 121 and a dielectric fin structure 130, in accordance with some embodiments.

Portions of the dielectric material 130a and the insulating material 120 formed above the semiconductor fin structures 114 are removed until the upper surfaces of the semiconductor fin structures 114 are exposed. In some embodiments, the removal process is an etching-back process or a chemical mechanical polishing (CMP) process. The remainder of the dielectric material 130a forms a dielectric fin structure 130, in accordance with some embodiments of the disclosure.

Afterward, the insulating material 120 is recessed using an etch process (such as dry plasma etching and/or wet chemical etching) to form gaps between the semiconductor fin structures 114 and between the semiconductor fin structures 114 and the dielectric fin structure 130, in accordance with some embodiments. The remainder of the insulating material 120 forms an isolation structure 121, in accordance with some embodiments of the disclosure. The isolation structure 121 surrounds lower portions of semiconductor fin structures 114 and a lower portion of the dielectric fin structure 130, in accordance with some embodiments. A portion of the isolation structure 121 extends below the dielectric fin structure 130, in accordance with some embodiments.

The isolation structure 121 is configured to electrically isolate active regions (e.g., the semiconductor fin structures 114) of the semiconductor structure 700 and is also referred to as shallow trench isolation (STI) feature, in accordance with some embodiments.

In some embodiments, the dielectric fin structure 130 extends in the X direction. That is, the dielectric fin structure 130 has a longitudinal axis parallel to the X direction and substantially parallel to the semiconductor fin structures 114, in accordance with some embodiments. In some embodiments, the dielectric fin structure 130 is also referred to as a hybrid fin structure and configured as a portion for cutting a gate stack.

FIGS. 8D-1, 8D-2, 8D-3 and 8D-4 illustrate the formation of a dummy gate structure G1 and gate spacer layers 320 and 322, in accordance with some embodiments.

A dummy gate structure G1 is formed over the semiconductor structure 700, as shown in FIGS. 8D-1, 8D-2, 8D-3 and 8D-4, in accordance with some embodiments. The dummy gate structure G1 extends across and surrounds the dielectric fin structure 130 and the channel regions of the semiconductor fin structures 114 to define the channel regions and the source/drain regions, in accordance with some embodiments. The dummy gate structure G1 is configured as a sacrificial structure and will be replaced with a final gate stack, in accordance with some embodiments.

In some embodiments, the dummy gate structure G1 extends in the Y direction. That is, the dummy gate structure G1 has a longitudinal axis parallel to the Y direction, in accordance with some embodiments. FIGS. 8D-1 and 8D-4 shows one dummy gate structure G1 for illustrative purposes and is not intended to be limiting. The number of dummy gate structures G1 may be dependent on the demands on the semiconductor device design and/or performance considerations.

The dummy gate structure G1 includes a dummy gate dielectric layer 140 and a dummy gate electrode layer 150 formed over the dummy gate dielectric layer 140, as shown in FIGS. 8D-1, 8D-2 and 8D-3, in accordance with some embodiments. In some embodiments, the dummy gate dielectric layer 140 is made of one or more dielectric materials, such as silicon oxide (SiO), silicon nitride (SiN), silicon oxynitride (SiON), HfO₂, HfZrO, HfSiO, HfTiO, HfAlO, and/or a combination thereof. In some embodiments, the dielectric material is formed using ALD, CVD, thermal oxidation, physical vapor deposition (PVD), another suitable technique, and/or a combination thereof.

In some embodiments, the dummy gate electrode layer 150 is made of semiconductor material such as polysilicon, poly-silicon germanium. In some embodiments, the dummy gate electrode layer 150 is made of a conductive material such as metallic nitrides, metallic silicides, metals, and/or a combination thereof. In some embodiments, the material for the dummy gate electrode layer 150 is formed using CVD, another suitable technique, and/or a combination thereof.

In some embodiments, the formation of the dummy gate structure G1 includes globally and conformally depositing a dielectric material for the dummy gate dielectric layer 140 over the semiconductor structure 700, depositing a material for the dummy gate electrode layer 150 over the dielectric material, planarizing the material for the dummy gate electrode layer 150, and patterning the dielectric material and the material for the dummy gate electrode layer 150 into the dummy gate structure G1.

The patterning process includes forming a patterned hard mask layer (not shown) over the material for the dummy gate electrode layer 150 to cover the channel regions of the semiconductor fin structures 114, in accordance with some embodiments. The material for the dummy gate electrode layer 150 and the dielectric material, uncovered by the patterned hard mask layer, is etched away until the source/drain regions of the semiconductor fin structures 114 are exposed, in accordance with some embodiments.

The gate spacer layers 320 and 322 are sequentially formed over the semiconductor structure 700, as shown in FIGS. 8D-2, 8D-3 and 8D-4, in accordance with some embodiments. The gate spacer layers 320 and 322 are used to offset the subsequently formed source/drain features and separate the source/drain features from the gate structure, in accordance with some embodiments.

In some embodiments, the gate spacer layers 320 and 322 are made of dielectric material, such as a silicon-containing dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN).

In some embodiments, the formation of the gate spacer layer 320 includes globally and conformally depositing a dielectric material for the gate spacer layer 320 to cover the sidewalls of the dummy gate structure G1, the upper surfaces and the sidewalls of the semiconductor fin structures 114, the upper surface and the sidewalls of the dielectric fin structure 130, and the upper surface of the isolation structure 121, in accordance with some embodiments. Afterward, an etching process is performed to remove portions of the dielectric material formed on the upper surface of the dummy gate structure G1, the upper surfaces of the semiconductor fin structures 114, the upper surface of the dielectric fin structure 130, and the upper surface of the isolation structure 121, in accordance with some embodiments. The etching process may be an anisotropic etching process such as dry plasma etching, an isotropic etching process such as dry chemical etching, remote plasma etching or wet chemical etching, and/or a combination thereof. In some embodiments, the etching process is performed without an additional photolithography process. Remaining portions of the dielectric material on the sidewalls of the dummy gate structure G1 form the gate spacer layer 320, in accordance with some embodiments.

The dielectric material for the gate spacer layer 322 is then globally and conformally deposited. Afterward, an etching process is performed to remove portions of the dielectric material formed on the upper surface of the dummy gate structure G1, the upper surfaces of the semiconductor fin structures 114, the upper surface of the dielectric fin structure 130, and the upper surface of the isolation structure 121, in accordance with some embodiments. The deposition and etching process may be similar to those described above. Remaining portions of the dielectric material on the sidewalls of the dummy gate structure G1 form the gate spacer layer 322, in accordance with some embodiments.

In some embodiments, the gate spacer layers 320 and 322 are made of low-k dielectric materials. For example, the dielectric constant (k) values of the gate spacer layers 320 and 322 may be lower than the k-value of silicon oxide (SiO), such as lower than 4.2, equal to or lower than about 3.9, such as in a range from about 3.5 to about 3.9. In some embodiments, the gate spacer layer 320 and the gate spacer layer 322 are made of different materials and have different dielectric constant values. In some embodiments, the gate spacer layer 320 and the gate spacer layer 322 have a great difference in etching selectivity. For example, the gate spacer layer 320 is a SiOCN layer and the gate spacer layer 322 is a Si(O)CN layer. The oxygen concentration in the SiOCN layer may be greater than the oxygen concentration in the Si(O)CN layer.

FIGS. 8E-1, 8E-2 and 8E-3 illustrate the formation of source/drain features 160, in accordance with some embodiments.

The source/drain features 160 are formed on the semiconductor fin structures 114 and on the opposite sides of the dummy gate structure G1, as shown in FIG. 8E-2, in accordance with some embodiments. The formation of the source/drain features 160 includes recessing the source/drain regions of the semiconductor fin structures 114 using the dummy gate structure G1 and the gate spacer layers 320 and 322 as a mask to form source/drain recesses on opposite sides of the dummy gate structure G1, in accordance with some embodiments. The recessing process may be an anisotropic etching process such as dry plasma etching, an isotropic etching process such as dry chemical etching, remote plasma etching or wet chemical etching, and/or a combination thereof.

Afterward, the source/drain features 160 are grown in the source/drain recesses using an epitaxial growth process, in accordance with some embodiments. The epitaxial growth process may be molecular beam epitaxy (MBE), metal organic chemical vapor deposition (MOCVD), or vapor phase epitaxy (VPE), or another suitable technique. In some embodiments, the source/drain features 160 are made of any suitable semiconductor material for an n-type semiconductor device and a p-type semiconductor device, such as Ge, Si, GaAs, AlGaAs, SiGe, GaAsP, SiP, SiC, SiCP, or a combination thereof.

In some embodiments wherein the semiconductor fin structures 114 are to be formed as n-channel devices (such as n-channel FinFETs), the source/drain features 160 are made of semiconductor material such as SiP, SiAs, SiCP, SiC, Si, GaAs, another suitable semiconductor material, or a combination thereof. In some embodiments, the source/drain features 160 are doped with the n-type dopant during the epitaxial growth process. For example, the n-type dopant may be phosphorous (P) or arsenic (As). For example, the source/drain features 160 may be the epitaxially grown Si doped with phosphorous to form silicon:phosphor (Si:P) source/drain features and/or arsenic to form silicon:arsenic (Si:As) source/drain feature.

In some embodiments wherein the semiconductor fin structures 114 are to be formed as p-channel device (such as p-channel FinFET), source/drain features 160 are made of semiconductor material such as SiGe, Si, GaAs, another suitable semiconductor material, or a combination thereof. In some embodiments, the source/drain features 160 are doped with the p-type dopant during the epitaxial growth process. For example, the p-type dopant may be boron (B) or BF₂. For example, the source/drain features 160 may be the epitaxially grown SiGe doped with boron (B) to form silicon germanium: boron (SiGe:B) source/drain feature.

FIGS. 8F-1, 8F-2 and 8F-3 illustrate the formation of a contact etching stop layer (CESL) 326 and an interlayer dielectric (ILD) layer 170, in accordance with some embodiments.

A contact etching stop layer 326 is formed over the semiconductor structure 700, as shown in FIG. 8F-2, in accordance with some embodiments. The contact etching stop layer 326 extends along and covers the surfaces of the source/drain features 160 and the sidewalls of the gate spacer layer 322, in accordance with some embodiments. Although not shown in FIGS. 8F-1, 8F-2 and 8F-3, the contact etching stop layer 326 also extends along and covers the sidewalls of the dielectric fin structure 130, and the upper surface of the isolation structure 121, in accordance with some embodiments. Afterward, an interlayer dielectric layer 170 is formed over the contact etching stop layer 326, as shown in FIG. 8F-2, in accordance with some embodiments.

In some embodiments, the contact etching stop layer 326 is made of a dielectric material, such as silicon oxide (SiO₂), silicon nitride (SiN), silicon oxynitride (SiON), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 326 is globally and conformally deposited over the semiconductor structure 700 using CVD (such as LPCVD, PECVD, HDP-CVD, HARP, and FCVD), ALD, another suitable method, or a combination thereof.

In some embodiments, the interlayer dielectric layer 170 is made of a dielectric material, such as un-doped silicate glass (USG), or doped silicon oxide such as borophosphosilicate glass (BPSG), fluoride-doped silicate glass (FSG), phosphosilicate glass (PSG), borosilicate glass (BSG), and/or another suitable dielectric material. In some embodiments, a dielectric material for the interlayer dielectric layer 170 is deposited using such as CVD (such as HDP-CVD, PECVD, HARP or FCVD), another suitable technique, and/or a combination thereof.

In some embodiments, the interlayer dielectric layer 170 is made of a different material than the contact etching stop layer 326. In some embodiments, the interlayer dielectric layer 170 and the contact etching stop layer 326 have a great difference in etching selectivity. In some embodiments, the interlayer dielectric layer 170 is made of an oxide (such as silicon oxide) and the contact etching stop layer 326 is made of a nitrogen-containing dielectric (such as silicon nitride or silicon oxynitride).

Afterward, the dielectric materials for the contact etching stop layer 326 and the interlayer dielectric layer 170 above the upper surfaces of the dummy gate electrode layer 150 are removed using such as CMP until the upper surface of the dummy gate structure G1 is exposed, in accordance with some embodiments. CMP may also remove the patterned mask layer for forming the dummy gate structure G1. In some embodiments, the upper surface of the interlayer dielectric layer 170 is substantially coplanar with the upper surface of the dummy gate electrode layer 150.

FIGS. 8G-1, 8G-2, 8G-3 and 8G-4 illustrate the formation of a gate-cut opening H, in accordance with some embodiments.

A patterned mask layer 180 is formed over the dummy gate structure G1 and the interlayer dielectric layer 170, as shown in FIGS. 8G-1, 8G-2 and 8G-3, in accordance with some embodiments. The patterned mask layer 180 has an opening 182, in accordance with some embodiments. The opening 182 of the patterned mask layer 180 is aligned over an intersection of the dummy gate structure G1 and the dielectric fin structure 130, in accordance with some embodiments. In some embodiments, the gate spacer layers 320 and 322 are covered by the patterned mask layer 180, as shown in FIG. 8G-3. In alternative embodiments, the gate spacer layers 320 and 322 may be exposed from the opening 182.

In some embodiments, the patterned mask layer 180 is a patterned hard mask layer which is made of silicon nitride (SiN), silicon oxynitride (SiON), silicon oxide (SiO), a nitrogen-free anti-reflection layer (NFARL), carbon-doped silicon dioxide (e.g., SiO₂:C), titanium nitride (TiN), titanium oxide (TiO), boron nitride (BN), another suitable material, and/or a combination thereof.

For example, the material for the patterned mask layer 180 is deposited over the semiconductor structure 700. A photoresist may be formed over the material for the patterned mask layer 180 such as by using spin-on coating, and patterned with an opening pattern corresponding to the opening 182 by exposing the photoresist to light using an appropriate photomask. Exposed or unexposed portions of the photoresist may be removed depending on whether a positive or negative resist is used. The material for the patterned mask layer 180 may be etched using the photoresist to have the opening 182. The photoresist may be removed during the etching process or by an additional process (such as ashing).

An etching process is performed using the patterned hard mask layers 130 to remove a portion of the dummy gate structure G1 exposed from the opening 182, thereby forming a gate-cut opening H, as shown in FIGS. 8G-1, 8G-2, 8G-3 and 8G-4, in accordance with some embodiments. The etching process is performed until the gate-cut opening H extends to the dielectric fin structure 130, in accordance with some embodiments. The etching process may be an anisotropic etching process such as dry plasma etching, an isotropic etching process such as dry chemical etching, remote plasma etching or wet chemical etching, and/or a combination thereof.

The gate-cut opening H cuts through the dummy gate structure G1, and thus the dummy gate structure G1 is divided into two segments, in accordance with some embodiments. In some embodiments, the dielectric fin structure 130 is also recessed. The recessed upper surface may be located at a lower level than the upper surface of the semiconductor fin structure 114, in accordance with some embodiments.

FIGS. 8H-1, 8H-2 and 8H-3 illustrate the formation of a protection layer 336 and a fill layer 338, in accordance with some embodiments.

A protection layer 336 is deposited over the patterned mask layer 180 to partially fill the gat-cut opening H, as shown in FIGS. 8H-1, 8H-2 and 8H-3, in accordance with some embodiments. The protection layer 336 extends along and covers the sidewalls and the bottom surface of the gat-cut opening H, in accordance with some embodiments. Afterward, a fill layer 338 is deposited over the protection layer 336 to overfill the remainder of the gat-cut opening H, as shown in FIGS. 8H-1, 8H-2 and 8H-3, in accordance with some embodiments.

In some embodiments, the protection layer 336 is made of a dielectric material with a dielectric constant (k-value) lower than 7. In some embodiments, the protection layer 336 is made of silicon oxide (SiO₂), silicon nitride (SiN), silicon-rich silicon nitride (Si—SiN), silicon oxynitride (SiON), silicon oxynitride (SiOC), silicon oxide carbonitride (SiOCN), oxygen-doped silicon carbide (SiC:O), oxygen-doped silicon carbonitride (Si(O)CN), or a combination thereof. In some embodiments, a protection layer 336 is globally and conformally deposited over the semiconductor structure 700 using ALD, CVD (such as LPCVD, PECVD, HDP-CVD and HARP), another suitable method, or a combination thereof. In some embodiments, the protection layer 336 is selected to have a good etching resistance, thereby protecting the fill layer 338 from being damaged in a subsequent etching process.

In some embodiments, the fill layer 338 is made of a dielectric material with a dielectric constant (k-value) lower than 7. In some embodiments, the dielectric constant of the fill layer 338 is lower than the dielectric constant of the protection layer 336. The relatively lower dielectric constant of the fill layer 338 helps reducing device parasitic capacitance. In some embodiments, the fill layer 338 is made of silicon oxide (SiO₂), silicon nitride (SiN), silicon-rich silicon nitride (Si—SiN), silicon oxynitride (SiON), silicon oxynitride (SiOC), silicon oxide carbonitride (SiOCN), oxygen-doped silicon carbide (SiC:O), oxygen-doped silicon carbonitride (Si(O)CN), or a combination thereof. In some embodiments, a fill layer 338 is deposited using CVD (such as LPCVD, PECVD, HDP-CVD and HARP), ALD, another suitable method, or a combination thereof. In some embodiments, the material of the fill layer 338 is selected with the characteristics of, among others, good gap-fill for void-free in gate-cut opening H, high breakdown voltage to prevent leakage between metal gates, suitable stress to avoid crack/peeling of pre- and post-layer material (such as metal gate electrode material), and/or low thermal budget to prevent dopant diffusion.

In some embodiments, the protection layer 336 and the fill layer 338 are made of different materials. In some embodiments, the protection layer 336 is made of silicon oxide (SiO) and the fill layer 338 is made of silicon-rich silicon nitride (Si—SiN). In some embodiments, the protection layer 336 is made of silicon-rich silicon nitride (Si—SiN) and the fill layer 338 is made of silicon nitride (SiN). In some embodiments, the protection layer 336 is made of silicon nitride (SiN) and the fill layer 338 is made of silicon oxynitride (SiON). In some embodiments, the protection layer 336 is made of silicon nitride (SiN) and the fill layer 338 is made of silicon oxide carbonitride (SiOCN).

In some embodiments, silicon-rich silicon nitride (Si—SiN) has a higher nitrogen concentration than silicon nitride (SiN). For example, the atomic percentage ratio of silicon to nitrogen in the silicon-rich silicon nitride may be greater than about 1 (such as in a range from about 1 to about 1.5), while the atomic percentage ratio of silicon to nitrogen in the silicon nitride may be less than about 1 (such as in a range from about 0.7 to about 0.9, such as about 0.8). The ranges of the atomic percentage ratio of silicon to nitrogen in the silicon-rich silicon nitride and silicon nitride are beneficial to the contrast of etch selectivities and also beneficial to the performances of electrical isolation, gap fill capability, and breakdown voltage level. In some embodiments, silicon nitride (SiN) has a higher nitrogen concentration than silicon oxynitride (SiON) and silicon oxide carbonitride (SiOCN).

FIGS. 8I-1, 8I-2, 8I-3 and 8I-4 illustrate the formation of a gate cut isolation structure 210, in accordance with some embodiments.

The portions of the protection layer 336 and the fill layer 338 above the upper surfaces of the dummy gate structure G1 are removed until the upper surface of the dummy gate structure G1 is exposed, as shown in FIGS. 8I-1, 8I-2, 8I-3 and 8I-4, in accordance with some embodiments. The removal process may be CMP or etching back process. The patterned mask layer 180 is also removed in the removal process, in accordance with some embodiments. The remaining portions of the protection layer 336 and the fill layer 338 combine to form a gate cut isolation structure 210, in accordance with some embodiments.

The gate cut isolation structure 210 lands on the dielectric fin structure 130 and is sandwiched between two segments of the dummy gate structure G1, in accordance with some embodiments. The gate cut isolation structure 210 is a bi-layered structure which includes the protection layer 336 and the fill layer 338 nested within the protection layer 336, in accordance with some embodiments. The protection layer 336 is in contact with the dummy gate electrode layer 150, the dielectric fin structure 130 and the gate spacer layer 320, in accordance with some embodiments. The gate cut isolation structure 210 is configured to separate and electrically isolate subsequently formed metal gate stacks, in accordance with some embodiments.

FIGS. 8J-1, 8J-2 and 8J-3 and FIGS. 8K-1, 8K-2, 8K-3 and 8K-4 illustrate the removal of the dummy gate structure G1, in accordance with some embodiments.

The dummy gate electrode layer 150 and the dummy gate dielectric layer 140 are removed using one or more etching processes to form gate trenches S1 and S2, as shown in FIGS. 8K-1, 8K-2, 8K-3 and 8K-4, in accordance with some embodiments. The one or more etching processes may be an anisotropic etching process such as dry plasma etching, an isotropic etching process such as dry chemical etching, remote plasma etching or wet chemical etching, and/or a combination thereof. For example, when the dummy gate electrode layer 150 is made of polysilicon, a wet etchant such as a tetramethylammonium hydroxide (TMAH) solution may be used to selectively remove the dummy gate electrode layer 150.

In some embodiments, the etching process for removing the dummy gate electrode layer 150 includes several etching steps. In some embodiments, a first etching step of the etching process is performed to etched away half of the dummy gate electrode layer 150 to form gate trenches S′, as shown in FIGS. 8J-1, 8J-2 and 8J-3. The remaining portion of the dummy gate electrode layer 150 still covers the semiconductor fin structures 114, in accordance with some embodiments. Portions of the gate spacer layer 320 and the protection layer 336 of the gate cut isolation structure 210 are partially exposed from the gate trenches S′, as shown in FIGS. 8J-1 and 8J-2, in accordance with some embodiments. The protection layer 336 of the gate cut isolation structure 210 has a good etching resistance, and thus the protection layer 336 is substantially not consumed or only slightly consumed in the first etching step. Therefore, the protection layer 336 may protect the fill layer 338 of the gate cut isolation structure 210 from being damaged in the first etching step, in accordance with some embodiments. In addition, the gate spacer layer 320 is substantially not consumed or only slightly consumed in the first etching step.

A second etching step of the etching process is then performed to etch away the remaining portion of the dummy gate electrode layer 150 until the dummy gate dielectric layer 140 is are exposed, FIGS. 8K-1, 8K-2, 8K-3 and 8K-4, in accordance with some embodiments. In some embodiments, the first etching step and the second etching step are continuous steps. Enlarged gate trenches S′ are referred to as gate trenches S1 and S2.

In the second etching step, the etchant also laterally etches the gate spacer layer 320 from the gate trenches S′ until the gate spacer layer 322 is exposed, in accordance with some embodiments. Therefore, the dimension of the gate trenches S1 and S2 in the X direction increases, which may reduce junction overlap, thereby enhancing the performance of the resulting semiconductor device. After the second etching step of the etching process, a portion of the gate spacer layer 320 remains between the gate cut isolation structure 210 and the gate spacer layer 320 and is denoted as 320A, as shown in FIGS. 8K-3 and 8K-4.

In order to simultaneously etch away the dummy gate electrode layer 150 and the gate spacer layer 320, the parameters (e.g., the flow rate and/or concentration of etchant, types of the etchant, the pressure of the etching chamber, and/or RF power) of the second etching step may be adjusted so that the etching rate of the gate spacer layer 320 increases, which may also increase the etching rate of the protection layer 336 of the gate cut isolation structure 210. Therefore, the protection layer 336 is also consumed in the second etching step of the etching process.

During the second etching step, the etching rate (or consumption) of the protection layer 336 at different heights may be different. In some embodiments, the protection layer 336 is heavily etched at its middle height, and thus the middle portion of the protection layer 336 is removed to expose the fill layer 338, as shown in FIG. 8K-5. That is, the portion of the protection layer 336 facing the gate trench S1 (and S2) is etched into two parts (i.e., an upper portion 336U and a lower portion 336L), as shown in FIG. 8K-5. In some embodiments, the fill layer 338 is substantially not consumed or only slightly consumed in the second etching step.

In some embodiments, the protection layer 336 is moderately etched at a higher position. After the etching process, as measured in the Y direction, the upper portion 336U of the protection layer 336 along the fill layer 338 and facing the gate trench S1 (and S2) has a thickness T1, as shown in FIG. 8K-5, in accordance with some embodiments.

In some embodiments, the protection layer 336 is slightly etched at a lower position. After the etching process, as measured in the Y direction, the lower portion 336L of the protection layer 336 along the fill layer 338 and facing the gate trench S1 (and S2) has a thickness T2, as shown in FIG. 8K-5, in accordance with some embodiments.

In some embodiments, the thickness T2 is greater than the thickness T1. In some embodiments, the ratio of the thickness T1 to thickness T2 is in a range from about 0.1 to about 0.9.

A portion of the protection layer 336 along the fill layer 338 and facing the spacer feature 320A is substantially unetched and has a thickness T3 as measured in the X direction, as shown in FIG. 8K-3, in accordance with some embodiments. In some embodiments, the thickness T3 is greater than the thickness T2. In some embodiments, the ratio of the thickness T2 to the thickness T3 is in a range from about 0.1 to about 0.9.

The bottom portion of the protection layer 336 between the fill layer 338 and the dielectric fin structure 130 is substantially unetched and has a thickness T4 as measured in the Z direction, as shown in FIG. 8K-5, in accordance with some embodiments. In some embodiments, the thickness T4 is greater than the thickness T2. In some embodiments, the ratio of the thickness T2 to the thickness T4 is in a range from about 0.1 to about 0.9.

In accordance with the embodiments of the present disclosure, the protection layer 336 of the gate cut isolation structure 210 having a good etching resistance may protect the fill layer 338 of the gate cut isolation structure 210 from being damaged (e.g., necking and/or collapsing). In addition, the minimum thickness of the as-deposited protection layer 336 may be decided based on the maximum etching rate of the protection layer 336 and the total etching time of the etching process, so that the fill layer 338 can have a larger volume percentage in the gate-cut opening H without being damaged due to the etching process. As a result, the overall breakdown voltage of the gate cut isolation structure 210 may be enhanced.

Afterward, the dummy gate dielectric layer 140 is removed to expose the semiconductor fin structures 114 and the dielectric fin structure 130, as shown in FIGS. 8K-1, 8K-2, 8K-3 and 8K-4, in accordance with some embodiments. For example, the dummy gate dielectric layer 140 may be removed using a plasma dry etching, a dry chemical etching, and/or a wet etching.

FIGS. 8L-1, 8L-2, 8L-3 and 8L-4 illustrate the formation of final gate stacks G21 and G22, in accordance with some embodiments.

An interfacial layer 346 is formed on the exposed surfaces of the semiconductor fin structures 114, as shown in FIGS. 8L-1 and 8L-2, in accordance with some embodiments. In some embodiments, the interfacial layer 346 is made of a chemically formed silicon oxide. In some embodiments, the interfacial layer 346 is formed using one or more cleaning processes such as including ozone (O₃), ammonia hydroxide-hydrogen peroxide-water mixture, and/or hydrochloric acid-hydrogen peroxide-water mixture. Semiconductor material from the semiconductor fin structures 114 is oxidized to form the interfacial layer 346, in accordance with some embodiments.

A gate dielectric layer 222 is formed conformally along the interfacial layer 346 to surround the semiconductor fin structures 114, as shown in FIGS. 8L-1, 8L-2 and 8L-4, in accordance with some embodiments. The gate dielectric layer 222 is also conformally formed along the sidewalls of the gate spacer layer 322 facing the channel region, in accordance with some embodiments. The gate dielectric layer 222 is also conformally formed along the upper surface of the isolation structure 121, the sidewalls of the dielectric fin structure 130, and sidewalls of the gate cut isolation structure 210, in accordance with some embodiments.

A portion of the gate dielectric layer 222 extends between the upper portion 336U and the lower portion 336L of the protection layer 336 and is in contact with the fill layer 338, as shown in FIG. 8L-5, in accordance with some embodiments.

The gate dielectric layer 222 may be high-k dielectric layer. In some embodiments, the high-k dielectric layer is made of a dielectric material with high dielectric constant (k value), for example, greater than 3.9. In some embodiments, the high-k dielectric layer includes hafnium oxide (HfO₂), TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Al₂O₃, Si₃N₄, oxynitrides (SiON), a combination thereof, or another suitable material. The high-k dielectric layer may be deposited using ALD, PVD, CVD, and/or another suitable technique.

A metal gate electrode layer 226 is formed over the gate dielectric layer 222 and fills remainders of the gate trenches S1 and S2, as shown in FIGS. 8L-1, 8L-2 and 8L-4, in accordance with some embodiments. The metal gate electrode layer 226 surrounding the upper portions of the semiconductor fin structures 114, in accordance with some embodiments. In some embodiments, the metal gate electrode layer 226 is made of more than one conductive material, such as a metal, metal alloy, conductive metal oxide and/or metal nitride, another suitable conductive material, and/or a combination thereof. For example, the metal gate electrode layer 226 may be made of Ti, Ag, Al, TiAlN, TaC, TaCN, TaSiN, Mn, Zr, TiN, TaN, Ru, Mo, Al, WN, Cu, W, Re, Ir, Co, Ni, another suitable conductive material, or multilayers thereof.

The metal gate electrode layer 226 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to a next layer, and a metal fill layer to reduce the total resistance of gate stacks, and/or another suitable layer. The metal gate electrode layer 226 may be formed using ALD, PVD, CVD, e-beam evaporation, or another suitable process. The metal gate electrode layer 226 may be formed separately for n-channel transistors and p-channel transistors, which may use different work function materials.

A planarization process such as CMP may be performed on the semiconductor structure 700 to remove the materials of the gate dielectric layer 222 and the metal gate electrode layer 226 formed above the upper surface of the interlayer dielectric layer 170 and the upper surface of the gate cut isolation structure 210, in accordance with some embodiments. After the planarization process, the upper surface of the metal gate electrode layer 226, the gate cut isolation structure 210 and the upper surface of the interlayer dielectric layer 170 are substantially coplanar, in accordance with some embodiments.

The interfacial layer 346, the gate dielectric layer 222 and the metal gate electrode layer 226 combine to form final gate stacks, as shown in FIGS. 8L-1, 8L-2 and 8L-4, in accordance with some embodiments. The final gate stack includes two segments G21 and G22 which are separated and electrically isolated by the gate cut isolation structure 210, in accordance with some embodiments.

In some embodiments, the final gate stacks G21 and G22 extend in the Y direction. That is, the final gate stacks G21 and G22 have longitudinal axes parallel to the Y direction, in accordance with some embodiments. In some embodiments, as measured in the X direction, the width of the final gate stacks G21 and G22 is greater than the width of the gate cut isolation structure 210, as shown in FIG. 8L-4.

The final gate stack 144 surrounds the upper portions of the semiconductor fin structures 114 and are interposed between the source/drain features 160, in accordance with some embodiments. The final gate stack 144 combines with the source/drain features 160 to form FinFET device, such as an n-channel FinFET device or p-channel FinFET device, in accordance with some embodiments. The final gate stacks G21 and G22 may engage the channel region of the semiconductor fin structures 114, so that current can flow between the source/drain features 160 during operation.

In accordance with the embodiments, by forming the protection layer 336 of the gate cut isolation structure 210 with good etching resistance, the fill layer 338 of the gate cut isolation structure 210 with high breakdown voltage can remain intact after the etching process so as to well prevent leakage between the final gate stacks G21 and G22. As a result, the reliability of the resulting semiconductor device may be improved, and the manufacturing yield of the semiconductor device may be increased.

It should be understood that the semiconductor structure 700 may undergo further CMOS processes to form various features over the semiconductor structure 700, such as a multilayer interconnect structure (e.g., contacts to gate and/or source/drain features, vias, lines, inter metal dielectric layers, passivation layers, etc.).

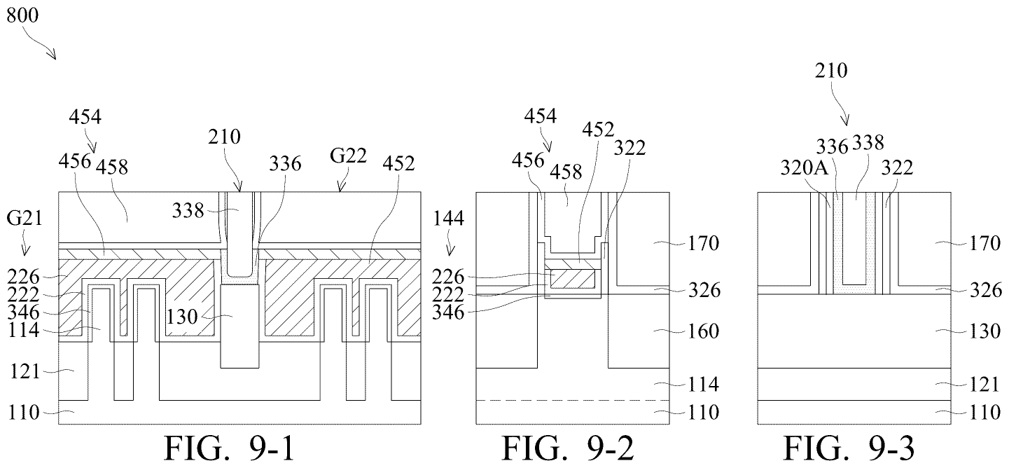

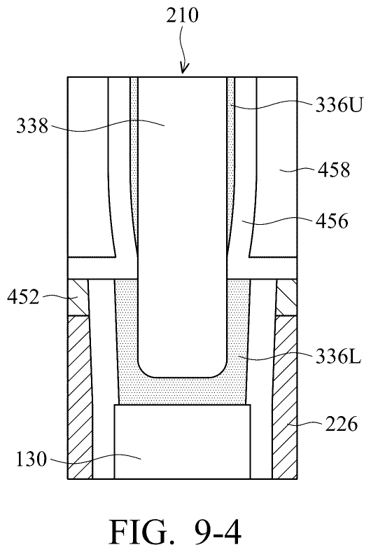

FIGS. 9-1 through 9-3 illustrate a semiconductor structure 800 which is a modification of the semiconductor structure 700 of FIGS. 8L-1 through 8L-4, in accordance with some embodiments of the disclosure. FIG. 9-1 is a cross-sectional view corresponding to plane Y-Y shown in FIG. 7, in accordance with some embodiments. FIG. 9-2 is a cross-sectional view corresponding to plane X-X shown in FIG. 7, in accordance with some embodiments. FIG. 9-3 is a cross-sectional view of the semiconductor structure 800 taken along a plane parallel to the X direction and through a dielectric fin structure, in accordance with some embodiments. FIG. 9-4 is an enlarged view of FIG. 9-1 to illustrate more detail of a gate cut isolation structure and neighboring components, in accordance with some embodiments.

After the final gate stacks G21 and G22 are formed, one or more etching process is performed to recess the final gate stacks G21 and G22 and the gate spacer layer 322, as shown in FIGS. 9-1 and 9-2, in accordance with some embodiments. The one or more etching process forms recesses over the final gate stacks G21 and G22 and the gate spacer layer 322. The etching process may be an anisotropic etching process such as dry plasma etching, an isotropic etching process such as dry chemical etching, remote plasma etching or wet chemical etching, and/or a combination thereof.

The upper surface of the recessed gate spacer layer 322 may be located at a higher level than the upper surfaces of the recessed final gate stacks G21 and G22, as shown in FIG. 9-2, in accordance with some embodiments. In some embodiments, the upper surfaces of the recessed final gate stacks G21 and G22 are located at a lower level than the upper surface of the lower portion 336L of the protection layer 336, as shown in FIG. 9-4, in accordance with some embodiments.

Afterward, a metal cap layer 452 is formed over the upper surfaces of the recessed final gate stacks G21 and G22 using a deposition process and an etching back process, as shown in FIGS. 9-1 and 9-2, in accordance with some embodiments. In some embodiments, the metal cap layer 452 is made of metal material such as W, Re, Ir, Co, Ni, Ru, Mo, Al, Ti, Ag, Al, another suitable metal, or multilayers thereof. The metal cap layer 452 and the metal gate electrode layer 226 are made of different materials. In some embodiments, the metal cap layer 452 is made of fluorine-free tungsten, which may lower the total resistance of the gate stack.

A dielectric cap structure 454 is formed over the metal cap layer 452 and the gate spacer layer 322 in the recesses, as shown in FIGS. 9-1 and 9-2, in accordance with some embodiments. In some embodiments, the dielectric cap structure 454 is a bi-layered structure including a lining layer 456 and a bulk layer 458 over the lining layer 456. The dielectric cap structure 454 may be configured to protect the gate spacer layer 322 and the final gate stacks G21 and G22 from being damaged during a subsequent etching process for forming contact plugs that land on the source/drain features 160.

The lining layer 456 is made of dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the dielectric material for the lining layer 456 is conformally deposited over the semiconductor structure 800 to partially fill the recesses using such as ALD, CVD (such as LPCVD, PECVD, HDP-CVD, or HARP), another suitable technique, and/or a combination thereof.

The bulk layer 458 is made of dielectric material such as silicon oxide (SiO₂), silicon nitride (SiN), silicon oxynitride (SiON), silicon carbon nitride (SiCN), silicon oxycarbonitride (SiOCN), oxygen-doped silicon carbonitride (Si(O)CN), or a combination thereof. In some embodiments, the dielectric material for the bulk layer 458 is then formed over the lining layer 456 to overfill the recesses using such as CVD (such as FCVD, LPCVD, PECVD, HDP-CVD or HARP), ALD, another suitable technique, and/or a combination thereof. In some embodiments, the bulk layer 458 and the lining layer 456 are made of different materials. For example, the bulk layer 458 has a lower dielectric constant than the lining layer 456. In some embodiments, the bulk layer 458 is made of an oxide (such as silicon oxide) and the lining layer 456 is made of a nitrogen-containing dielectric (such as silicon nitride or silicon oxynitride).

Afterward, a planarization process is then performed on the bulk layer 458 and the lining layer 456 until the interlayer dielectric layer 170 is exposed, in accordance with some embodiments. The planarization may be CMP, etching back process, or a combination thereof.

A portion of the lining layer 456 of the dielectric cap structure 454 extends between the upper portion 336U and the lower portion 336L of the protection layer 336 and is in contact with the fill layer 338, as shown in FIG. 9-4, in accordance with some embodiments.

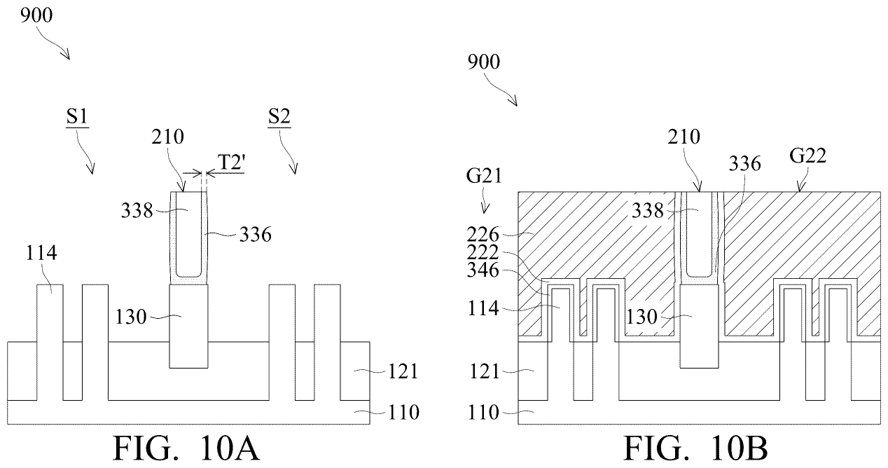

FIGS. 10A-10B are cross-sectional views illustrating the formation of a semiconductor structure 900 at various intermediate stages, in which FIG. 10A is a modification of FIG. 8K-1, in accordance with some embodiments of the disclosure. FIGS. 10A-10B correspond to plane Y-Y shown in FIG. 7, in accordance with some embodiments. The embodiments of the FIGS. 10A-10B are similar to the embodiments of the FIGS. 8A-1 through 8L-5, except that the sidewalls of the fill layer 338 remains covered by the protection layer 336 without being exposed.

By selecting the material and the thickness of protection layer 336 and/or adjusting the parameters (e.g., the flow rate and/or concentration of etchant, types of the etchant, the pressure of the etching chamber, and/or RF power) of the etching process for removing the dummy gate structure G1, the portion of the protection layer 336 facing the gate trench S1 (and S2) remains substantially intact and continuously extends from the bottom to the top of the fill layer 338, as shown in FIG. 10A, in accordance with some embodiments.

After the etching process, as measured in the Y direction, the portion of the protection layer 336 along the fill layer 338 and facing the gate trench S1 (and S2) has a thickness T2′, as shown in FIG. 10A, in accordance with some embodiments. In some embodiments, the thickness T3 (FIG. 8K-3) is greater than the thickness T2′. In some embodiments, the ratio of the thickness T2′ to thickness T3 is in a range from about 0.1 to about 0.9.

The steps described above with respect to FIGS. 8L-1, 8L-2, 8L-3 and 8L-4 are performed, thereby forming the final gate stacks G21 and G22, as shown in FIG. 10B, in accordance with some embodiments. In some embodiments, the gate dielectric layer 222 is separated from the fill layer 338 by the protection layer 336, in accordance with some embodiments.

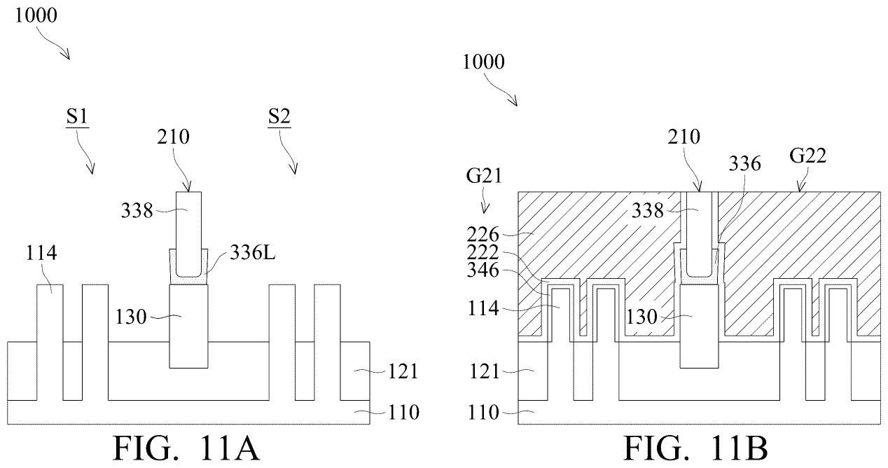

FIGS. 11A-11B are cross-sectional views illustrating the formation of a semiconductor structure 7000 at various intermediate stages, in which FIG. 11A is a modification of FIG. 8K-1, in accordance with some embodiments of the disclosure. FIGS. 11A-11B correspond to plane Y-Y shown in FIG. 7, in accordance with some embodiments. The embodiments of the FIGS. 11A-11B are similar to the embodiments of the FIGS. 8A-1 through 8L-5, except that the upper portion 336U of the protection layer 336 (FIG. 8K-1) is removed in the etching process for removing the dummy gate structure.

By selecting the material and the thickness of protection layer 336 and/or adjusting the parameters (e.g., the flow rate and/or concentration of etchant, types of the etchant, the pressure of the etching chamber, and/or RF power) of the etching process for removing the dummy gate structure G1, the upper portion and the middle portion of the protection layer 336 facing the gate trench S1 (and S2) are removed, while the lower portion 336L of the protection layer 336 facing the gate trench S1 (and S2) remains, as shown in FIG. 11A, in accordance with some embodiments.

In some embodiments, the lower portion of the fill layer 338 is nested within the protection layer 336 while the upper portion of the fill layer 338 protrudes from the protection layer 336, as shown in FIG. 11A, in accordance with some embodiments.

The steps described above with respect to FIGS. 8L-1, 8L-2, 8L-3 and 8L-4 are performed, thereby forming the final gate stacks G21 and G22, as shown in FIG. 11B, in accordance with some embodiments. The gate dielectric layer 222 is in contact with the upper portion of the fill layer 338, in accordance with some embodiments.

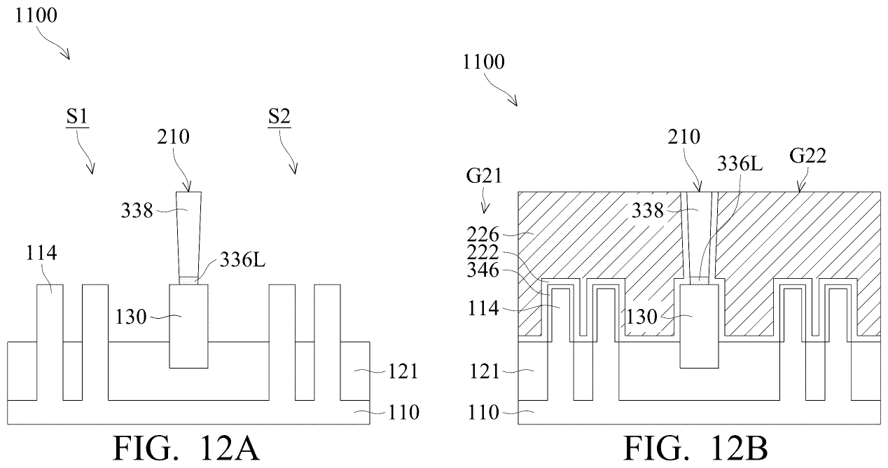

FIGS. 12A-12B are cross-sectional views illustrating the formation of a semiconductor structure 1100 at various intermediate stages, in which FIG. 12A is a modification of FIG. 8K-1, in accordance with some embodiments of the disclosure. FIGS. 12A-12B correspond to plane Y-Y shown in FIG. 7, in accordance with some embodiments. The embodiments of the FIGS. 12A-12B are similar to the embodiments of the FIGS. 8A-1 through 8L-5, except that the portion of the protection layer 336 facing the gate trenches is entirely removed.

By selecting the material and the thickness of protection layer 336 and/or adjusting the parameters (e.g., the flow rate and/or concentration of etchant, types of the etchant, the pressure of the etching chamber, and/or RF power) of the etching process for removing the dummy gate structure G1, the portion of the protection layer 336 facing the gate trenches S1 (and S2) is entirely removed, as shown in FIG. 12A, in accordance with some embodiments. After the etching process, the bottom portion 336L of the protection layer 336 remains between the fill layer 338 and the dielectric fin structure 130, in accordance with some embodiments.

The steps described above with respect to FIGS. 8L-1, 8L-2, 8L-3 and 8L-4 are performed, thereby forming the final gate stacks G21 and G22, as shown in FIG. 12B, in accordance with some embodiments. In some embodiments, the gate dielectric layer 222 is in contact with and extends along, from bottom to top, the sidewalls of the fill layer 338, in accordance with some embodiments.

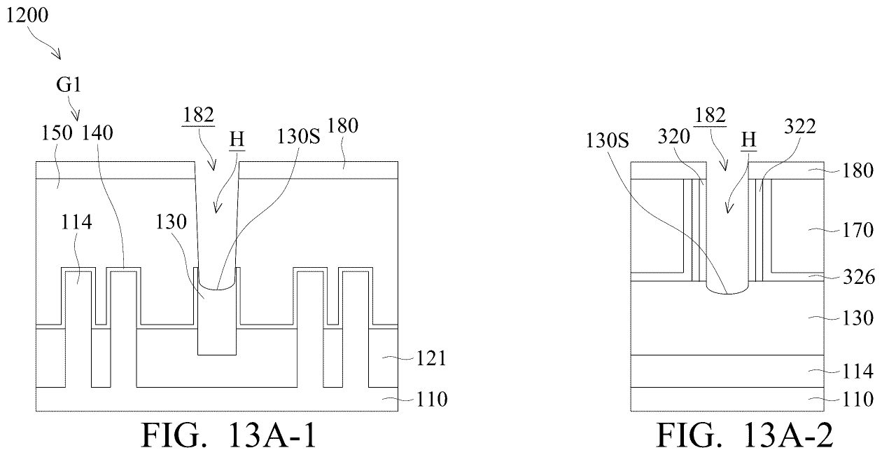

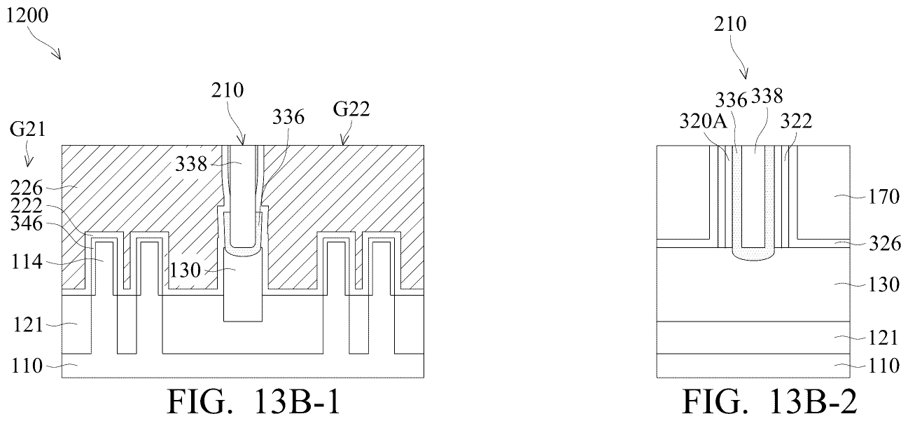

FIGS. 13A-1 through 13B-2 are cross-sectional views illustrating the formation of a semiconductor structure 1200 at various intermediate stages, in which FIGS. 13A-1 and 13A-2 is a modification of FIGS. 8G-1 and 8G-3, in accordance with some embodiments of the disclosure. FIGS. 13A-1 and 13B-1 correspond to plane Y-Y shown in FIG. 7, in accordance with some embodiments. FIGS. 13A-2 and 13B-2 are taken along a plane parallel to X direction and through a dielectric fin structure, in accordance with some embodiments. The embodiments of the FIG. 13A-1 through 13B-2 are similar to the embodiments of the FIGS. 8A-1 through 8L-5, except that the upper surface of the dielectric fin structure 130 is recessed.

In the etching process for forming the gate-cut opening H, the upper surface of the dielectric fin structure 130 is also recessed, thereby forming a concave upper surface 130S, as shown in FIGS. 13A-1 and 13A-2, in accordance with some embodiments. The concave upper surface 130S may be located at a lower level than the upper surface of the semiconductor fin structure 114, in accordance with some embodiments.

The steps described above with respect to FIGS. 8H-1 through 8L-5 are performed, thereby forming a gate cut isolation structure 210 and final gate stacks G21 and G22, as shown in FIGS. 13B-1 and 13B-2, in accordance with some embodiments. In some embodiments, the lower portion 336L of the protection layer 336 is embedded in the top portion of the dielectric fin structure 130. In some embodiments, the protection layer 336L has a convex bottom surface that is in contact with and mate with the concave upper surface 130S of the dielectric fin structure 130.

FIGS. 14A-1 through 14D-5 are schematic views illustrating the formation of a semiconductor structure 1300 at various intermediate stages, in accordance with some embodiments of the disclosure.

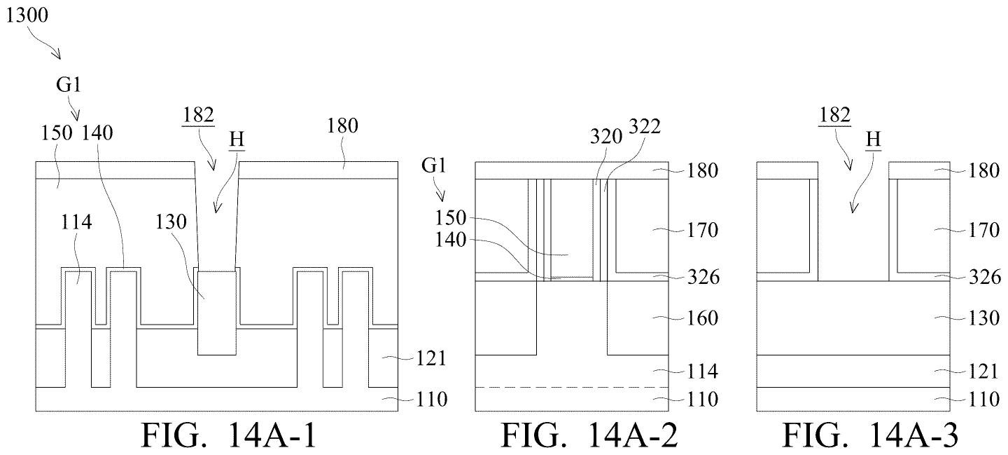

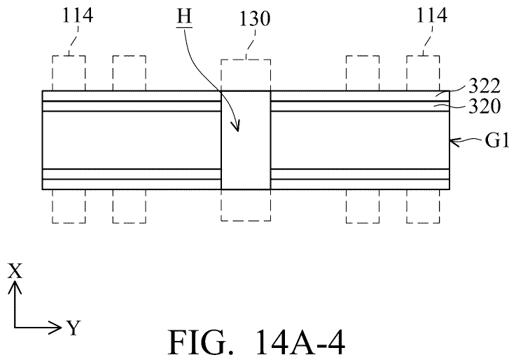

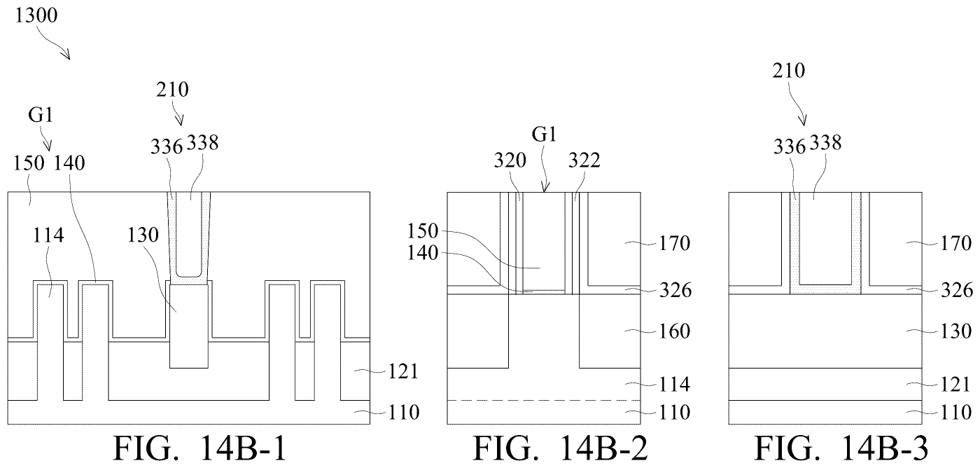

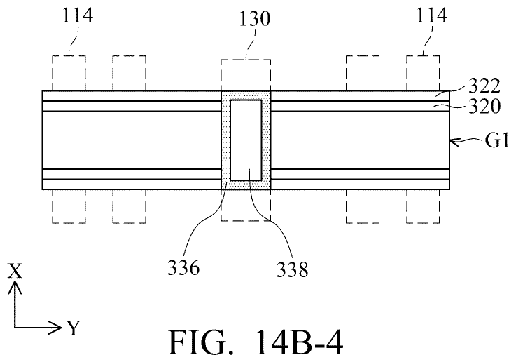

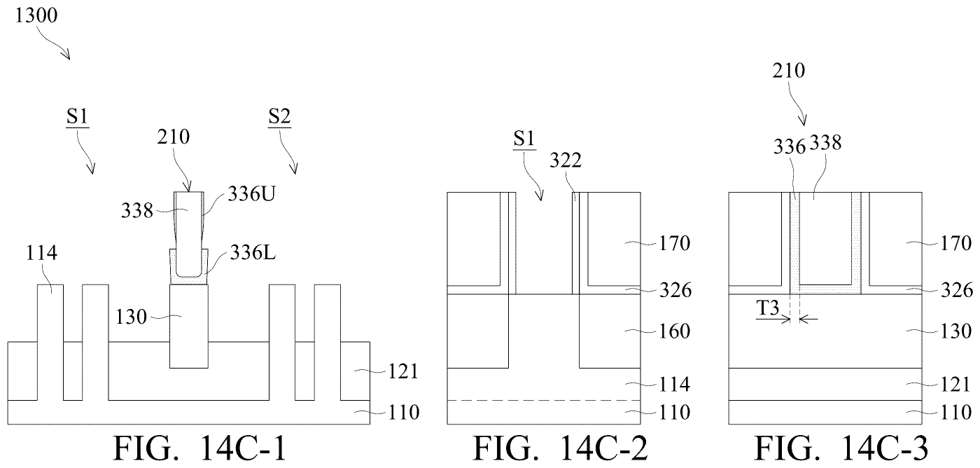

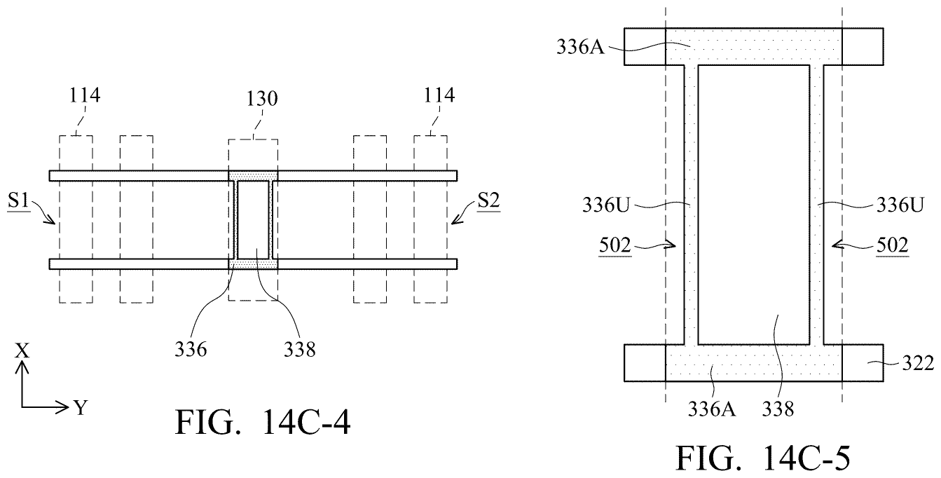

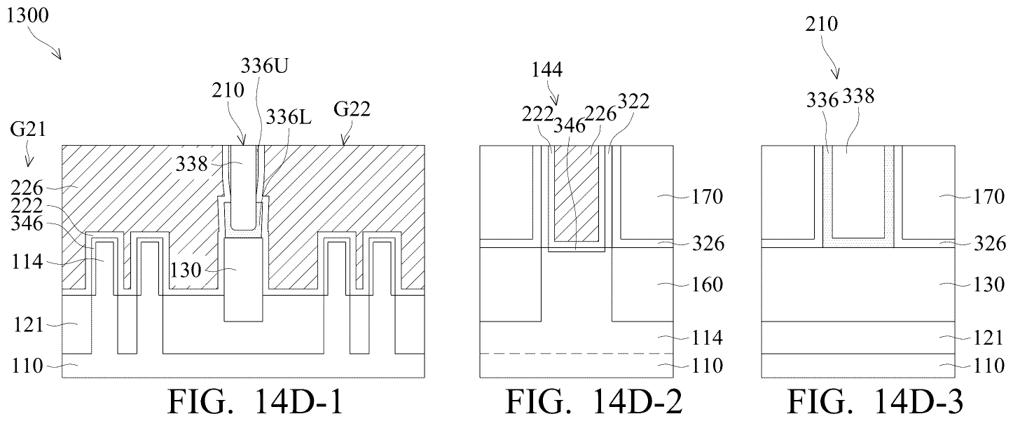

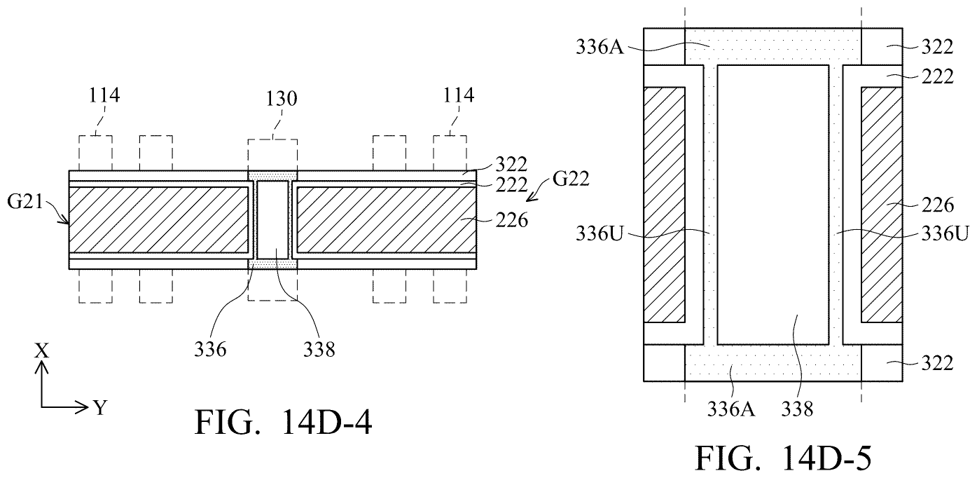

FIGS. 14A-1, 14B-1, 14C-1 are 14D-1 are cross-sectional views corresponding to plane X-X shown in FIG. 7, in accordance with some embodiments. FIGS. 14A-2, 14B-2, 14C-2 are 14D-2 are cross-sectional views corresponding to plane Y-Y shown in FIG. 7, in accordance with some embodiments. FIGS. 14A-3, 14B-3, 14C-3 are 14D-3 are cross-sectional views of the semiconductor structure 1300 taken along a plane parallel to the longitudinal axis (X direction) and through a dielectric fin structure, in accordance with some embodiments. FIGS. 14A-4, 14B-4, 14C-4 are 14D-4 are plan views of the semiconductor structure 1300, in accordance with some embodiments. FIGS. 14C-5 and 14D-5 are enlarged views of FIGS. 14C-4 and 14D-4 to illustrate more detail of a gate cut isolation structure and neighboring components, in accordance with some embodiments.

The embodiments of the FIGS. 14A-1 through 14D-5 are similar to the embodiments of the FIGS. 8A-1 through 8L-5, except that the gate cut isolation structure 210 has a larger dimension in the X direction.

Continuing from FIGS. 8G-1, 8G-2, 8G-3 and 8G-4, a patterned mask layer 180 is formed over dummy gate structure G1 and the interlayer dielectric layer 170, as shown in FIGS. 14A-1, 14B-2 and 14C-3, in accordance with some embodiments. The patterned mask layer 180 has an opening 182 which exposes the dummy gate structure G1 along with the gate spacer layers 320 and 322, in accordance with some embodiments.

An etching process is performed using the patterned hard mask layers 130 to remove portions of the dummy gate structure G1 and the gate spacer layers 320 and 322 exposed from the opening 182, thereby forming a gate-cut opening H, as shown in FIGS. 8A-1, 8A-2, 8A-3 and 8A-4, in accordance with some embodiments.

The gate-cut opening H exposes the contact etching stop layer 326, as shown in FIG. 14A-3, in accordance with some embodiments. The gate-cut opening H also cuts through the gate spacer layers 320 and 322, and thus each of the gate spacer layers 320 and 322 is divided into two segments, as shown in FIG. 14A-4, in accordance with some embodiments.

The steps described above with respect to FIGS. 8H-1 through 8I-5 are performed, thereby forming a gate cut isolation structure 210, as shown in FIGS. 14B-1, 14B-2, 14B-3 and 14B-4, in accordance with some embodiments.

The steps described above with respect to FIGS. 8J-1 through 8K-5 are performed, thereby forming gate trenches S1 and S2, as shown in FIGS. 14C-1, 14C-2, 14C-3 and 14C-4, in accordance with some embodiments. The gate spacer layer 320 is also removed in the second step of the etching process as described above until the dummy gate dielectric layer 140 and the gate spacer layer 322 are exposed, in accordance with some embodiments.

The protection layer 336 may be consumed in the second etching step of the etching process. The protection layer 336 is laterally recessed to form notches 502, as shown in FIG. 8C-5, in accordance with some embodiments. The protection layer 336 includes protruding portions 336A sandwiched between the two segments of the gate spacer layer 322 and remaining substantially unetched, as shown in FIG. 8C-5, in accordance with some embodiments. In the plan view, the protruding portions 336A laterally protrude from the upper portions 336U in the Y direction, in accordance with some embodiments.

The steps described above with respect to FIGS. 8L-1 through 8L-5 are performed, thereby forming final gate stacks G21 and G22, as shown in FIGS. 14D-1, 14D-2, 14D-3 and 14D-4, in accordance with some embodiments. In some embodiments, as measured in the X direction, the width of the final gate stack 144 is less than the width of the gate cut isolation structure 210, as shown in FIG. 14D-4.

A portion of the gate dielectric layer 222 is formed to fill the notches 502 and extends between the protruding portions 336A of the protection layer 336, as shown in FIG. 14D-5, in accordance with some embodiments.

As described above, the semiconductor structure includes a gate cut isolation structure 210 between the final gate stacks G21 and G22, in accordance with some embodiments. The gate cut isolation structure 210 includes a protection layer 336 with good etching resistance and a fill layer 338 with high breakdown voltage, in accordance with some embodiments. The protection layer 336 may protect the fill layer 338 from being damaged in the etching process for removing the dummy gate structure G1, in accordance with some embodiments. As a result, the fill layer 338 may remain intact after the etching process so as to well prevent leakage between the final gate stacks G21 and G22. Therefore, the reliability of the semiconductor device may be improved, and the manufacturing yield of the semiconductor device may be increased.

Embodiments of a semiconductor structure are provided. The semiconductor structure may include a gate cut isolation structure over a dielectric fin structure and between a first gate stack and a second gate stack. The gate cut isolation structure includes a protection layer and a fill layer over the protection layer, which are made of different materials. The protection layer may protect the fill layer from being damaged in the etching process, and the fill layer may prevent leakage between the gate stacks. Therefore, the reliability of the semiconductor device may be improved, and the manufacturing yield of the semiconductor device may be increased.

In some embodiments, a semiconductor structure is provided. The semiconductor structure includes a first gate stack across a first semiconductor fin structure, a second gate stack across a second semiconductor fin structure, a dielectric fin structure between the first semiconductor fin structure and the second semiconductor fin structure, and a gate cut isolation structure over the dielectric fin structure and between the first gate stack and the second gate stack. The gate cut isolation structure includes a protection layer and a fill layer over the protection layer, and the protection layer and the fill layer are made of different materials.

In some embodiments, a semiconductor structure is provided. The semiconductor structure includes a first semiconductor fin structure and a dielectric fin structure over a substrate, and a gate cut isolation structure over the dielectric fin structure. The gate cut isolation structure includes a fill layer and a protection layer surrounding the fill layer. The semiconductor structure also includes a first gate stack over the first semiconductor fin structure and adjoining the gate cut isolation structure. The first gate stack includes a gate dielectric layer in contact with both the protection layer and the fill layer, and a metal gate electrode layer over the gate dielectric layer.

In some embodiments, a method for forming a semiconductor structure is provided. The method includes forming a first semiconductor fin structure and a second semiconductor fin structure over a substrate, forming a dielectric fin structure between the first semiconductor fin structure and the second semiconductor fin structure, forming a dummy gate structure across the first semiconductor fin structure, the second semiconductor fin structure and the dielectric fin structure, etching the dummy gate structure to form an opening until the dielectric fin structure is exposed, forming a protection layer along sidewalls and a bottom surface of the opening, and forming a fill layer over the protection layer in the opening. The protection layer and the fill layer are made of different materials. The method also includes etching the dummy gate structure to expose the first semiconductor fin structure, the second semiconductor fin structure, the dielectric fin structure, and the protection layer. In some embodiments, the methos also includes etching the protection layer while etching the dummy gate structure, thereby exposing the fill layer a bottom portion of the protection layer is embedded in the dielectric fin structure. In some embodiments, the method also includes forming a first gate spacer layer along a sidewall of the dummy gate structure, forming a second gate spacer layer along a sidewall of the first gate spacer layer, and etching the first gate spacer layer while etching the dummy gate structure, thereby exposing the second gate spacer layer. In some embodiments, etching the dummy gate structure to form an opening includes removing a portion of the first gate spacer layer and a portion of the second gate spacer layer. In some embodiments, the methos also includes forming a gate dielectric layer along the first semiconductor fin structure, the second semiconductor fin structure, the dielectric fin structure and the protection layer, and forming a metal gate electrode layer over the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
an isolation structure over the substrate;
a first semiconductor fin protruding from the substrate and through the isolation structure;
a second semiconductor fin protruding from the substrate and through the isolation structure;
a dielectric fin between the first semiconductor fin and the second semiconductor fin, wherein top surfaces of the first and second semiconductor fins and a top surface of the dielectric fin are coplanar;
a first gate stack across the first semiconductor fin;
a first gate spacer extending along a sidewall of the first gate stack;
a second gate stack across the second semiconductor fin;
a second gate spacer extending along a sidewall of the second gate stack; and
a gate cut feature disposed over the top surface of the dielectric fin, the gate cut feature separating the first gate stack from the second gate stack.

2. The semiconductor structure of claim 1, wherein top surfaces of the first and second gate stacks and a top surface of the gate cut feature are coplanar.

3. The semiconductor structure of claim 1, wherein a bottom portion of the dielectric fin is embedded in the isolation structure.

4. The semiconductor structure of claim 1, wherein a top portion of the dielectric fin is embedded in the gate cut feature.

5. The semiconductor structure of claim 1, wherein the gate cut feature separates the first gate spacer from the second gate spacer.

6. The semiconductor structure of claim 1, wherein in a direction perpendicular to a lengthwise direction of the dielectric fin, a width of a bottom surface of the gate cut feature is greater than a width of the top surface of the dielectric fin.

7. The semiconductor structure of claim 1, wherein in a direction perpendicular to a lengthwise direction of the dielectric fin, a width of a bottom surface of the gate cut feature is smaller than a width of the top surface of the dielectric fin.

8. The semiconductor structure of claim 1, wherein in a lengthwise direction of the dielectric fin, a length of the dielectric fin is greater than a length of the gate cut feature.

9. The semiconductor structure of claim 1, wherein the gate cut feature includes a protection layer and a fill layer over the protection layer, and wherein the protection layer includes an upper portion and a lower portion wider than the upper portion.

10. The semiconductor structure of claim 9, wherein the fill layer has a first sidewall interfacing with a gate dielectric layer of the first gate stack and a second sidewall interfacing with a gate dielectric layer of the second gate stack.

11. A semiconductor structure, comprising:
a substrate and an isolation structure over the substrate;
a first active region over the substrate and a second active region over the substrate;
a dielectric fin partially embedded in the isolation structure and between the first and second active regions;
a first gate stack wrapping around the first active region and over a first side of the dielectric fin;
a second gate stack wrapping around the second active region and over a second side of the dielectric fin; and
a gate cut feature over the dielectric fin, wherein a bottommost portion of the gate cut feature is above a top surface of the dielectric fin, and wherein the dielectric fin and the gate cut feature electrically insulate the first gate stack from the second gate stack.

12. The semiconductor structure of claim 11, wherein the top surface of the dielectric fin is coplanar with top surfaces of the first and second active regions.

13. The semiconductor structure of claim 11, further comprising:
a gate spacer extending from a sidewall of the first gate stack to a sidewall of the second gate stack, the gate spacer interfacing with the gate cut feature.

14. The semiconductor structure of claim 11, further comprising:
a first gate spacer disposed on a sidewall of the first gate stack; and
a second gate spacer disposed on a sidewall of the second gate stack,
wherein the gate cut feature separates the first gate spacer from the second gate spacer.

15. The semiconductor structure of claim 11, wherein an interface between the dielectric fin and the isolation structure has a curvature profile.

16. The semiconductor structure of claim 11, wherein the first gate stack includes a first gate dielectric layer and a first gate electrode over the first gate dielectric layer, the second gate stack includes a second gate dielectric layer and a second gate electrode over the second gate dielectric layer, the first gate dielectric layer interfaces with a first sidewall of the gate cut feature, and the second gate dielectric layer interfaces with a second sidewall of the gate cut feature.

17. The semiconductor structure of claim 16, wherein each of the first and second gate dielectric layers interfaces with the top surface of the dielectric fin.

18. A semiconductor structure, comprising:
a semiconductor fin and a dielectric fin over a substrate and extending parallel to each other;
a gate cut feature over the dielectric fin, wherein the gate cut feature comprises a fill layer and a protection layer disposed on sidewalls and a bottom surface of the fill layer; and
a gate stack over the semiconductor fin,
wherein the gate stack includes a gate dielectric layer and a gate electrode over the gate dielectric layer, wherein the gate dielectric layer interfaces with both the protection layer and the fill layer.

19. The semiconductor structure of claim 18, wherein the protection layer includes an upper portion and a lower portion wider than the upper portion.

20. The semiconductor structure of claim 18, wherein a bottom surface of the gate cut feature is below a top surface of the semiconductor fin.
